(19) United States
(12) Patent Application Publication
(10) Pub. No.: US 2025/0374459 A1
(43) Pub. Date: Dec. 4, 2025

(54) ELECTRICAL CONNECTION UNIT

(71) Applicant: YAZAKI CORPORATION, Tokyo (JP)

(72) Inventors: Ryu Senoo, Kakegawa-shi (JP); Hirotaka Mukasa, Kakegawa-shi (JP); Hirokuni Kurashiki, Susono-shi (JP)

(21) Appl. No.: 19/218,187

(22) Filed: May 23, 2025

(30) Foreign Application Priority Data
May 29, 2024 (JP) 2024-087323

(51) Int. Cl. H05K 5/02; H05K 7/20

(52) U.S. Cl. CPC H05K 5/0247; H05K 7/2039

(57) ABSTRACT

An electrical connection unit includes an insulating base member and a bus bar. The base member includes a flat surface portion having a plate shape or sheet shape. In a case where a thickness direction of the flat surface portion is a first direction, the flat surface portion includes an accommodation portion recessed in the first direction or penetrating the flat surface portion in the first direction. At least a part of the bus bar is accommodated in the accommodation portion and extends along the flat surface portion.

### BACKGROUND OF THE INVENTION

### Field of the Invention

Embodiments of the present invention relate to an electrical connection unit.

Priority is claimed on Japanese Patent Application No. 2024-087323 filed in Japan on May 29, 2024, the content of which is incorporated herein by reference.

### Description of the Related Art

An electrical connection unit having a housing that accommodates electronic components and a bus bar attached to the housing in a standing posture is known.

### PRIOR ART DOCUMENT

### Patent Document

[Patent Document 1] Japanese Unexamined Patent Application, First Publication No. 2024-037492

### SUMMARY OF THE INVENTION

Incidentally, a height of an electrical connection unit is expected to be further reduced.

An embodiment provides an electrical connection unit capable of achieving height reduction.

An electrical connection unit according to an embodiment includes an insulating base member and a bus bar. The base member includes a flat surface portion having a plate shape or sheet shape. In a case where a thickness direction of the flat surface portion is a first direction, the flat surface portion includes an accommodation portion recessed in the first direction or penetrating the flat surface portion in the first direction. At least a part of the bus bar is accommodated in the accommodation portion and extends along the flat surface portion.

According to one embodiment, a height of an electrical connection unit can be reduced.

### BRIEF DESCRIPTION OF THE DRAWINGS

FIG. 1 is a cross-sectional view illustrating an electrical connection unit of a first embodiment.

FIG. 2 is a perspective view for describing a main body of the first embodiment.

FIG. 3 is a perspective view for describing a subunit of the first embodiment.

FIG. 4 is a partially exploded perspective view of the subunit of the first embodiment.

FIG. 5 is a perspective view for describing an electronic component and a connection component of the first embodiment.

FIG. 6 is a perspective view for describing the electronic component and the connection component of the first embodiment.

FIG. 7 is a perspective view illustrating the connection component of the first embodiment.

FIG. 8 is a perspective view illustrating a routing board of the first embodiment.

FIG. 9 is a partially exploded perspective view of the routing board according to the first embodiment.

FIG. 10 is a plan view illustrating the routing board of the first embodiment.

FIG. 11 is a partially exploded perspective view of a connection unit of the first embodiment.

FIG. 12 is a bottom view illustrating the routing board of the first embodiment.

FIG. 13 is a cross-sectional view taken along line F13-F13 of a structure illustrated in FIG. 10.

FIG. 14 is a cross-sectional view illustrating a modification example of the first embodiment.

FIG. 15 is a cross-sectional view illustrating a modification example of the first embodiment.

FIG. 16 is a cross-sectional view illustrating a modification example of the first embodiment.

FIG. 17 is a cross-sectional view illustrating a modification example of the first embodiment.

FIG. 18 is a perspective view illustrating a three-dimensional routing structure of a bus bar of the first embodiment.

FIG. 19 is a plan view illustrating the three-dimensional routing structure of the bus bar of the first embodiment.

FIG. 20 is a cross-sectional view taken along line F20-F20 of the structure illustrated in FIG. 10.

FIG. 21 is a cross-sectional view for describing a heat dissipation path related to a fixing portion of the first embodiment.

FIG. 22 is a cross-sectional view for describing a heat dissipation path according to a modification example of the first embodiment.

FIG. 23 is a cross-sectional view for describing an absorption structure for thermal expansion/contraction related to the fixing portion of the first embodiment.

FIG. 24 is a cross-sectional view illustrating an action of the absorption structure of the first embodiment.

FIG. 25 is a perspective view for describing a first aspect of an insulating rib of the first embodiment.

FIG. 26 is a perspective view for describing a first modification example of the first aspect of the first embodiment.

FIG. 27 is a cross-sectional view for describing a second modification example of the first aspect of the first embodiment.

FIG. 28 is a perspective view for describing a second aspect of the insulating rib of the first embodiment.

FIG. 29 is a cross-sectional view for describing a structure related to the connection component of the first embodiment.

FIG. 30 is a cross-sectional view for describing a method of manufacturing the electrical connection unit of the first embodiment.

FIG. 31 is a cross-sectional view for describing the method of manufacturing the electrical connection unit of the first embodiment.

FIG. 32 is a cross-sectional view for describing the method of manufacturing the electrical connection unit of the first embodiment.

FIG. 33 is a cross-sectional view for describing the method of manufacturing the electrical connection unit of the first embodiment.

FIG. 34 is a cross-sectional view for describing the method of manufacturing the electrical connection unit of the first embodiment.

FIG. 35 is a perspective view for describing a subunit of a second embodiment.

FIG. 36 is a cross-sectional view taken along line F36-F36 of the structure illustrated in FIG. 35.

FIG. 37 is a perspective view for describing a subunit of a third embodiment.

FIG. 38 is a perspective view for describing a subunit of a fourth embodiment.

FIG. 39 is a cross-sectional view taken along line F39-F39 of the structure illustrated in FIG. 38.

FIG. 40 is a cross-sectional view illustrating a modification example of the fourth embodiment.

FIG. 41 is a perspective view for describing a subunit of a fifth embodiment.

FIG. 42 is a cross-sectional view taken along line F42-F42 of the structure illustrated in FIG. 41.

### DETAILED DESCRIPTION OF THE INVENTION

Hereinafter, embodiments will be described with reference to the drawings. In the following description, constitutions having the same or similar functions are denoted by the same reference numbers. Redundant descriptions of these constitutions may be omitted. Note that the constitution described below does not limit the scope of the embodiment.

In the present disclosure, the terms are defined as follows. The term “connection” is not limited to a mechanical connection, and may include an electrical connection. That is, the term “connection” is not limited to a case where two elements that are connection targets are directly connected, and may include a case where two elements that are connection targets are connected with another element interposed therebetween. The term “accommodation” is not limited to a case where the entire component is accommodated, and may include a case where only part of the component is accommodated (a state in which the remaining part of the component protrudes). The term “facing” indicates that virtual projection images of two target objects overlap each other when viewed from a specific direction. That is, the term “facing” is not limited to a case where two target objects directly face each other, and may include a case where two target objects face each other in a state in which another member exists between the two target objects. “Parallel”, “orthogonal”, or “the same” may include “substantially parallel”, “substantially orthogonal”, or “substantially the same”, respectively.

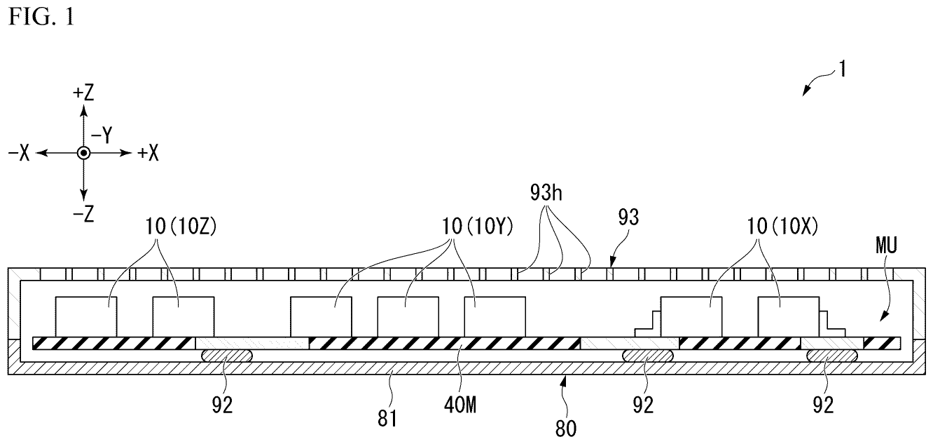

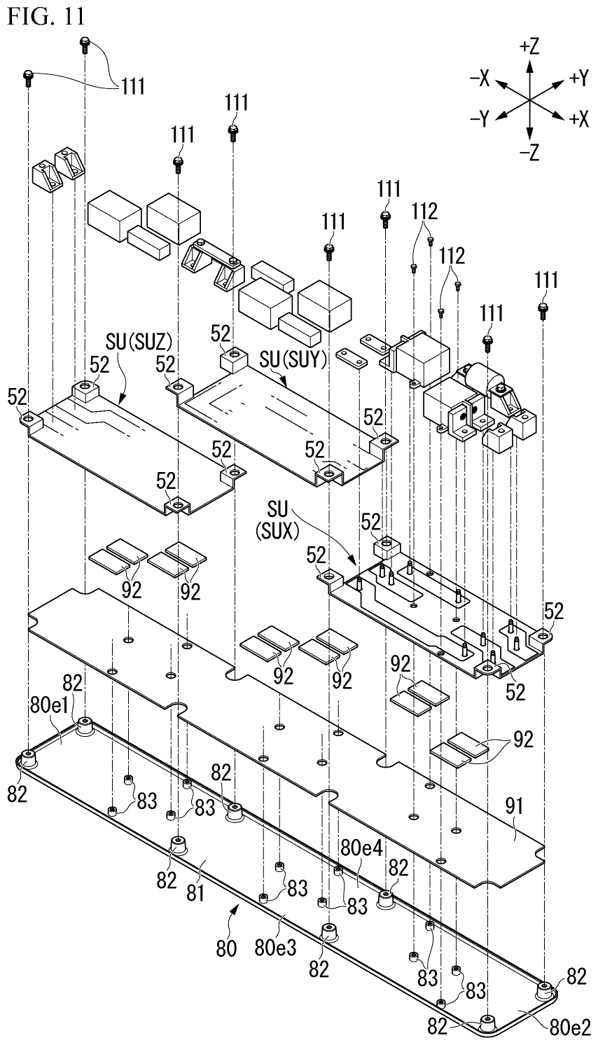

In the present disclosure, a +X direction, a −X direction, a +Y direction, a −Y direction, a +Z direction, and a −Z direction are defined as follows. The +X direction is a direction from a first end 80e1 to a second end 80e2 of a metal plate 80 that will be described later (see FIG. 11). The −X direction is a direction opposite to the +X direction. Hereinafter, in a case where the +X direction and the −X direction are not distinguished, the directions will be simply referred to as “X direction”. The +Y direction and the −Y direction are directions intersecting (for example, orthogonal to) the X direction. The +Y direction is a direction from a third end 80e3 to a fourth end 80e4 of the metal plate 80 that will be described later (see FIG. 11). The −Y direction is a direction opposite to the +Y direction. Hereinafter, in a case where the +Y direction and the −Y direction are not distinguished, the directions will be simply referred to as “Y direction”. The +Z direction and the −Z direction are directions intersecting (for example, orthogonal to) the X direction and the Y direction. The +Z direction is a direction from the metal plate 80 that will be described later toward a main body MU (see FIG. 1). The −Z direction is a direction opposite to the +Z direction. Hereinafter, in a case where the +Z direction and the −Z direction are not distinguished, the directions will be simply referred to as “Z direction”. The Z direction is an example of a “first direction”. The X direction is an example of a “second direction”. The “second direction” is not limited to the X direction, and may be the Y direction or other directions.

Hereinafter, in a case where the X direction and the Y direction are not distinguished, the directions may be referred to as “horizontal direction”. Hereinafter, the Z direction may be referred to as “vertical direction”. Hereinafter, the +Z direction side may be referred to as “upper”, and the −Z direction side may be referred to as “lower”. However, these expressions are expressions for convenience of description, and do not limit a gravity direction of an electrical connection unit 1 (an installation posture of the electrical connection unit 1).

### First Embodiment

### 1. Constitution of Electrical Connection Unit

FIG. 1 is a cross-sectional view illustrating an electrical connection unit 1 of a first embodiment. The electrical connection unit 1 is, for example, an in-vehicle device mounted on a vehicle such as an electric vehicle (EV), a hybrid electric vehicle (HEV), or a plug-in hybrid electric vehicle (PHEV). The electrical connection unit 1 may be referred to as an “electrical connection box” or a “junction box”, for example. However, the electrical connection unit 1 is not limited to a box-shaped device.

The electrical connection unit 1 includes, for example, a main body MU, a metal plate 80, an insulating sheet 91 (see FIG. 11), a plurality of heat transfer members 92, and an insulating cover 93.

### 2. Main Body

First, the main body MU will be described.

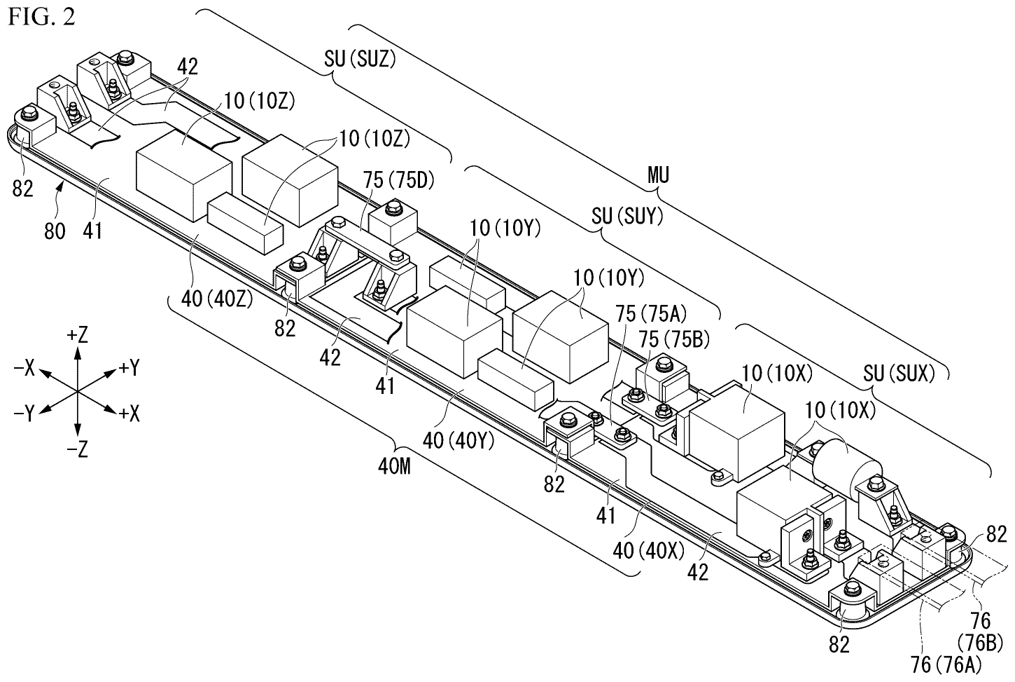

FIG. 2 is a perspective view for describing the main body MU. The main body MU is a portion that performs a main function (for example, switching of electrical connection states or overcurrent protection) of the electrical connection unit 1. In the present embodiment, the main body MU is divided into a plurality of subunits SU. The main body MU is formed by connecting a plurality of subunits SU. In the present embodiment, the main body MU includes three subunits SU (subunits SUX, SUY, and SUZ). Each subunit SU may be referred to as a “circuit constitution body”.

The subunit SUX has an electrical first function. The subunit SUX includes, for example, a plurality of electronic components 10X and a first routing board 40X. The plurality of electronic components 10X are electrically connected to the first routing board 40X.

The subunit SUY has an electrical second function. The second function is a function different from the first function. The subunit SUY includes, for example, a plurality of electronic components 10Y and a second routing board 40Y. The plurality of electronic components 10Y are electrically connected to the second routing board 40Y.

The subunit SUZ has an electrical third function. The third function is a function different from the first function and the second function. The subunit SUZ includes, for example, a plurality of electronic components 10Z and a third routing board 40Z. The plurality of electronic components 10Z are electrically connected to the third routing board 40Z.

In the present embodiment, the three subunits SUX, SUY, and SUZ are disposed to be arranged in the X direction. For example, the subunit SUX is disposed on the +X direction side with respect to the subunit SUY. The subunit SUX and the subunit SUY are electrically connected via a plurality of coupling bus bars 75 extending between the first routing board 40X and the second routing board 40Y. On the other hand, the subunit SUZ is disposed on the −X direction side with respect to the subunit SUY. The subunit SUZ and the subunit SUY are electrically connected via a plurality of coupling bus bars 75 (only one is illustrated in FIG. 2) extending between the third routing board 40Z and the second routing board 40Y. The coupling bus bar 75 is disposed on the side opposite to the metal plate 80 with respect to the plurality of subunits SU.

In the present embodiment, the three routing boards 40X, 40Y, and 40Z included in the three subunits SUX, SUY, and SUZ are disposed on the same plane. In other words, the three routing boards 40X, 40Y, and 40Z are disposed at the same height position in the Z direction. As a result, one large routing board 40M is formed by the three routing boards 40X, 40Y, and 40Z.

In the present embodiment, the three subunits SUX, SUY, and SUZ have the same or similar basic structure. Therefore, one subunit SU will be described in detail below as a representative. Hereinafter, in a case where the subunit SUX, the subunit SUY, and the subunit SUZ are not distinguished, the subunits are simply referred to as “subunit SU”. In addition, in a case where the electronic component 10X, the electronic component 10Y, and the electronic component 10Z are not distinguished, the electronic components are simply referred to as “electronic component 10”. In a case where the first routing board 40X, the second routing board 40Y, and the third routing board 40Z are not distinguished, the routing boards are simply referred to as “routing board 40”. One subunit SU included in the three subunits SUX, SUY, and SUZ is an example of a “first subunit”. On the other hand, another subunit SU included in the three subunits SUX, SUY, and SUZ is an example of a “second subunit”.

Note that the main body MU need not be divided into a plurality of subunits SU instead of the example described above. That is, the main body MU may be formed by the plurality of electronic components 10 and one routing board 40. In addition, the two or more subunits SU are not limited to the subunits SU having different functions, and may be the subunits SU having the same function.

### 3. Constitution of Subunit

Next, a constitution of the subunit SU will be described.

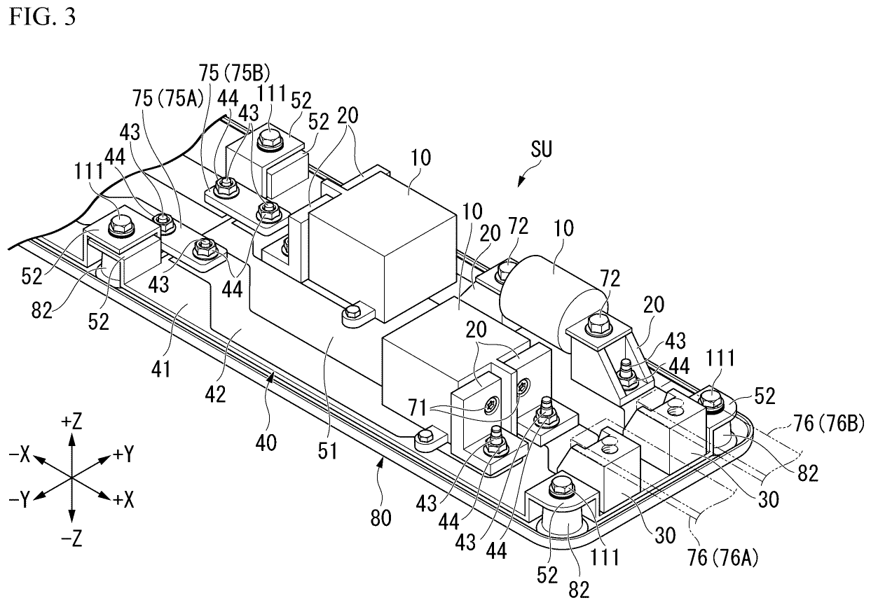

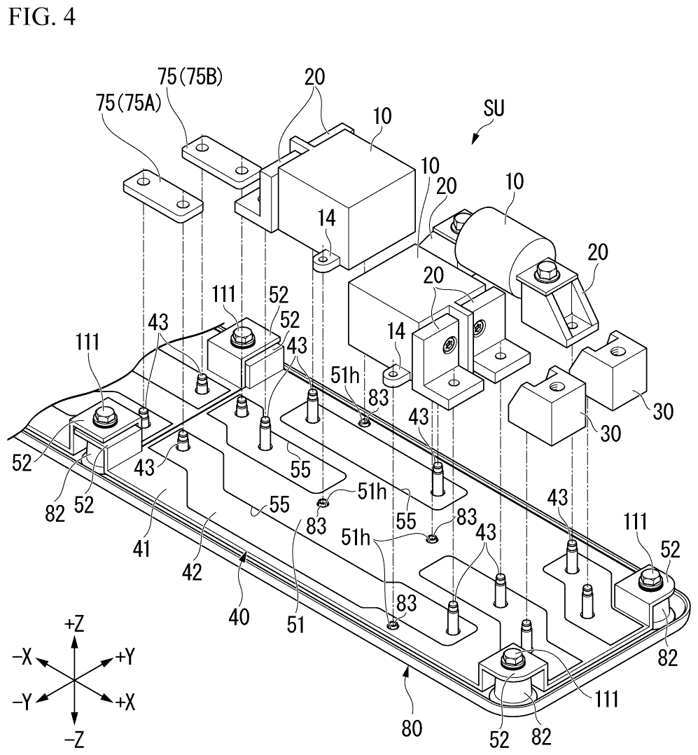

FIG. 3 is a perspective view for describing the subunit SU. FIG. 4 is a partially exploded perspective view of the subunit SU. The subunit SU includes, for example, a plurality of electronic components 10, a plurality of connection components 20 for component connection, a plurality of connection components 30 for external connection, and a routing board 40. The connection components 20 and 30 are members forming an energization path in the vertical direction. The connection components 20 and 30 may be referred to as “vertical routing members”.

### <3.1 Electronic Component and Connection Component for Component Connection>

First, the electronic component 10 and the connection component 20 for component connection will be described.

The electronic component 10 is an electronic component mounted according to a function required for the subunit SU. The electronic component 10 is, for example, a connector, a fuse, a relay (for example, a mechanical relay or a semiconductor relay), a capacitor, a branch component, any of various sensors (for example, a current sensor or a voltage sensor), an electronic control unit, or an electronic component unit in which two or more of these are unitized. Note that the type of the electronic component 10 is not limited to the above example. The electronic component 10 is, for example, a heat generating component that generates heat at the time of energization. Hereinafter, a first-type electronic component 10M and a second-type electronic component 10N will be described as examples of the electronic component 10.

The connection component 20 is a component that electrically connects the electronic component 10 to the routing board 40. The connection component 20 forms part of an energization path in the subunit SU. The connection component 20 is made of a metal (for example, copper or a copper alloy). The connection component 20 may be referred to as a “metal component”. Hereinafter, a first-type connection component 20M and a second-type connection component 20N will be described as examples of the connection component 20.

### <3.1.1 First-Type Electronic Component>

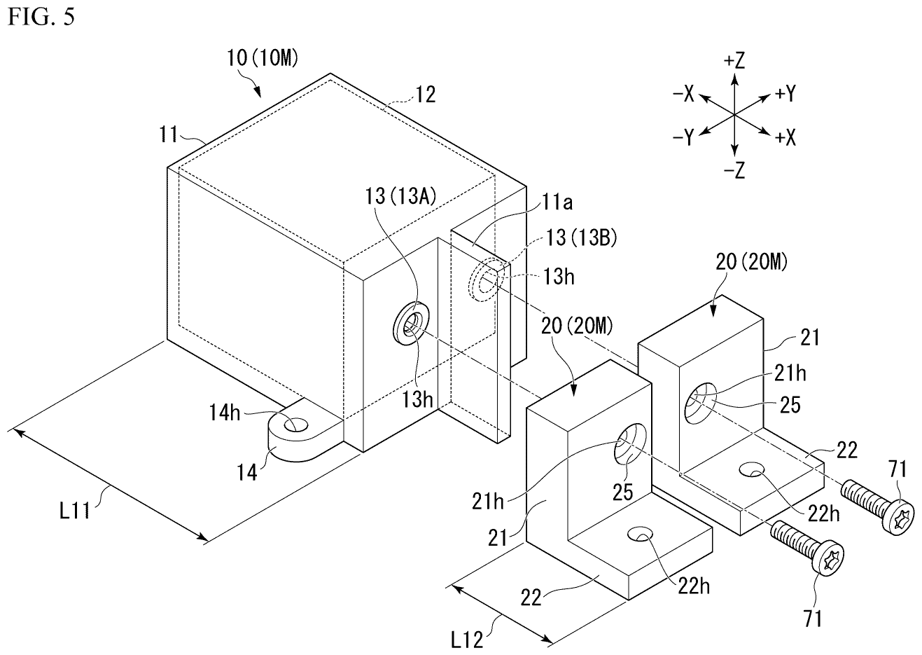

FIG. 5 is a perspective view illustrating the first-type electronic component 10M and the first-type connection component 20M. The first-type electronic component 10M is an electronic component in which a plurality of terminals 13 are disposed to be arranged at one end of the electronic component 10M. The electronic component 10M includes, for example, a case 11, a component body 12, a plurality of terminals 13, and a plurality of attachment portions 14.

### (Case)

The case 11 is an outer member that forms most of the outer shape of the electronic component 10M. The case 11 is made of, for example, synthetic resin and has an insulating property. The case 11 accommodates the component body 12. The case 11 and the component body 12 may be integrally formed.

In the present embodiment, the case 11 has an insulating rib 11a that protrudes in the horizontal direction (for example, the X direction) and extends in the Z direction. The insulating rib 11a has, for example, a plate shape formed in the horizontal direction (for example, the X direction) and the Z direction. The insulating rib 11a extends over the entire length of the case 11 in the Z direction, for example. The insulating rib 11a is disposed between the plurality of terminals 13 (a terminal 13A and a terminal 13B that will be described later). The insulating rib 11a electrically insulates the terminal 13A from the terminal 13B. In the present embodiment, part of the insulating rib 11a is disposed between first portions 21 (that will be described later) of two connection components 20M connected to the electronic component 10M. The insulating rib 11a electrically insulates the first portions 21 of the two connection components 20M connected to the electronic component 10M from each other.

### (Component Body)

The component body 12 is a portion that performs a main function of the electronic component 10M. For example, in a case where the electronic component 10M is a relay, the component body 12 includes a switch (for example, a contact) that switches between a conductive state and a non-conductive state. For example, in a case where the electronic component 10M is a fuse, the component body 12 includes a fusion portion that is fused when an overcurrent flows. For example, in a case where the electronic component 10M is a capacitor, the component body 12 includes a portion that stores electric charge.

### (Terminal)

The terminal 13 is an electrical connection portion exposed to the outside of the case 11. The terminal 13 is electrically connected to the component body 12 inside the case 11. In the present embodiment, the electronic component 10M includes a terminal 13A and a terminal 13B as the plurality of terminals 13. One of the terminal 13A and the terminal 13B is a terminal on the positive electrode side. The other of the terminal 13A and the terminal 13B is a terminal on the negative electrode side. One of the terminal 13A and the terminal 13B is an example of a “first terminal”. The other of the terminal 13A and the terminal 13B is an example of a “second terminal”.

In the present embodiment, the terminal 13A and the terminal 13B are provided at one end of the electronic component 10M in the horizontal direction (for example, the X direction). The terminal 13A and the terminal 13B are disposed to be arranged in the horizontal direction (for example, the Y direction). Each terminal 13 has an attachment hole 13h to which a fastening member 71 (for example, a screw or a bolt) that will be described later is attached. The attachment hole 13h is open in the horizontal direction (for example, the X direction). An inner circumferential surface of the attachment hole 13h of the electronic component 10M has a screw groove.

### (Attachment Portion)

The attachment portion 14 is a portion for fixing the electronic component 10M. The attachment portion 14 has an attachment hole 14h to which a fastening member 112 (for example, a screw or a bolt; and see FIG. 11) that will be described later is attached. The attachment hole 14h is open in the Z direction. The attachment hole 14h is an insertion hole through which the fastening member 112 passes. A fixing destination of the attachment portion 14 will be described later.

### <3.1.2 First-Type Connection Component>

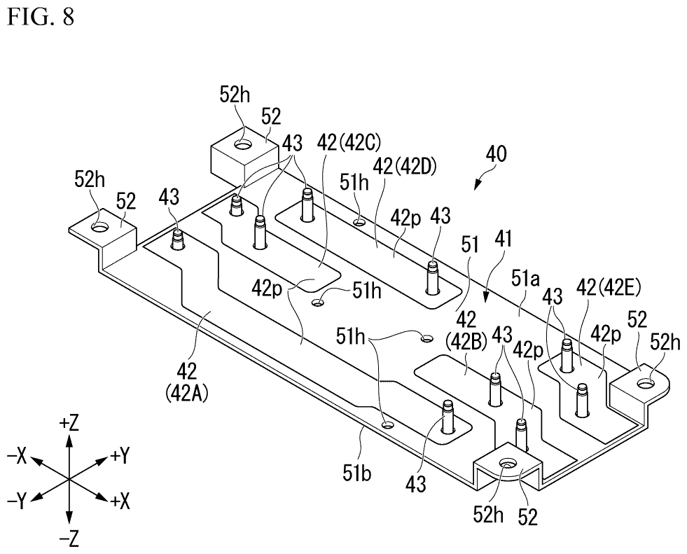

The first-type connection component 20M is a component that electrically connects the first-type electronic component 10M to the routing board 40. In the present embodiment, the connection component 20M electrically connects the electronic component 10M to a bus bar 42 (see FIG. 8) included in the routing board 40. In the present embodiment, a width L12 of the connection component 20M in a longitudinal direction (for example, the X direction) of the electronic component 10M is smaller than a width L11 of the electronic component 10M in the longitudinal direction. The connection component 20M includes, for example, a first portion 21 and a second portion 22.

### (First Portion)

The first portion 21 of the connection component 20M is a portion connected to the terminal 13 of the electronic component 10M. The first portion 21 is a plate-shaped or rectangular parallelepiped portion extending in the Z direction. The first portion 21 extends in the Z direction along one end (for example, an end in the X direction) of the electronic component 10M. The first portion 21 is a standing portion that stands in the Z direction with respect to the routing board 40 (for example, with respect to a bus bar 42 that will be described later). The first portion 21 is adjacent to the electronic component 10M in the horizontal direction (for example, the X direction). For example, the first portion 21 is adjacent to the terminal 13 of the electronic component 10M in the horizontal direction (for example, the X direction), and is connected to the terminal 13 of the electronic component 10M from the horizontal direction (for example, the X direction).

The first portion 21 of the connection component 20M has a first attachment hole 21h through which the fastening member 71 (for example, a screw or a bolt) passes. The first attachment hole 21h is open in the horizontal direction (for example, the X direction). The first portion 21 has a recess 25 around the first attachment hole 21h. The recess 25 is an accommodation portion that accommodates a head of the fastening member 71 inserted into the first attachment hole 21h. The fastening member 71 that has passed through the first attachment hole 21h is engaged with the attachment hole 13h of the terminal 13 of the electronic component 10M, and thus the first portion 21 is physically and electrically connected to the terminal 13 of the electronic component 10M. The first portion 21 need not have the recess 25.

### (Second Portion)

The second portion 22 of the connection component 20M is a portion connected to the bus bar 42 (see FIG. 8). The second portion 22 protrudes in the horizontal direction (for example, the X direction) from end of the first portion 21 on the −Z direction side. The second portion 22 is a plate portion provided in the horizontal direction. The second portion 22 is adjacent to the bus bar 42 in the Z direction, and is connected to the bus bar 42 from the Z direction. The second portion 22 of the connection component 20M is attached to the fastening member 43 (for example, a screw or a bolt; and see FIG. 8) protruding from the bus bar 42 in the +Z direction from the Z direction, and is physically and electrically connected to the bus bar 42. In the present embodiment, the second portion 22 of the connection component 20M has a second attachment hole 22h through which the fastening member 43 passes. The second attachment hole 22h is open in the Z direction. In the second portion 22, the fastening member 43 passes through the second attachment hole 22h. An engagement member 44 (for example, a nut; and see FIG. 3) is engaged with the tip of the fastening member 43 that has passed through the second attachment hole 22h, and thus the second portion 22 is fixed to the bus bar 42. In the present embodiment, the first portion 21 and the second portion 22 form one L-shaped connection component 20M.

### <3.1.3 Second-Type Electronic Component>

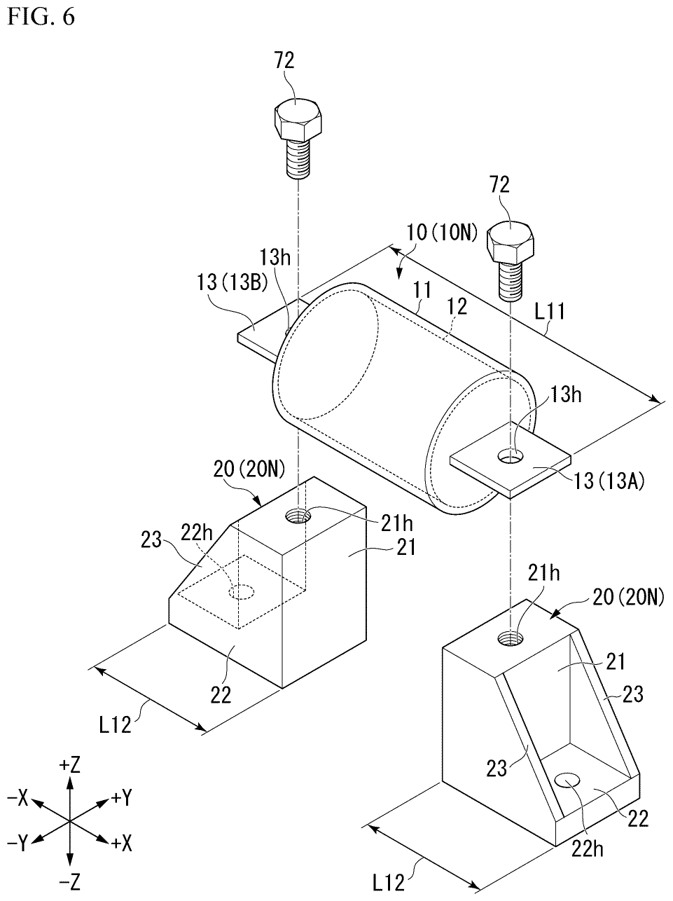

FIG. 6 is a perspective view illustrating the second-type electronic component 10N and the second-type connection component 20N. The second-type electronic component 10N is an electronic component in which two terminals 13 are separately disposed at both ends in the horizontal direction of the electronic component 10N. The electronic component 10N includes, for example, a case 11, a component body 12, and a plurality of terminals 13. Note that, among the constitutions of the electronic component 10N, constitutions having functions similar to those of the electronic component 10M are denoted by the same reference numbers. In this case, in the description regarding the electronic component 10N, the “electronic component 10M” may be replaced with the “electronic component 10N” in the description regarding the electronic component 10M described above.

In the electronic component 10N, the terminal 13A and the terminal 13B are disposed separately at both ends of the electronic component 10N in the horizontal direction (for example, the X direction). Each terminal 13 has an attachment hole 13h to which a fastening member 72 (for example, a screw or a bolt) that will be described later is attached. The attachment hole 13h is open in the Z direction. For example, the attachment hole 13h of the electronic component 10N is an insertion hole through which the fastening member 72 passes. One of the terminal 13A and the terminal 13B is an example of a “first terminal”. The other of the terminal 13A and the terminal 13B is an example of a “second terminal”.

### <3.1.4 Second-Type Connection Component>

The second-type connection component 20N is a component that electrically connects the second-type electronic component 10N to the routing board 40. In the present embodiment, the connection component 20N electrically connects the electronic component 10N to the bus bar 42 (see FIG. 8) included in the routing board 40. In the present embodiment, a width L12 of the connection component 20N in the longitudinal direction (for example, the X direction) of the electronic component 10N is smaller than a width L11 of the electronic component 10N in the longitudinal direction. The connection component 20N includes, for example, a first portion 21, a second portion 22, and a third portion 23.

### (First Portion)

The first portion 21 of the connection component 20N is a portion connected to the terminal 13 of the electronic component 10N. The first portion 21 is a rectangular parallelepiped portion extending in the Z direction. The first portion 21 is a standing portion that stands in the Z direction with respect to the routing board 40 (for example, with respect to the bus bar 42). The first portion 21 is adjacent to the terminal 13 of the electronic component 10N in the Z direction, and is connected to the terminal 13 of the electronic component 10N from the Z direction. The first portion 21 of the connection component 20N has a first attachment hole 21h with which the fastening member 72 is engaged. The first attachment hole 21h is open in the Z direction. An inner circumferential surface of the first attachment hole 21h of the connection component 20N has a screw groove. The fastening member 72 that has passed through the attachment hole 13h of the terminal 13 of the electronic component 10N is engaged with the attachment hole 21h of the first portion 21, and thus the first portion 21 is physically and electrically connected to the terminal 13 of the electronic component 10N.

### (Second Portion)

The second portion 22 of the connection component 20N is a portion connected to the bus bar 42 (see FIG. 8). The second portion 22 protrudes in the horizontal direction (for example, the X direction) from end of the first portion 21 on the −Z direction side. The second portion 22 is a plate portion provided in the horizontal direction. The second portion 22 is adjacent to the bus bar 42 in the Z direction, and is connected to the bus bar 42 from the Z direction. The second portion 22 of the connection component 20N is attached to, from the Z direction, the fastening member 43 (for example, a screw or a bolt; and see FIG. 8) protruding from the bus bar 42 in the +Z direction, and is physically and electrically connected to the bus bar 42. In the present embodiment, the second portion 22 of the connection component 20N has a second attachment hole 22h through which the fastening member 43 passes. The second attachment hole 22h is open in the Z direction. In the second portion 22, the fastening member 43 that will be described later passes through the second attachment hole 22h. An engagement member 44 (for example, a nut; and see FIG. 3) is engaged with the tip of the fastening member 43 that has passed through the second attachment hole 22h, and thus the second portion 22 is fixed to the bus bar 42.

### (Third Portion)

The third portion 23 is a standing wall (side wall) standing in the +Z direction from both ends of the second portion 22 in the horizontal direction. The third portion 23 is a wall provided in the Z direction. The third portion 23 is connected to the first portion 21 and is also connected to the second portion 22. For example, the third portion 23 extends obliquely so as to increase in the X direction as proceeding in the −Z direction.

The third portion 23 may be provided in the connection component 20M described above. On the other hand, the connection component 20N need not have the third portion 23.

### <3.2 Connection Component for External Connection>

Next, the connection component 30 for external connection will be described.

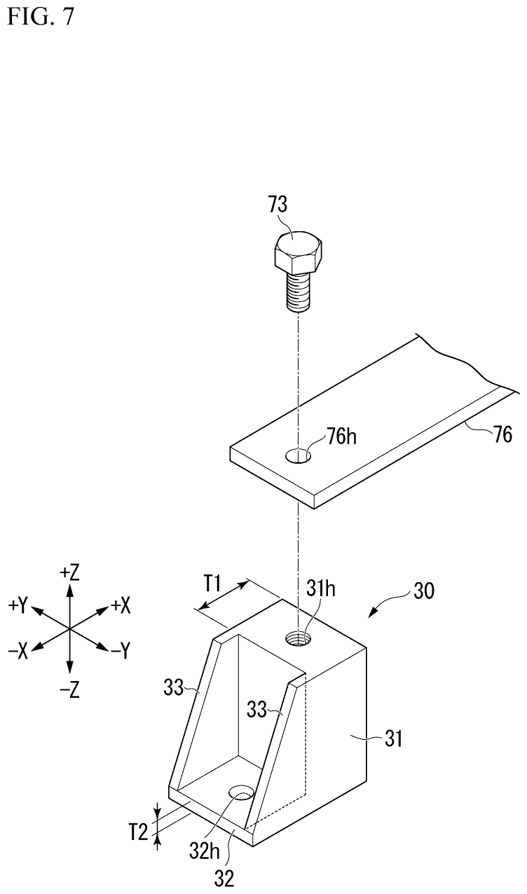

FIG. 7 is a perspective view illustrating the connection component 30 for external connection. The connection component 30 is a component that electrically connects an external connection bus bar 76 to the routing board 40. In the present embodiment, the connection component 30 electrically connects the external connection bus bar 76 to the bus bar 42 (see FIG. 8) included in the routing board 40. The external connection bus bar 76 is electrically connected to an external device. In the present disclosure, the “external device” is an electrical device existing outside the electrical connection unit 1. The external device is, for example, a battery unit mounted on a vehicle or an inverter for driving a motor of the vehicle, but is not limited to these examples. The connection component 30 includes, for example, a first portion 31, a second portion 32, and a third portion 33.

### (First Portion)

The first portion 31 is a portion connected to the external connection bus bar 76. The first portion 31 is a rectangular parallelepiped portion extending in the Z direction. The first portion 31 is a standing portion standing in the Z direction with respect to the routing board 40 (for example, with respect to the bus bar 42). The first portion 31 is adjacent to the external connection bus bar 76 in the Z direction, and is connected to the 5 external connection bus bar 76 from the Z direction. The first portion 31 has a first attachment hole 31h through which a fastening member 73 (for example, a screw or a bolt) passes. The first attachment hole 31h is open in the Z direction. An inner circumferential surface of the first attachment hole 31h has a screw groove. The fastening member 73 that has passed through the attachment hole 76h of the external connection bus bar 76 is engaged with the attachment hole 31h of the first portion 31, and thus the first portion 31 is physically and electrically connected to the external connection bus bar 76.

### (Second Portion)

The second portion 32 is a portion connected to the bus bar 42 (see FIG. 8). The second portion 32 protrudes in the horizontal direction (for example, the X direction) from the end of the first portion 31 on the −Z direction side. The second portion 32 is a plate portion provided in the horizontal direction. The second portion 32 is adjacent to the bus bar 42 in the Z direction, and is connected to the bus bar 42 from the Z direction. The second portion 32 is attached to, from the Z direction, the fastening member 43 (for example, a screw or a bolt; and see FIG. 8) protruding from the bus bar 42 in the +Z direction, and is physically and electrically connected to the bus bar 42. In the present embodiment, the second portion 32 has a second attachment hole 32h through which the fastening member 43 passes. The second attachment hole 32h is open in the Z direction. In the second portion 32, the fastening member 43 that will be described later passes through the second attachment hole 32h. The engagement member 44 (for example, a nut; and see FIG. 3) is engaged with the tip of the fastening member 43 that has passed through the second attachment hole 32h, and thus the second portion 32 is fixed to the bus bar 42.

### (Third Portion)

The third portion 33 is a standing wall (side wall) standing in the +Z direction from both ends of the second portion 32 in the horizontal direction. The third portion 33 is a wall provided in the Z direction. The third portion 33 is connected to the first portion 31 and is also connected to the second portion 32. For example, the third portion 33 extends obliquely to increase in the X direction (or the Y direction) as proceeding in the −Z direction. The connection component 30 need not include the third portion 33.

### <3.3 Routing Board>

Next, the routing board 40 will be described.

FIG. 8 is a perspective view illustrating the routing board 40. The routing board 40 is a member that forms at least part of an energization path between the plurality of electronic components 10 and/or at least part of an energization path between the electronic component 10 and an external device. In the present disclosure, the “routing board” indicates a board-type routing structure. The “board type” indicates a plate shape along one plane when viewed as a whole regardless of a fine shape. In the present disclosure, the term “plate shape”, “sheet shape”, or “planar” is not limited to the case of being completely flat, and may include a case where a fixing structure, a rib, or the like protruding in the Z direction is partially present, a case where an uneven shape following the thickness of the bus bar is present on the surface, and the like. In the present embodiment, the routing board 40 has a plate shape formed in the X direction and the Y direction.

The routing board 40 includes, for example, a base plate 41, one or more (for example, a plurality of) bus bars 42, and a plurality of fastening members 43. In the present embodiment, the base plate 41 and the plurality of bus bars 42 are integrated through insert molding. For example, the routing board 40 is formed as a single member by insert-molding the bus bar 42 with the base plate 41 after the fastening member 43 is fixed to the bus bar 42. That is, the bus bar 42 is integrated with the base plate 41 without using a fastening member such as a screw or a bolt. Note that the routing board 40 may be formed by another structure instead of the insert molding. A modification example in which the routing board 40 is formed by another structure will be described later.

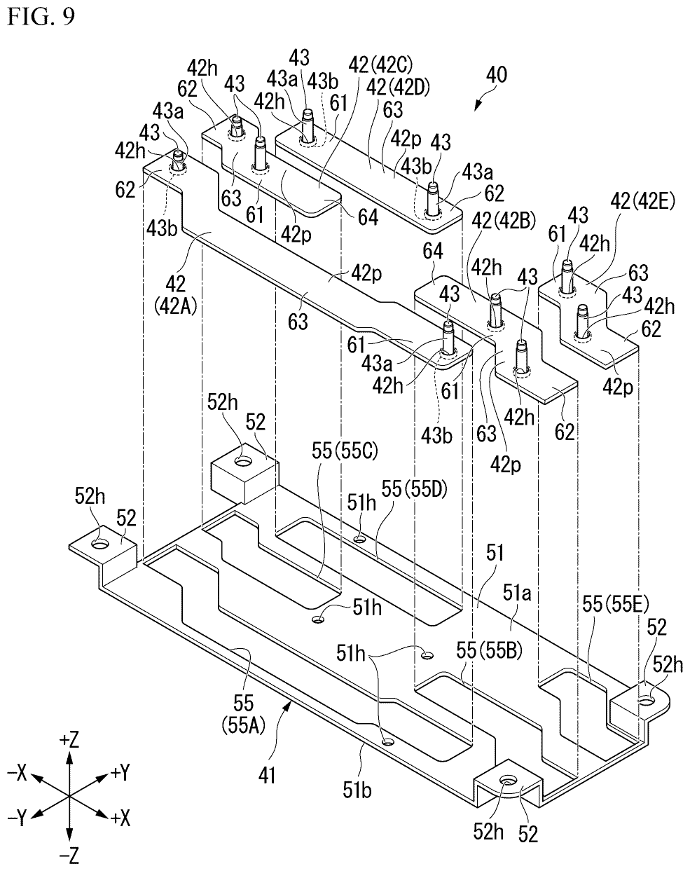

FIG. 9 is a partially exploded perspective view of the routing board 40. Hereinafter, for convenience of description, the base plate 41, the bus bar 42, and the fastening member 43 will be described with reference to the drawings in which the routing board 40 is partially exploded.

### (Base Plate)

The base plate 41 is a holding member that integrally holds the plurality of bus bars 42 arranged in the horizontal direction at intervals. The base plate 41 is made of, for example, synthetic resin and has an insulating property. The base plate 41 electrically insulates the plurality of bus bars 42 from each other. The base plate 41 is an example of a “base member”. The base plate 41 may be referred to as an “insulating substrate”. The base plate 41 includes, for example, a flat surface portion 51 and a plurality of fixing portions 52. The fixing portion 52 will be described later.

The flat surface portion 51 is a portion formed in a plate shape in the base plate 41. The flat surface portion 51 has a plate shape formed in the horizontal direction. The flat surface portion 51 forms a main portion of the base plate 41. The flat surface portion 51 forms a base portion (insulating base portion) of the base plate 41. In the present embodiment, the flat surface portion 51 extends over the entire width in the X direction of the base plate 41 and over the entire width in the Y direction of the base plate 41 except for four corner portions of the base plate 41.

The flat surface portion 51 has a first surface 51a and a second surface 51b. The first surface 51a is a surface directed in the +Z direction. The first surface 51a is a flat surface provided in the horizontal direction. The first surface 51a faces the plurality of electronic components 10 and faces the insulating cover 93 (see FIG. 1) of the electrical connection unit 1. The second surface 51b is located on the side opposite to the first surface 51a. The second surface 51b is a surface directed in the −Z direction. The second surface 51b is a flat surface provided in the horizontal direction. The second surface 51b faces the metal plate 80 (see FIG. 1). The thickness direction (plate thickness direction) of the flat surface portion 51 is the Z direction.

The flat surface portion 51 has, for example, one or more (for example, a plurality of) accommodation portions 55 in which the bus bars 42 are accommodated, respectively. The plurality of accommodation portions 55 are formed apart from each other in the X direction or the Y direction. Each of the accommodation portions 55 is, for example, a through-hole penetrating the flat surface portion 51 in the Z direction. Note that the accommodation portion 55 may be a recess provided on the first surface 51a or the second surface 51b of the flat surface portion 51 and recessed in the Z direction, instead of a through-hole. In the present disclosure, the phrase “the accommodation portion penetrates the flat surface portion in the first direction (Z direction)” may include a case where part of the entire length of the accommodation portion 55 penetrates the flat surface portion 51 in the Z direction (for example, the remaining portion of the accommodation portion 55 may be a recess recessed in the Z direction, or may be provided inside the base plate 41 and not exposed to the outside of the base plate 41). Similarly, in the present disclosure, the phrase “the accommodation portion is recessed in the first direction (Z direction)” may include a case where part of the entire length of the accommodation portion 55 is recessed in the Z direction (for example, a remaining portion of the accommodation portion 55 may be a through-hole penetrating the flat surface portion 51 in the Z direction, or may be provided inside the base plate 41 and not exposed to the outside of the base plate 41).

Each accommodation portion 55 has an outer shape corresponding to the shape of the bus bar 42 to be accommodated when viewed from the Z direction. In the present embodiment, the flat surface portion 51 includes, for example, five accommodation portions 55A, 55B, 55C, 55D, and 55E as the plurality of accommodation portions 55. The accommodation portion 55A is provided to correspond to a bus bar 42A that will be described later, and accommodates the bus bar 42A. The accommodation portion 55B is provided to correspond to a bus bar 42B that will be described later, and accommodates the bus bar 42B. The accommodation portion 55C is provided to correspond to a bus bar 42C that will be described later, and accommodates the bus bar 42C. The accommodation portion 55D is provided to correspond to a bus bar 42D that will be described later, and accommodates the bus bar 42D. The accommodation portion 55E is provided to correspond to a bus bar 42E that will be described later, and accommodates the bus bar 42E.

### (Bus Bar)

The bus bar 42 is a routing member (electrical connection member) included in the routing board 40. The bus bar 42 is, for example, a routing member for electrically connecting the plurality of electronic components 10. Alternatively, the bus bar 42 may be a routing member for connecting the electronic component 10 to an external device. The bus bar 42 is made of a metal (for example, copper or a copper alloy) and has conductivity. In the present embodiment, the routing board 40 includes, for example, five bus bars 42A, 42B, 42C, 42D, and 42E as the plurality of bus bars 42. The five bus bars 42A, 42B, 42C, 42D, and 42E are disposed to be arranged in the horizontal direction at intervals. The five bus bars 42A, 42B, 42C, 42D, and 42E include portions arranged on the same plane. The five bus bars 42A, 42B, 42C, 42D, and 42E are held by the flat surface portion 51 of the base plate 41.

At least part of each bus bar 42 has a plate shape formed in the horizontal direction. At least part of each bus bar 42 is accommodated in the accommodation portion 55 and extends along the flat surface portion 51. That is, at least part of each bus bar 42 extends along the first surface 51a of the flat surface portion 51. At least part of each bus bar 42 extends in the horizontal direction in the accommodation portion 55. In the present embodiment, each bus bar 42 has a plate shape formed in the horizontal direction over the entire bus bar 42. Each of the bus bars 42 is accommodated in the accommodation portion 55 over the entire length of the bus bar 42 and extends along the flat surface portion 51. Hereinafter, a portion of each bus bar 42 that is accommodated in the accommodation portion 55 and extends along the flat surface portion 51 may be referred to as a “plate portion 42p”. The bus bar 42 is a member that forms a horizontal energization path. The bus bar 42 may be referred to as a “horizontal routing member”.

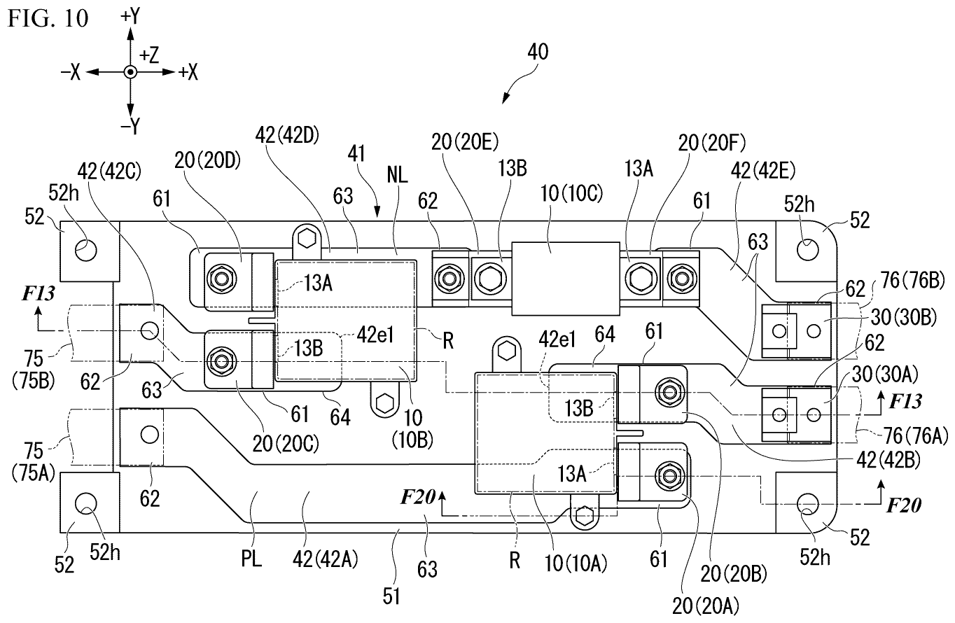

FIG. 10 is a plan view illustrating the routing board 40. The plate portion 42p of each bus bar 42 has, for example, a first connection portion 61, a second connection portion 62, and an extending portion 63.

The first connection portion 61 is a portion in contact with one connection component 20 (hereinafter referred to as a “first connection component 20”). The first connection component 20 is a connection component that connects one electronic component 10 (hereinafter referred to as a “first electronic component 10”) to the bus bar 42. The first connection portion 61 is a portion of the bus bar 42 overlapping the first connection component 20 when viewed from the Z direction. The first connection portion 61 is adjacent to the first connection component 20 in the Z direction, and is connected to the first connection component 20 from the Z direction.

The second connection portion 62 is a portion in contact with another connection component 20 (hereinafter referred to as a “second connection component 20”). The second connection component 20 is a connection component that connects another electronic component 10 (hereinafter referred to as a “second electronic component 10”) included in the plurality of electronic components 10 to the bus bar 42. The second connection portion 62 is a portion of the bus bar 42 overlapping the second connection component 20 when viewed from the Z direction. The second connection portion 62 is adjacent to the second connection component 20 in the Z direction, and is connected to the second connection component 20 from the Z direction.

Note that the second connection portion 62 may be a portion in contact with another connection component 30 (hereinafter referred to as a “second connection component 30”) instead of the above example. The connection component 30 is a connection component for connecting an external device to the bus bar 42. In this case, the second connection portion 62 is a portion of the bus bar 42 overlapping the second connection component 30 when viewed from the Z direction. The second connection portion 62 is adjacent to the second connection component 30 in the Z direction, and is connected to the second connection component 30 from the Z direction.

The second connection portion 62 may be a portion in contact with the coupling bus bar 75 for connection with another subunit SU instead of the connection components 20 and 30. In this case, the second connection portion 62 is a portion of the bus bar 42 that overlaps the coupling bus bar 75 when viewed from the Z direction. The second connection portion 62 is adjacent to the coupling bus bar 75 in the Z direction, and is connected to the coupling bus bar 75 from the Z direction.

The extending portion 63 extends from the first connection portion 61 in the X direction or the Y direction. The extending portion 63 is provided between the first connection portion 61 and the second connection portion 62. The extending portion 63 extends over the first connection portion 61 and the second connection portion 62. The extending portion 63 connects the first connection portion 61 to the second connection portion 62.

In the present embodiment, the first connection portion 61, the second connection portion 62, and the extending portion 63 have a plate shape formed in the horizontal direction. In the present embodiment, each bus bar 42 is accommodated in the accommodation portion 55 at least over the first connection portion 61 and the second connection portion 62 and extends along the flat surface portion 51. For example, the first connection portion 61, the second connection portion 62, and the extending portion 63 are accommodated in the accommodation portion 55 and extend along the flat surface portion 51.

In the present embodiment, the extending portions 63 of some of the bus bars 42 are accommodated in the accommodation portion 55 to extend over both sides of a region R through the region R overlapping the electronic component 10 when viewed from the Z direction. For example, the extending portion 63 extends linearly in the X direction. The extending portion 63 extends over a region R overlapping the electronic component 10 when viewed from the Z direction, over the +X direction side and the −X direction side of the region R. That is, the bus bar 42 is accommodated in the accommodation portion 55 to be easily routed through a better path (for example, a path with a shorter distance) without being disturbed by the presence of the electronic component 10.

The one or more bus bars 42 may have an extension 64 in addition to the first connection portion 61, the second connection portion 62, and the extending portion 63. The extension 64 is a portion where the bus bar 42 extends for the purpose of increasing a heat dissipation area and/or increasing a heat capacity for heat storage (heat absorption). The extension 64 is a portion that is not used for electrical connection. For example, the extension 64 is located on the side opposite to the extending portion 63 with respect to the first connection portion 61 (or the second connection portion 62). The extension 64 has a plate shape formed in the horizontal direction. The extension 64 is accommodated in the accommodation portion 55 and extends along the flat surface portion 51. The extension 64 extends to the region R overlapping the electronic component 10 when viewed from the Z direction, and has an end 42e1 of the bus bar 42 at a position overlapping the electronic component 10 when viewed from the Z direction.

Some routing examples of the bus bar 42 will be described below. The plurality of electronic components 10 include three electronic components 10A, 10B, and 10C. The electronic component 10A and the electronic component 10B are, for example, the first-type electronic component 10M. The electronic component 10C is, for example, the second-type electronic component 10N. Note that the type of the electronic component 10 is not limited to the above example. The plurality of connection components 20 include six connection components 20A, 20B, 20C, 20D, 20E, and 20F. The plurality of connection components 30 include two connection components 30A and 30B. The plurality of coupling bus bars 75 include two coupling bus bars 75A and 75B. The plurality of external connection bus bars 76 include two external connection bus bars 76A and 76B.

### First Routing Example

First, a routing example related to the bus bar 42A will be described. The bus bar 42A has the first connection portion 61, the second connection portion 62, and extending portion 63. The first connection portion 61 is located on the +X direction side with respect to the electronic component 10A when viewed from the Z direction. The first connection portion 61 is electrically connected to the terminal 13A of the electronic component 10A via the connection component 20A that is the first connection component 20. The second connection portion 62 is located on the −X direction side with respect to the electronic component 10A when viewed from the Z direction. The second connection portion 62 is electrically connected to another subunit SU via the coupling bus bar 75A.

The extending portion 63 is accommodated in the accommodation portion 55 to extend over both sides of the region R through the region R overlapping the electronic component 10A when viewed from the Z direction. For example, the extending portion 63 extends linearly in the X direction. The extending portion 63 extends over the region R overlapping the electronic component 10A when viewed from the Z direction, over the +X direction side and the −X direction side of the region R. The bus bar 42A is an example of a “first bus bar”. The accommodation portion 55A that accommodates the bus bar 42A is an example of a “first accommodation portion”. The bus bar 42A is, for example, a bus bar included in the positive electrode line PL included in the electrical connection unit 1.

### Second Routing Example

Next, a routing example related to the bus bar 42B will be described. The bus bar 42B has the first connection portion 61, the second connection portion 62, the extending portion 63, and the extension 64. The first connection portion 61 is electrically connected to the terminal 13B of the electronic component 10A via the connection component 20B that is the first connection component 20. The second connection portion 62 is electrically connected to the external connection bus bar 76A via the connection component 30A that is the second connection component 30. The extension 64 extends to the region R overlapping the electronic component 10A when viewed from the Z direction, and has an end 42e1 of the bus bar 42 at a position overlapping the electronic component 10A. Similarly to the bus bar 42A, the bus bar 42B may have an extending portion 63 that extends through the region R overlapping the electronic component 10 and over both sides of the region R when viewed from the Z direction. The bus bar 42B is another example of a “first bus bar”. The accommodation portion 55B that accommodates the bus bar 42B is another example of a “first accommodation portion”. From another point of view, the bus bar 42B is an example of a “second bus bar”. The accommodation portion 55B is another example of a “second accommodation portion”. The bus bar 42B is, for example, a bus bar included in the positive electrode line PL included in the electrical connection unit 1.

### Third Routing Example

Next, a routing example related to the bus bar 42C will be described. The bus bar 42C includes the first connection portion 61, the second connection portion 62, the extending portion 63, and the extension 64. The first connection portion 61 is electrically connected to the terminal 13B of the electronic component 10B via the connection component 20C that is the first connection component 20. The second connection portion 62 is electrically connected to another subunit SU via the coupling bus bar 75B. The extension 64 extends to the region R overlapping the electronic component 10B when viewed from the Z direction, and has an end 42e1 of the bus bar 42 at a position overlapping the electronic component 10B when viewed from the Z direction. The bus bar 42C is another example of a “first bus bar”. The accommodation portion 55C that accommodates the bus bar 42C is another example of a “first accommodation portion”. The bus bar 42C is, for example, a bus bar included in the negative electrode line NL included in the electrical connection unit 1. From another point of view, the bus bar 42C is an example of a “third bus bar”. The accommodation portion 55C is an example of a “third accommodation portion”.

### Fourth Routing Example

Next, a routing example related to the bus bar 42D will be described. The bus bar 42D has the first connection portion 61, the second connection portion 62, and the extending portion 63. The first connection portion 61 is electrically connected to the terminal 13A of the electronic component 10B via the connection component 20D that is the first connection component 20. The second connection portion 62 is electrically connected to the terminal 13B of the electronic component 10C via the connection component 20E that is the second connection component 20. The bus bar 42D is another example of a “first bus bar”. The accommodation portion 55D that accommodates the bus bar 42D is another example of a “first accommodation portion”. The bus bar 42D is, for example, a bus bar included in the negative electrode line NL included in the electrical connection unit 1. From another point of view, the bus bar 42D is another example of a “third bus bar”. The accommodation portion 55D is another example of a “third accommodation portion”.

### Fifth Routing Example

Next, a routing example related to the bus bar 42E will be described. The bus bar 42E has the first connection portion 61, the second connection portion 62, and the extending portion 63. The first connection portion 61 is electrically connected to the terminal 13A of the electronic component 10C via the connection component 20F that is the first connection component 20. The second connection portion 62 is electrically connected to the external connection bus bar 76B via the connection component 30B that is the second connection component 30. The bus bar 42E is another example of a “first bus bar”. The accommodation portion 55E that accommodates the bus bar 42E is another example of a “first accommodation portion”. The bus bar 42E is, for example, a bus bar included in the negative electrode line NL included in the electrical connection unit 1. From another point of view, the bus bar 42E is another example of a “third bus bar”. The accommodation portion 55E is another example of a “third accommodation portion”.

### (Fastening Member)

Next, referring to FIG. 9 again, the fastening member 43 will be described. The fastening member 43 is a component for fixing the bus bar 42 to a connection target component (the connection component 20, the connection component 30, the coupling bus bar 75, or a connection component 100) of the bus bar 42. The fastening member 43 is, for example, a caulking bolt fixed to the bus bar 42. The fastening member 43 is an example of a “fastening portion”.

In the present embodiment, each of the first connection portion 61 and the second connection portion 62 of the bus bar 42 has a through-hole 42h. The through-hole 42h penetrates the bus bar 42 in the Z direction. The fastening member 43 is, for example, a bolt having a shaft 43a and a head 43b. A circumferential surface of the shaft 43a has a screw groove. The head 43b has a diameter larger than that of the shaft 43a. The head 43b of the fastening member 43 is caulked and fixed to the bus bar 42 in a state in which the shaft 43a passes through the through-hole 42h of the bus bar 42. With this fixation, the fastening member 43 is electrically and physically connected to the bus bar 42 in a state in which the shaft 43a protrudes in the +Z direction from the through-hole 42h of the bus bar 42. The fastening member 43 is not limited to caulking fixation, and may be fixed to the bus bar 42 through welding or other methods.

In the present embodiment, the connection component 20 is attached to the fastening member 43 from the Z direction in a state of being previously fixed to the electronic component 10 via the fastening member 72 or the fastening member 71. For example, in the connection component 20, the shaft 43a of the fastening member 43 is inserted into the attachment hole 22h of the second portion 22. The engagement member 44 (for example, a nut) is engaged with the shaft 43a of the fastening member 43 protruding from the attachment hole 22h of the second portion 22 of the connection component 20. The engagement member 44 is attached to the shaft 43a in the Z direction, for example. This engagement fixes the second portion 22 of the connection component 20 to the fastening member 43.

### 4. Metal Plate, Insulating Sheet, Heat Transfer Member, and Insulating Cover

Next, the metal plate 80, the insulating sheet 91, the heat transfer member 92, and the insulating cover 93 will be described.

### <4.1 Metal Plate>

FIG. 11 is a partially exploded perspective view of the electrical connection unit 1. The metal plate 80 is a member for securing rigidity of the electrical connection unit 1 and enhancing a heat dissipation property of the electrical connection unit 1. The metal plate 80 is made of a metal (for example, aluminum or an aluminum alloy). The metal plate 80 may be referred to as a “rigid member”.

The metal plate 80 has a rectangular shape formed in the X direction when viewed from the Z direction. The metal plate 80 has a first end 80e1, a second end 80e2, a third end 80e3, and a fourth end 80e4. The first end 80e1 and the second end 80e2 are a pair of ends of the metal plate 80 in the longitudinal direction, and are separated in the X direction. The third end 80e3 and the fourth end 80e4 are a pair of ends of the metal plate 80 in the lateral direction, and are separated in the Y direction. The metal plate 80 includes, for example, a flat surface portion 81, a plurality of fixing portions 82, and a plurality of fixing portions 83.

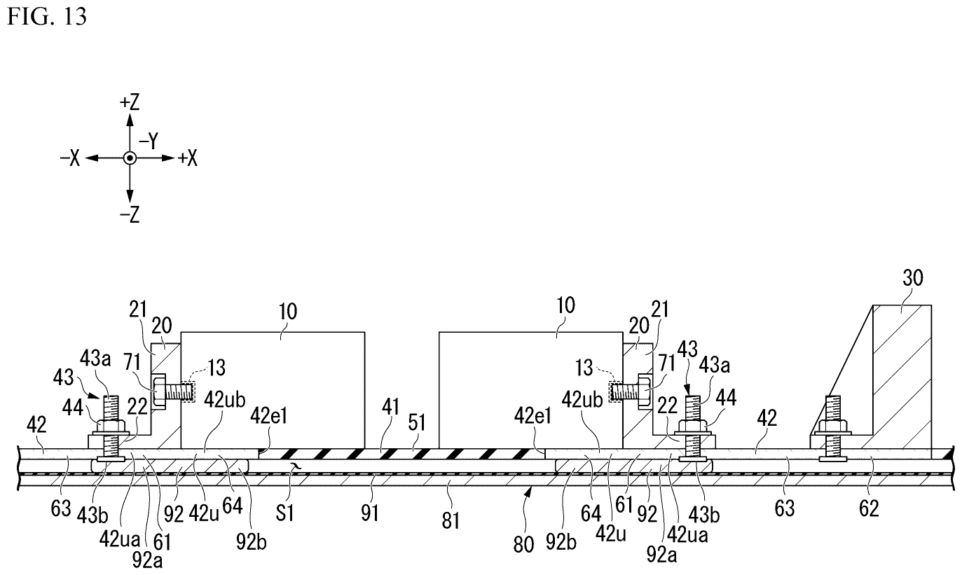

The flat surface portion 81 is a portion formed in a plate shape in the metal plate 80. The flat surface portion 81 has a plate shape formed in the horizontal direction. The flat surface portion 81 forms a main portion of the metal plate 80. The flat surface portion 81 forms a base portion (metal base portion) of the metal plate 80. In the present embodiment, the flat surface portion 81 has a size that covers the three subunits SU from below. The flat surface portion 81 faces the routing boards 40 of the three subunits SU. In the present embodiment, the metal plate 80 forms a gap S1 (see FIG. 13) with the second surface 51b of the flat surface portion 51 of each subunit SU, and faces the second surface 51b of the flat surface portion 51 of each subunit SU. The gap S1 is an example of a “first gap”.

The fixing portion 82 is a fixing portion for fixing the base plate 41 of each subunit SU to the metal plate 80. The fixing portion 82 is provided at a position corresponding to the fixing portion 52 of the base plate 41 of each subunit SU when viewed from the Z direction. The fixing portion 82 is a cylindrical or prismatic boss protruding in the +Z direction from the flat surface portion 81 of the metal plate 80. The fixing portion 82 will be described in detail later.

The fixing portion 83 is a fixing portion for directly fixing the electronic component 10 of each subunit SU to the metal plate 80 without interposing the base plate 41. The fixing portion 83 is provided at a position corresponding to the attachment portion 14 of the electronic component 10 of each subunit SU when viewed from the Z direction. The fixing portion 83 is a cylindrical or prismatic boss protruding in the +Z direction from the flat surface portion 81. The fixing portion 83 will be described in detail later.

### <4.2 Insulating Sheet>

The insulating sheet 91 is an insulating member for electrically insulating the metal plate 80 and the bus bar 42 of each subunit SU. The insulating sheet 91 is made of, for example, a synthetic resin such as polyester or polyimide, and has an insulating property. The insulating sheet 91 has a rectangular shape when viewed from the Z direction. The insulating sheet 91 has a sheet shape formed in the horizontal direction. The insulating sheet 91 is disposed between the flat surface portion 81 of the metal plate 80 and the routing board 40 of each subunit SU. For example, the insulating sheet 91 is disposed between the flat surface portion 81 of the metal plate 80 and the plurality of heat transfer members 92.

In the present embodiment, the insulating sheet 91 is attached to the flat surface portion 81 of the metal plate 80. The insulating sheet 91 has a notch or an opening for avoiding the fixing portion 82 and the fixing portion 83 of the metal plate 80. Note that, instead of the above example, the insulating sheet 91 may be provided between the routing board 40 of each subunit SU and the plurality of heat transfer members 92. Note that, in a case where the heat transfer member 92 has an insulating property and the necessary insulating property is secured by the heat transfer member 92, the insulating sheet 91 may be omitted.

### <4.3 Heat Transfer Member>

The heat transfer member 92 is a member for transferring heat generated by the electronic component 10 at the time of energization and/or heat (Joule heat) generated by the bus bar 42 itself at the time of energization to the metal plate 80. The heat transfer member 92 is, for example, a heat transfer sheet (for example, a thermally conductive silicone sheet) having elasticity. The heat transfer member 92 is made of a material having higher thermal conductivity than that of the base plate 41, for example. However, the heat transfer member 92 is not limited to the above example, and may be a heat transfer member made of a thermally conductive gel or another material.

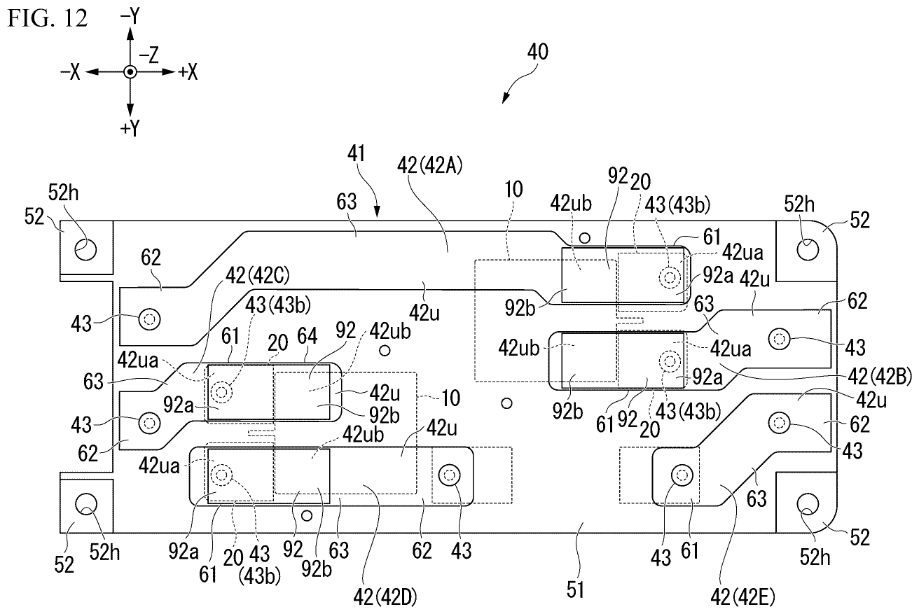

FIG. 12 is a bottom view illustrating the routing board 40. In the present embodiment, the plurality of heat transfer members 92 are partially provided in the routing board 40. For example, the plurality of heat transfer members 92 are disposed at positions overlapping part of the bus bar 42 when viewed from the Z direction. More specifically, the plurality of heat transfer members 92 are disposed at positions overlapping part of the bus bar 42 in the vicinity of the electronic component 10 (for example, the electronic components 10A and 10B) when viewed from the Z direction. In the present embodiment, the plurality of heat transfer members 92 are disposed at 5 positions overlapping the connection component 20 when viewed from the Z direction.

FIG. 13 is a cross-sectional view taken along line F13-F13 of the structure illustrated in FIG. 10. In the present embodiment, the heat transfer member 92 is disposed between the metal plate 80 and the bus bar 42. The heat transfer member 92 transfers heat transferred from the electronic component 10 to the bus bar 42 and/or heat generated by the bus bar 42 from the bus bar 42 to the metal plate 80.

In the present embodiment, part of the heat transfer member 92 is in contact with the bus bar 42 at a position overlapping the connection component 20 when viewed from the Z direction. In this case, the heat transfer member 92 easily transfers the heat transferred from the terminal 13 of the electronic component 10 to the connection component 20 from the connection component 20 to the metal plate 80 via the bus bar 42.

In the present embodiment, part of the heat transfer member 92 is disposed at a position overlapping the head 43b of the fastening member 43 when viewed from the Z direction, and is in contact with the head 43b of the fastening member 43. In this case, the heat transfer member 92 easily transfers the heat transferred from the terminal 13 of the electronic component 10 to the connection component 20 from the fastening member 43 to the metal plate 80.

In the present embodiment, part of the heat transfer member 92 is in contact with the bus bar 42 at a position overlapping the electronic component 10 when viewed from the Z direction. In this case, the heat transfer member 92 easily transfers the heat transferred from the electronic component 10 to the bus bar 42 from the bus bar 42 to the metal plate 80. In the example illustrated in FIG. 13, the upper surface of the bus bar 42 is in contact with the electronic component 10, and thus the bus bar 42 is thermally connected to the electronic component 10. Note that the bus bar 42 may be thermally connected to the electronic component 10 at the extending portion 63 or the extension 64.

### Modification Example

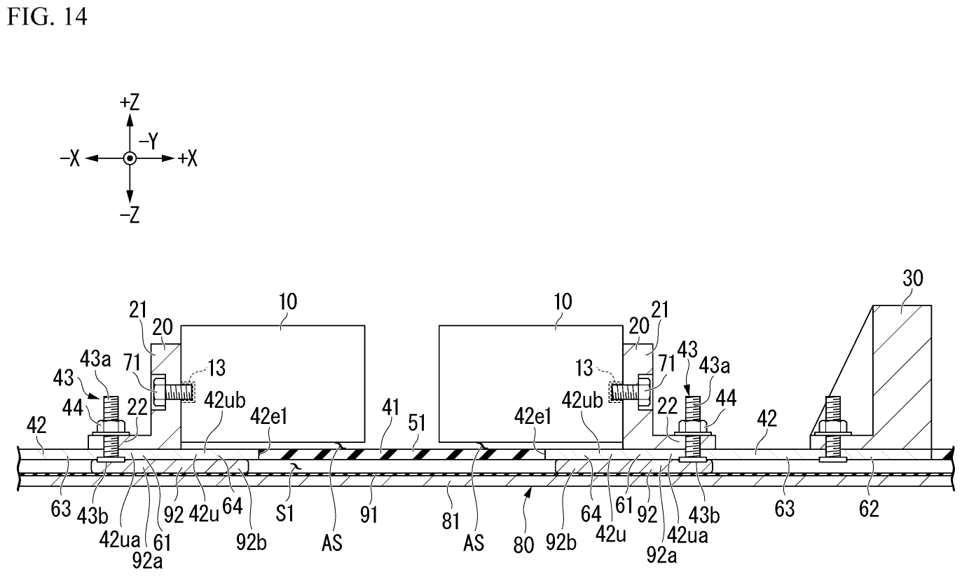

FIG. 14 is a cross-sectional view illustrating one modification example. In the present modification example, an air layer AS that is a gap exists between the bus bar 42 and the electronic component 10. The bus bar 42 is thermally connected to the electronic component 10 via the air layer AS. According to this constitution, the heat generated by the electronic component 10 is moved to the bus bar 42 through the air layer AS. The heat moved to the bus bar 42 is moved to the metal plate 80 via the heat transfer member 92 and dissipated.

### Modification Example

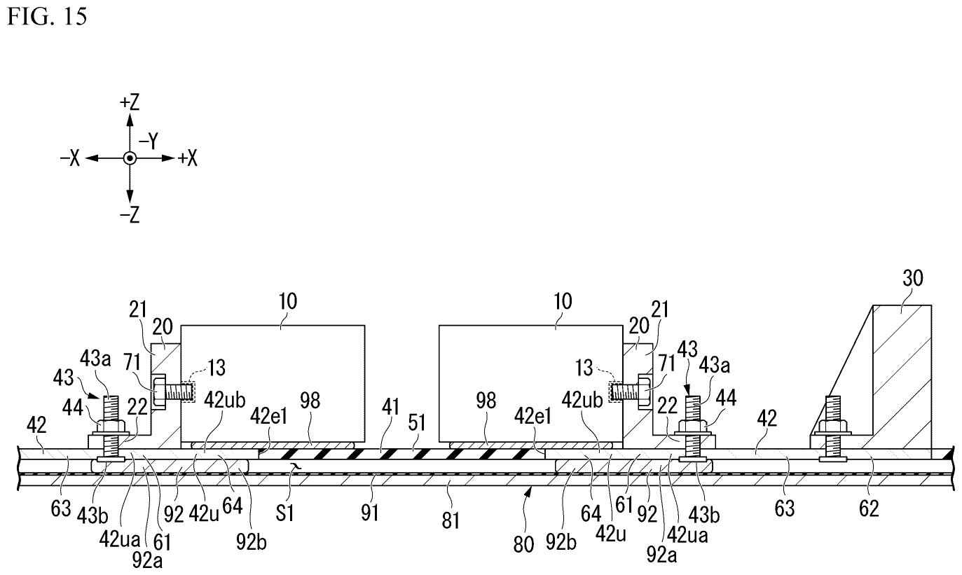

FIG. 15 is a cross-sectional view illustrating another modification example. In the present modification example, a heat transfer member 98 is provided between the bus bar 42 and the electronic component 10. The heat transfer member 98 is interposed between the bus bar 42 and the electronic component 10 in the Z direction. The bus bar 42 is thermally connected to the electronic component 10 via the heat transfer member 98. The heat transfer member 98 transfers heat generated by the electronic component 10 to the bus bar 42. The heat transfer member 98 is, for example, a heat transfer sheet (for example, a thermally conductive silicone sheet) having elasticity. However, the heat transfer member 98 is not limited to the above example, and may be a heat transfer member made of a thermally conductive gel or another material. According to this constitution, heat generated by the electronic component 10 is efficiently moved to the bus bar 42 via the heat transfer member 98. The heat moved to the bus bar 42 is moved to the metal plate 80 via the heat transfer member 92 and dissipated.

### <4.4 Insulating Cover>

Referring to FIG. 1 again, the insulating cover 93 will be described. The insulating cover 93 is a member for preventing the main body MU from contacting the energization path. The insulating cover 93 is made of, for example, a synthetic resin and has an insulating property. The insulating cover 93 has, for example, a box shape that is open on the −Z direction side. The insulating cover 93 has a plurality of vent holes 93h. The insulating cover 93 is attached to the metal plate 80 in the Z direction. Note that the insulating cover 93 is not limited to a box-shaped member, and may be a sheet-shaped member that covers the energization path of the main body MU.

### 5. Exposure Structure of Bus Bar

Next, an exposure structure of the bus bar 42 will be described.

### <5.1 Exposure Structure on Upper Surface Side of Bus Bar>

First, an exposure structure on the upper surface side of the bus bar 42 will be described with reference to FIG. 8. In the present embodiment, at least part of the extending portion 63 of the bus bar 42 is exposed to the outside of the base plate 41 on the upper surface side (the first surface 51a side of the flat surface portion 51). For example, the extending portion 63 of the bus bar 42 is exposed to the outside of the base plate 41 on the upper surface side at least in part of the region R (see FIG. 10) overlapping the electronic component 10 when viewed from the Z direction.

In the present embodiment, the bus bar 42 is accommodated in the accommodation portion 55 at least over the entire length between the first connection portion 61 and the second connection portion 62 and extends along the first surface 51a of the flat surface portion 51. The bus bar 42 is exposed to the outside of the base plate 41 on the upper surface side at least over the entire length between the first connection portion 61 and the second connection portion 62.

In the present embodiment, the bus bar 42 is accommodated in the accommodation portion 55 over the entire length of the bus bar 42 and extends along the first surface 51a of the flat surface portion 51. The bus bar 42 is exposed to the outside of the base plate 41 on the upper surface side over the entire length of the bus bar 42.

As illustrated in FIG. 13, at least part of the extending portion 63 of the bus bar 42 is exposed to the outside of the base plate 41 not only on the upper surface side but also on the lower surface side (second surface 51b side). For example, the bus bar 42 is exposed to the outside of the base plate 41 on the lower surface side over the entire length of the bus bar 42.

### Modification Example

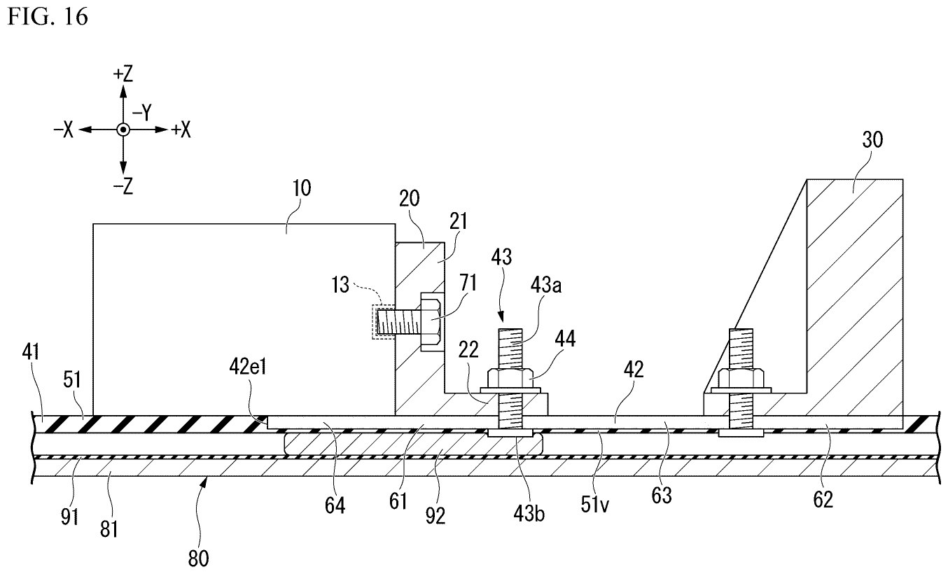

FIG. 16 is a cross-sectional view illustrating one modification example. In the present modification example, the flat surface portion 51 of the base plate 41 has a cover portion 51v that covers at least part of the extending portion 63 of the bus bar 42 on the lower surface side (second surface 51b side). In the region covered by the cover portion 51v, the bus bar 42 is not exposed to the lower surface side. The cover portion 51v may be provided over the entire length of the bus bar 42. Note that the cover portion 51v need not be provided, for example, in a region overlapping the heat transfer member 92 when viewed from the Z direction.

### <5.2 Exposure Structure on Lower Surface Side of Bus Bar>

Next, an exposure structure on the lower surface side of the bus bar 42 will be described with reference to FIG. 13. In the present embodiment, the plate portion 42p of the bus bar 42 includes an exposed portion 42u exposed to the outside of the base plate 41 on the lower surface side (the second surface 51b side of the flat surface portion 51). In the present embodiment, the exposed portion 42u of the bus bar 42 extends over the entire length of the bus bar 42. In the present embodiment, the heat transfer member 92 is disposed between the exposed portion 42u of the bus bar 42 and the metal plate 80. For example, the heat transfer member 92 is in contact with the exposed portion 42u of the bus bar 42.

In the present embodiment, at least part of the exposed portion 42u of the bus bar 42 is provided in a region overlapping the connection component 20 when viewed from the Z direction. At least part of the heat transfer member 92 overlaps the exposed portion 42u of the bus bar 42 in a region overlapping the connection component 20 when viewed from the Z direction. For example, at least part of the heat transfer member 92 is in contact with the exposed portion 42u of the bus bar 42 in a region overlapping the connection component 20 when viewed from the Z direction.

In the present embodiment, the exposed portion 42u of the bus bar 42 includes a first portion 42ua disposed in a region overlapping the connection component 20 when viewed from the Z direction and a second portion 42ub disposed in a region overlapping the electronic component 10 when viewed from the Z direction.

The heat transfer member 92 includes a first heat transfer portion 92a and a second heat transfer portion 92b. The first heat transfer portion 92a overlaps the first portion 42ua of the exposed portion 42u of the bus bar 42 in a region overlapping the connection component 20 when viewed from the Z direction. For example, the first heat transfer portion 92a is in contact with the first portion 42ua of the exposed portion 42u of the bus bar 42. On the other hand, the second heat transfer portion 92b overlaps the second portion 42ub of the exposed portion 42u of the bus bar 42 in a region overlapping the electronic component 10 when viewed from the Z direction. For example, the second heat transfer portion 92b is in contact with the second portion 42ub of the exposed portion 42u of the bus bar 42.

As described above, at least part of the extending portion 63 of the bus bar 42 is exposed to the outside of the base plate 41 not only on the lower surface side but also on the upper surface side (first surface 51a side). For example, the bus bar 42 is exposed to the outside of the base plate 41 on the upper surface side over the entire length of the bus bar 42. For example, the second portion 42ub of the exposed portion 42u of the bus bar 42 is exposed to the outside of the base plate 41 not only on the lower surface side but also on the upper surface side, and faces the electronic component 10.

### Modification Example

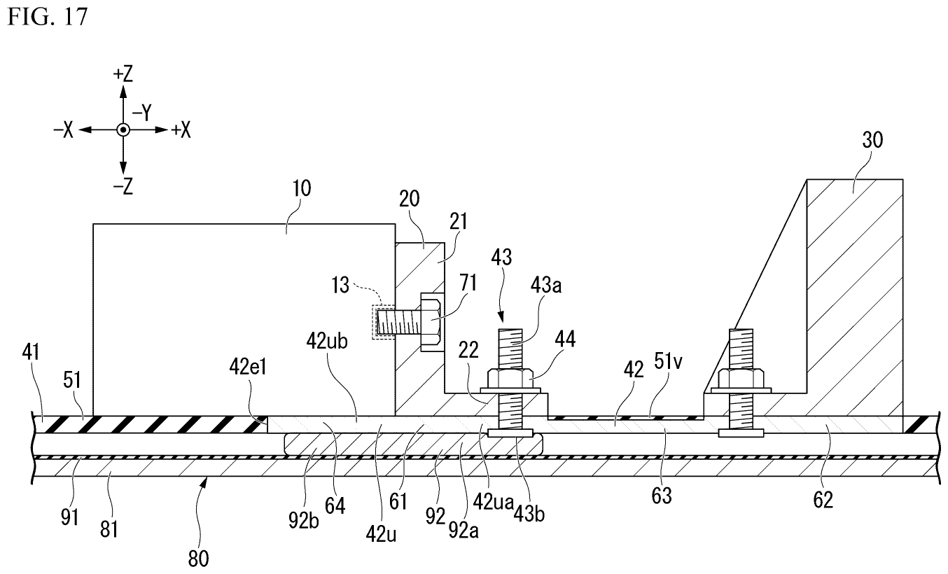

FIG. 17 is a cross-sectional view illustrating one modification example. In the present modification example, the flat surface portion 51 of the base plate 41 has a cover portion 51v that covers at least part of the extending portion 63 of the bus bar 42 on the upper surface side (first surface 51a side). In the region covered by the cover portion 51v, the bus bar 42 is not exposed to the upper surface side. Note that the cover portion 51v may be provided over the entire length of the bus bar 42. Note that the cover portion 51v need not be provided, for example, in a region overlapping the first connection portion 61 and the second connection portion 62 when viewed from the Z direction.

### 6. Three-Dimensional Routing Structure of Bus Bar

Next, a three-dimensional routing structure CS of the bus bar 42 will be described.

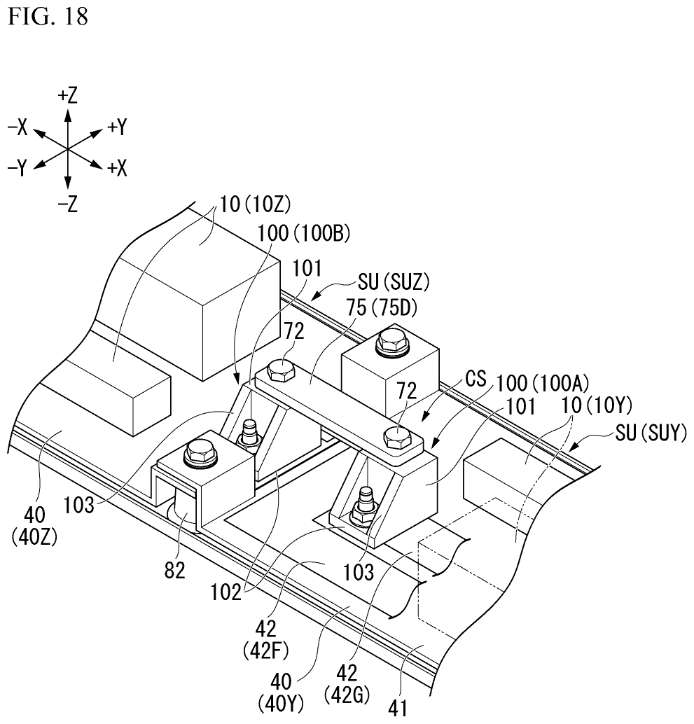

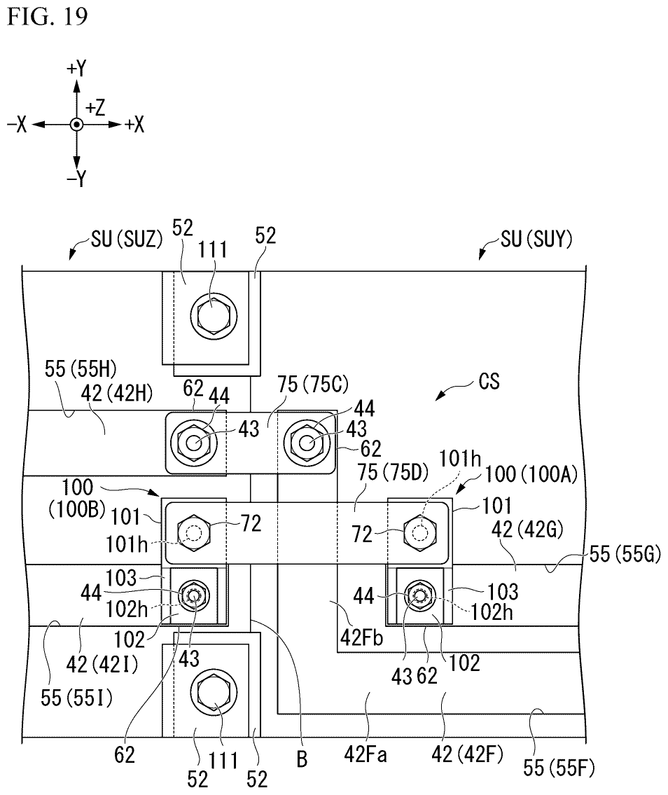

FIG. 18 is a perspective view illustrating the three-dimensional routing structure CS of the bus bar 42. FIG. 19 is a plan view illustrating the three-dimensional routing structure CS of the bus bar 42. The three-dimensional routing structure CS includes a bus bar 42F, a bus bar 42G, a bus bar 42H, and a bus bar 42I as the plurality of bus bars 42. In addition, the three-dimensional routing structure CS includes a plurality of connection components 100. In addition, the three-dimensional routing structure CS includes a coupling bus bar 75C and a coupling bus bar 75D as the plurality of coupling bus bars 75.

The bus bar 42F and the bus bar 42G are, for example, the bus bars 42 included in the subunit SUY. The flat surface portion 51 of the base plate 41 of the subunit SUY includes an accommodation portion 55F and an accommodation portion 55G as the plurality of accommodation portions 55. The bus bar 42F is accommodated in the accommodation portion 55F and extends along the flat surface portion 51. The bus bar 42G is accommodated in the accommodation portion 55G and extends along the flat surface portion 51. The bus bar 42F is an example of a “first bus bar”. The accommodation portion 55F that accommodates the bus bar 42F is an example of a “first accommodation portion”. The bus bar 42G is an example of a “fourth bus bar”. The accommodation portion 55G that accommodates the bus bar 42G is an example of a “fourth accommodation portion”. The bus bar 42F and the bus bar 42G are the bus bars 42 located in the first layer (lower layer) in the three-dimensional routing structure CS.

In the present embodiment, the bus bar 42F includes a first portion 42Fa extending in the X direction and a second portion 42Fb bent from the first portion 42Fa and extending in the Y direction. The second portion 42Fb extends along a boundary B between the subunit SUY and the subunit SUZ.

On the other hand, the bus bar 42H and the bus bar 42I are, for example, the bus bars 42 included in the subunit SUZ. The flat surface portion 51 of the base plate 41 of the subunit SUZ includes an accommodation portion 55H and an accommodation portion 55I as the plurality of accommodation portions 55. The bus bar 42H is accommodated in the accommodation portion 55H and extends along the flat surface portion 51. The bus bar 42I is accommodated in the accommodation portion 55I and extends along the flat surface portion 51. The bus bar 42H and the bus bar 42I are the bus bars 42 located in the first layer (lower layer) in the three-dimensional routing structure CS.

The connection component 100 has the same constitution as the connection component 30 for external connection described above. For example, the connection component 100 has a first portion 101, a second portion 102, and a third portion 103. For details of the connection component 100, in the above description regarding the connection component 30, the “connection component 30” may be replaced with the “connection component 100”, the “first portion 31” may be replaced with the “first portion 101”, the “first attachment hole 31h” may be replaced with the “first attachment hole 101h”, the “second portion 32” may be replaced with the “second portion 102”, the “second attachment hole 32h” may be replaced with the “second attachment hole 102h”, and the “third portion 33” may be replaced with the “third portion 103”. The connection component 100 is a member forming an energization path in the vertical direction. The connection component 100 may be referred to as a “vertical routing member”.

The plurality of connection components 100 include a connection component 100A and a connection component 100B. The connection component 100A overlaps the second connection portion 62 of the bus bar 42G in the subunit SUY when viewed from the Z direction. The connection component 100A is adjacent to the second connection portion 62 of the bus bar 42G in the Z direction, and is connected to the second connection portion 62 of the bus bar 42G from the Z direction. The connection component 100A stands in the +Z direction from the bus bar 42G. The connection component 100A is an example of a “third connection component”.

The connection component 100B overlaps the second connection portion 62 of the bus bar 42I in the subunit SUZ when viewed from the Z direction. The connection component 100B is adjacent to the second connection portion 62 of the bus bar 42I in the Z direction, and is connected to the second connection portion 62 of the bus bar 42I from the Z direction. The connection component 100B stands in the +Z direction from the bus bar 42I.

One end of the coupling bus bar 75C is adjacent to the second connection portion 62 of the bus bar 42F in the Z direction and is connected to the second connection portion 62 of the bus bar 42F from the Z direction in the subunit SUY. The other end of the coupling bus bar 75C is adjacent to the second connection portion 62 of the bus bar 42H in the Z direction and is connected to the second connection portion 62 of the bus bar 42H from the Z direction in the subunit SUZ. With this constitution, the bus bar 42F of the subunit SUY and the bus bar 42H of the subunit SUZ are electrically connected via the coupling bus bar 75C. The coupling bus bar 75C is the bus bar 75 located in the first layer (lower layer) in the three-dimensional routing structure CS.

On the other hand, in the subunit SUY, the coupling bus bar 75D is adjacent to the first portion 101 of the connection component 100A in the Z direction, and is connected to the first portion 101 of the connection component 100A from the Z direction. The other end of the coupling bus bar 75D is adjacent to the first portion 101 of the connection component 100B in the Z direction in the subunit SUZ, and is connected to the first portion 101 of the connection component 100B from the Z direction.

The coupling bus bar 75D is supported by the first portion 101 of the connection component 100A and the first portion 101 of the connection component 100B at a position away from the bus bar 42F in the Z direction. The coupling bus bar 75D is supported by the first portion 101 of the connection component 100A and the first portion 101 of the connection component 100B, and extends in the horizontal direction (for example, the X direction). The coupling bus bar 75D is electrically connected to the first portion 101 of the connection component 100A and the first portion 101 of the connection component 100B. With this constitution, the bus bar 42F of the subunit SUY and the bus bar 42I of the subunit SUZ are electrically connected via the two connection components 100 and the coupling bus bar 75D. The coupling bus bar 75D is an example of a “fifth bus bar”.

In the present embodiment, the coupling bus bar 75D extends to straddle the second portion 42Fb of the bus bar 42F at a position away from the bus bar 42F in the +Z direction. As a result, a three-dimensional intersecting structure is formed by the coupling bus bar 75D and the bus bar 42F. In the present embodiment, the coupling bus bar 75D extends to straddle the boundary B of the plurality of subunits SU.

In the present embodiment, the three-dimensional routing structure CS of the bus bar 42 is provided at a position of straddling the boundary B of the plurality of subunits SU. According to such a disposition, the coupling structure between the plurality of subunits SU is reinforced by the three-dimensional routing structure CS. Note that the three-dimensional routing structure CS of the bus bar 42 may be provided inside one or more subunits SU instead of being provided at the boundary B of the plurality of subunits SU.

### 7. Fixing Structure

Next, a fixing structure of the subunit SU will be described.

### <7.1 Structure of Metal Plate>

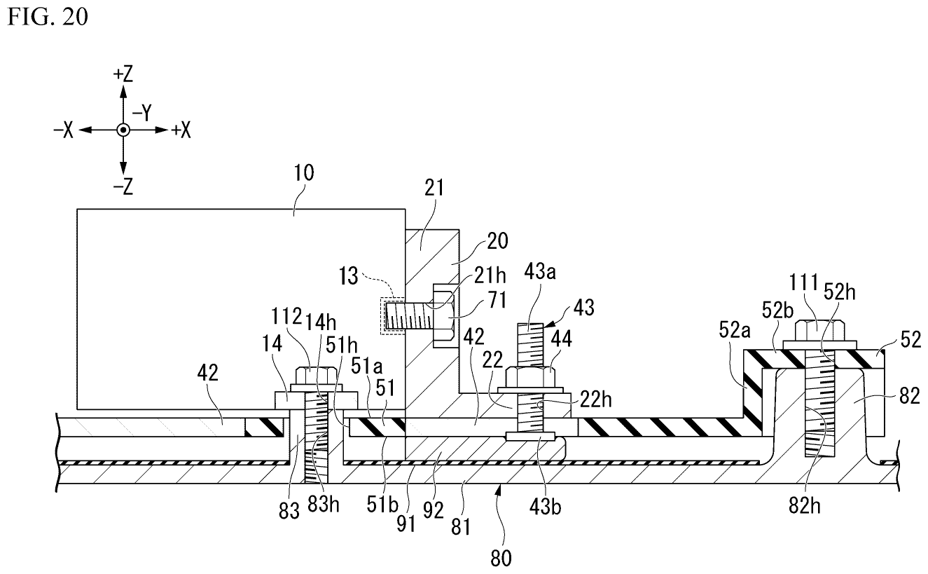

FIG. 20 is a cross-sectional view taken along line F20-F20 of the structure illustrated in FIG. 10. As described above, the metal plate 80 includes the fixing portion 82 and the fixing portion 83.

The fixing portion 82 is a boss protruding in the +Z direction from the flat surface portion 81 of the metal plate 80. For example, the fixing portion 82 protrudes to the +Z direction side from the first surface 51a of the flat surface portion 51 of the base plate 41. In the present embodiment, the fixing portion 82 protrudes more in the +Z direction than the fixing portion 83 that will be described later. The fixing portion 82 faces the fixing portion 52 of the base plate 41 in the Z direction. The fixing portion 82 has an engagement hole 82h that is open in the +Z direction. An inner circumferential surface of the engagement hole 82h has a screw groove. The fixing portion 82 is an example of a “first fixing portion”. The engagement hole 82h is an example of a “first engagement hole”.

The fixing portion 83 is a boss protruding in the +Z direction from the flat surface portion 81. The fixing portion 83 is inserted into a through-hole 51h (that will be described later) of the flat surface portion 51 of the base plate 41. For example, the fixing portion 83 passes through the through-hole 51h of the flat surface portion 51 and protrudes to the same position as the first surface 51a of the flat surface portion 51 or protrudes beyond a position of the first surface 51a of the flat surface portion 51 (a position on the +Z direction side with respect to the first surface 51a). The fixing portion 83 faces the attachment portion 14 of the electronic component 10 in the Z direction. The fixing portion 83 has an engagement hole 83h that is open in the +Z direction. An inner circumferential surface of the engagement hole 83h has a screw groove. The fixing portion 83 is an example of a “second fixing portion”. The engagement hole 83h is an example of a “second engagement hole”.

A fastening member 112 (for example, a screw or a bolt) passes through the attachment hole 14h of the attachment portion 14 of the electronic component 10 from the +Z direction side. When the fastening member 112 that has passed through the attachment hole 14h of the attachment portion 14 of the electronic component 10 is engaged with the engagement hole 83h of the fixing portion 83 of the metal plate 80, the electronic component 10 is fixed to the metal plate 80 without interposing the base plate 41. The fastening member 112 is an example of a “second fastening member”.

### <7.2 Structure of Routing Board>

The base plate 41 has the fixing portion 52 fixed to the fixing portion 82 of the metal plate 80. The fixing portion 52 includes, for example, a standing plate portion 52a and a horizontal plate portion 52b.

The standing plate portion 52a stands in the +Z direction from the end of the flat surface portion 51 of the base plate 41. The standing plate portion 52a is a plate portion provided in the Y direction and the Z direction. The thickness direction of the standing plate portion 52a is the X direction.

The horizontal plate portion 52b extends in the horizontal direction from the end of the standing plate portion 52a in the +Z direction. The horizontal plate portion 52b is a plate portion provided in the horizontal direction. The horizontal plate portion 52b faces the fixing portion 82 of the metal plate 80 in the Z direction. The horizontal plate portion 52b has an insertion hole 52h facing the engagement hole 82h of the fixing portion 82 of the metal plate 80. A fastening member 111 (for example, a screw or a bolt) passes through the insertion hole 52h. When the fastening member 111 that has passed through the insertion hole 52h of the fixing portion 52 of the base plate 41 is engaged with the engagement hole 82h of the fixing portion 82 of the metal plate 80, the base plate 41 is fixed to the metal plate 80. The fastening member 111 is an example of a “first fastening member”.

The flat surface portion 51 of the base plate 41 has the above-described through-hole 51h. The through-hole 51h penetrates the flat surface portion 51 in the Z direction. The through-hole 51h is provided at a position corresponding to the fixing portion 83 of the metal plate 80 when viewed from the Z direction. The fixing portion 83 of the metal plate 80 passes through the through-hole 51h of the base plate 41 and protrudes to the same position as the first surface 51a of the flat surface portion 51 or to the +Z direction side with respect to the first surface 51a of the flat surface portion 51. The attachment portion 14 of the electronic component 10 is fixed to the fixing portion 83 at the same position as the first surface 51a of the flat surface portion 51 or at a position on the +Z direction side with respect to the first surface 51a of the flat surface portion 51.

### 8. Heat Dissipation Path Related to Fixing Structure

Next, a heat dissipation path related to the fixing portion 83 of the metal plate 80 will be described.

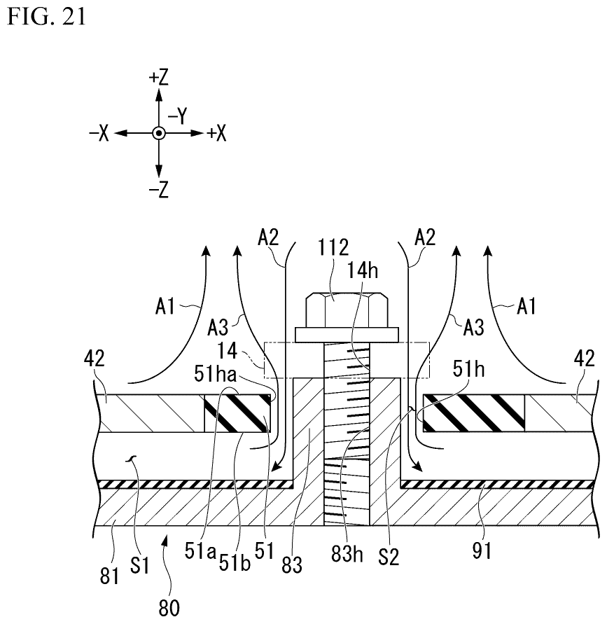

FIG. 21 is a cross-sectional view for describing a heat dissipation path related to the fixing portion 83 of the metal plate 80. In the present embodiment, the fixing portion 83 of the metal plate 80 is not in contact with a high-temperature portion (for example, the terminal 13) of the electronic component 10. In the present embodiment, a gap S2 through which air can pass is provided between the inner circumferential surface 51ha of the through-hole 51h of the base plate 41 and the fixing portion 83. For example, the through-hole 51h may be largely open such that part of the through-hole 51h does not overlap the attachment portion 14 of the electronic component 10 when viewed from the Z direction (such that part of the through-hole 51h is located on the outer peripheral side of the attachment portion 14 when viewed from the Z direction). The fixing portion 83 is an example of a “protruding portion”.

In the present embodiment, the temperature of the fixing portion 83 of the metal plate 80 tends to be lower than the temperature of the bus bar 42. In this case, convection occurs due to a temperature difference between the fixing portion 83 (low temperature) of the metal plate 80 and the bus bar 42 (high temperature).

Specifically, in response to generation of an upward flow of warm air (see an arrow A1) around the bus bar 42, a downward flow (see an arrow A2) passing through the through-hole 51h of the base plate 41 and directed downward from the base plate 41 is generated around the fixing portion 83 of the metal plate 80. In a case where the downward flow is generated, an upward flow (see an arrow A3) is generated by being pushed out by air moving in the downward flow. This upward flow is generated near the inner circumferential surface 51ha of the through-hole 51h to move warm air in the gap S1 between the metal plate 80 and the base plate 41 upward (outside the gap S1). As a result, the warm air is prevented from being confined in the gap S1 between the metal plate 80 and the base plate 41, and the heat dissipation of the electrical connection unit 1 is promoted.

### Modification Example

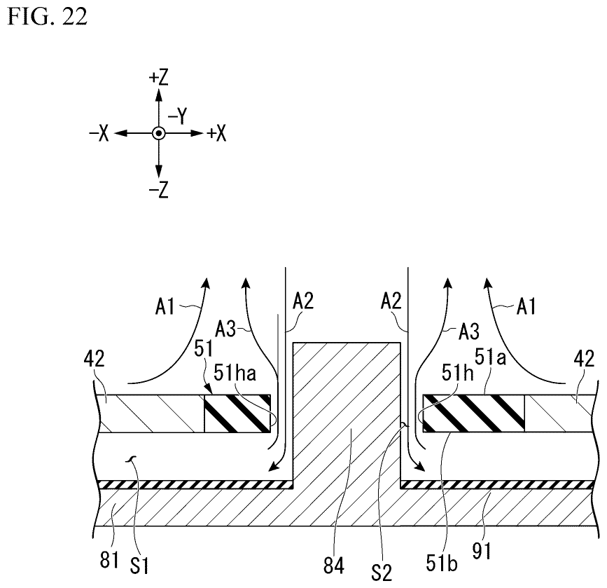

FIG. 22 is a cross-sectional view for describing a modification example of a heat dissipation path. In the present modification example, the metal plate 80 has a protruding portion 84 instead of/in addition to the fixing portion 83. The protruding portion 84 is a protruding portion for heat dissipation. The protruding portion 84 need not be used for the fixing structure. The protruding portion 84 is a cylindrical or prismatic boss protruding in the +Z direction from the flat surface portion 81 of the metal plate 80. The protruding portion 84 is inserted into the through-hole 51h of the flat surface portion 51 of the base plate 41. For example, the protruding portion 84 passes through the through-hole 51h of the flat surface portion 51 and protrudes to the same position as the first surface 51a of the flat surface portion 51 or protrudes beyond a position of the first surface 51a of the flat surface portion 51 (a position on the +Z direction side with respect to the first surface 51a).

According to the constitution of the present modification example, the temperature of the protruding portion 84 of the metal plate 80 tends to be lower than the temperature of the bus bar 42. In this case, convection occurs due to a temperature difference between the protruding portion 84 (low temperature) of the metal plate 80 and the bus bar 42 (high temperature). As a result, air flows indicated by the arrows A1 to A3 described above are generated, and heat dissipation of the electrical connection unit 1 is promoted.

### 9. Absorption Structure for Thermal Expansion/Contraction Related to Fixing Structure

Next, an absorption structure for thermal expansion/contraction related to the fixing structure will be described.

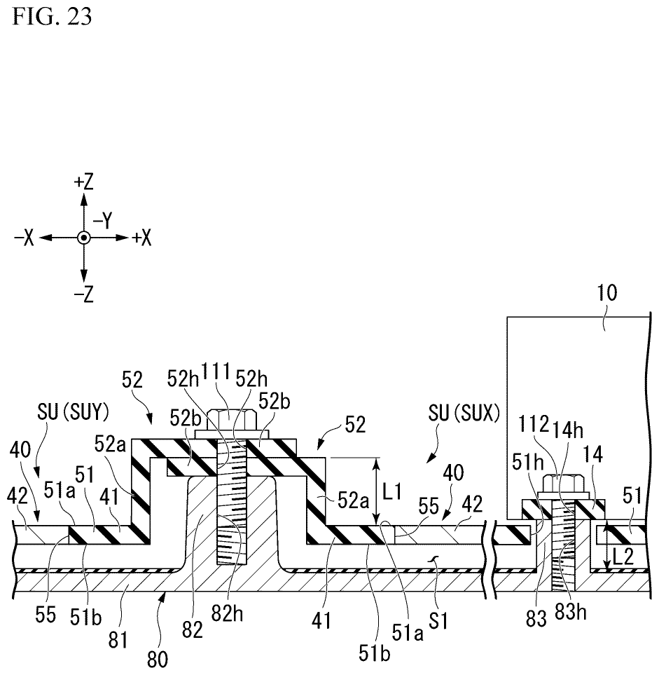

FIG. 23 is a cross-sectional view for describing an absorption structure for thermal expansion/contraction related to the fixing portion 82. In the present embodiment, the routing board 40 of the subunit SUX includes the base plate 41 and the bus bar 42. The flat surface portion 51 of the base plate 41 has the accommodation portion 55 that accommodates the bus bars 42. The fixing portion 52 of the base plate 41 includes the standing plate portion 52a standing in the Z direction from the flat surface portion 51, and the horizontal plate portion 52b extending in the horizontal direction from the +Z direction end of the standing plate portion 52a. The horizontal plate portion 52b is disposed at a position different from the first surface 51a in the Z direction. The horizontal plate portion 52b has the insertion hole 52h through which the fastening member 111 passes. The horizontal plate portion 52b is fixed to the fixing portion 82 of the metal plate 80 via the fastening member 111.

The metal plate 80 has the fixing portion 83 that protrudes from the flat surface portion 81 of the metal plate 80, is inserted into the through-hole 51h of the base plate 41, and to which the electronic component 10 is fixed. A length L1 of the standing plate portion 52a in the Z direction is larger than a length L2 of the fixing portion 83 in the Z direction.

The bus bar 42 of the subunit SUX is an example of a “first bus bar”. The base plate 41 of the subunit SUX is an example of a “first base member”. The flat surface portion 51 of the subunit SUX is an example of a “first flat surface portion”. The standing plate portion 52a of the subunit SUX is an example of a “first portion”. The horizontal plate portion 52b of the subunit SUX is an example of a “second portion”. The fixing portion 82 of the metal plate 80 is an example of a “first fixing portion”. The fixing portion 83 of the metal plate 80 is an example of a “second fixing portion”.

In the present embodiment, the routing board 40 of the subunit SUY includes the base plate 41 and the bus bar 42. The flat surface portion 51 of the base plate 41 has the accommodation portion 55 that accommodates the bus bars 42. The fixing portion 52 of the base plate 41 includes the standing plate portion 52a standing in the Z direction from the flat surface portion 51, and the horizontal plate portion 52b extending in the horizontal direction from the +Z direction end of the standing plate portion 52a. The horizontal plate portion 52b is disposed at a position different from the first surface 51a in the Z direction. The horizontal plate portion 52b of the base plate 41 of the subunit SUY overlaps the base plate 41 and the horizontal plate portion 52b of the subunit SUX. The horizontal plate portion 52b of the base plate 41 of the subunit SUY has the insertion hole 52h through which the fastening member 111 passes. The horizontal plate portion 52b of the base plate 41 of the subunit SUY is fastened to the fixing portion 82 of the metal plate 80 via the fastening member 111 together with the base plate 41 and the horizontal plate portion 52b of the subunit SUX.

The bus bar 42 of the subunit SUY is an example of a “second bus bar”. The base plate 41 of the subunit SUY is an example of a “second base member”. The flat surface portion 51 of the subunit SUY is an example of a “second flat surface portion”. The first surface 51a of the flat surface portion 51 of the subunit SUY is an example of a “third surface”. The second surface 51b of the flat surface portion 51 of the subunit SUY is an example of a “fourth surface”. The standing plate portion 52a of the subunit SUY is an example of a “third portion”. The horizontal plate portion 52b of the subunit SUY is an example of a “fourth portion”.

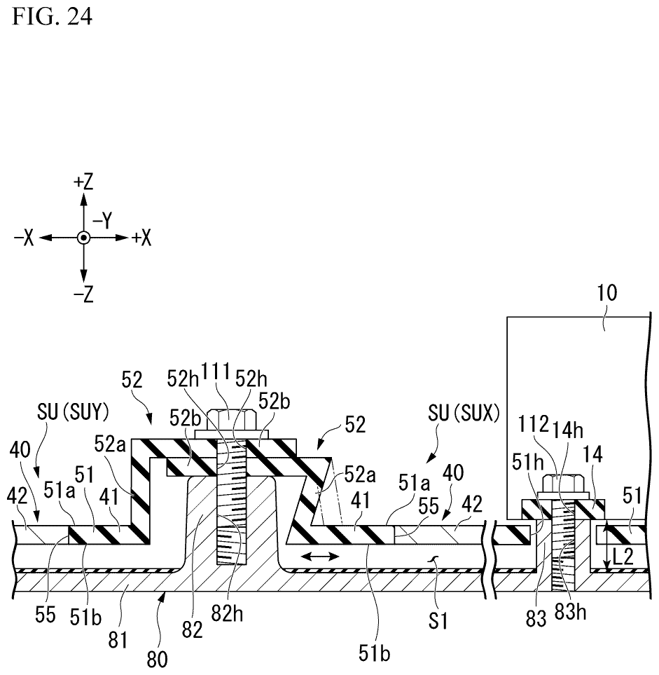

FIG. 24 is a cross-sectional view illustrating the action of the absorption structure. Here, a linear expansion coefficient of the base plate 41 made of a synthetic resin is larger than a linear expansion coefficient of the metal plate 80 made of a metal. Therefore, at the time of thermal expansion, the base plate 41 tends to extend more than the metal plate 80. On the other hand, at the time of thermal contraction, the base plate 41 tends to contract more than the metal plate 80.

In the present embodiment, the fixing portion 52 of the base plate 41 has the standing plate portion 52a. In a case where the standing plate portion 52a is provided, the standing plate portion 52a is bent in the X direction at the time of thermal expansion, so that it is possible to suppress a large load from acting on the flat surface portion 51 and/or the fixing portion 52 of the base plate 41. Similarly, at the time of thermal contraction, since the standing plate portion 52a is bent in the X direction, it is possible to suppress a large load from acting on the flat surface portion 51 and/or the fixing portion 52 of the base plate 41.

### 10. Fixing Structure Related to Plurality of Subunits

Next, referring to FIG. 11 again, a fixing structure related to the plurality of subunits SU will be described. In the present embodiment, the main body MU is divided into a plurality of subunits SU (for example, three subunits SUX, SUY, and SUZ).

The subunit SUX includes the plurality of electronic components 10X, the base plate 41, and the plurality of bus bars 42. The plurality of bus bars 42 include portions disposed on the same plane, and are electrically connected to the plurality of electronic components 10X. The subunit SUX is an example of a “first subunit”. The electronic components 10X is an example of a “first electronic component”. The base plate 41 of the subunit SUX is an example of a “first base member”. The flat surface portion 51 of the base plate 41 of the subunit SUX is an example of a “first flat surface portion”.

The subunit SUY includes the plurality of electronic components 10Y, the base plate 41, and the plurality of bus bars 42. The plurality of bus bars 42 include portions disposed on the same plane, and are electrically connected to the plurality of electronic components 10Y. The subunit SUY is electrically connected to the subunit SUX via, for example, the coupling bus bar 75. The subunit SUY is an example of a “second subunit”. The electronic component 10Y is an example of a “second electronic component”. The base plate 41 of the subunit SUY is an example of a “second base member”. The flat surface portion 51 of the base plate 41 of the subunit SUY is an example of a “second flat surface portion”

The subunit SUZ includes the plurality of electronic components 10Z, the base plate 41, and the plurality of bus bars 42. The plurality of bus bars 42 include portions disposed on the same plane, and are electrically connected to the plurality of electronic components 10Z. The subunit SUZ is electrically connected to the subunit SUY via, for example, a plurality of coupling bus bars 75. The subunit SUZ is an example of a “third subunit”. The electronic component 10Z is an example of a “third electronic component”. The base plate 41 of the subunit SUZ is an example of a “third base member”. The flat surface portion 51 of the base plate 41 of the subunit SUZ is an example of a “third flat surface portion”.

In the present embodiment, each of the plurality of subunits SU (for example, three subunits SUX, SUY, and SUZ) is fixed to the metal plate 80. As a result, the plurality of subunits SU (for example, three subunits SUX, SUY, and SUZ) are integrally held by one metal plate 80.

In the present embodiment, the longitudinal direction of the subunit SUX is the X direction. The longitudinal direction of the subunit SUY is the X direction. The longitudinal direction of the subunit SUZ is the X direction. The plurality of subunits SU (for example, three subunits SUX, SUY, and SUZ) are adjacent to each other in the X direction and are arranged in a line in the X direction. The longitudinal direction of the metal plate 80 is the X direction. The length of the metal plate 80 in the X direction is larger than the sum of the lengths of the plurality of subunits SU (for example, three subunits SUX, SUY, and SUZ) in the X direction.

In the present embodiment, the fixing portion 52 of the subunit SUX and the fixing portion 52 of the subunit SUY are disposed at positions overlapping each other in the Z direction. The fixing portion 52 of the subunit SUX and the fixing portion 52 of the subunit SUY are collectively fixed to the fixing portion 82 of the metal plate 80 via one fastening member 111. The fixing portion 52 of the subunit SUX is an example of a “first fixing portion”. The fixing portion 52 of the subunit SUY is an example of a “second fixing portion”.

Similarly, the fixing portion 52 of the subunit SUY and the fixing portion 52 of the subunit SUZ are disposed at positions overlapping each other in the Z direction. The fixing portion 52 of the subunit SUY and the fixing portion 52 of the subunit SUZ are collectively fixed to the fixing portion 82 of the metal plate 80 by one fastening member 111.

In the present embodiment, heat generated by the electronic component 10X and the bus bar 42 included in the subunit SUX is transferred to the metal plate 80 via the one or more heat transfer members 92 facing the subunit SUX. Similarly, heat generated by the electronic component 10Y and the bus bar 42 included in the subunit SUY is transferred to the metal plate 80 via the one or more heat transfer members 92 facing the subunit SUY. Heat generated by the electronic components 10Z and the bus bars 42 included in the subunit SUZ is transferred to the metal plate 80 via the one or more heat transfer members 92 facing the subunit SUZ.

In the present embodiment, the plurality of subunits SU (for example, three subunits SUX, SUY, and SUZ) may have different amounts of heat generation. Even in a case where the amounts of heat generation of the plurality of subunits SU are different, it is possible to promote cooling of the plurality of subunits SU (for example, three subunits SUX, SUY, and SUZ) by using one large metal plate 80. For example, in a case where the amounts of heat generation of the plurality of subunits SU are different, the heat of the plurality of subunits SU can be equalized by one large metal plate 80.

### 11. Structure Related to Insulating Rib

Next, a structure related to the insulating rib 53 will be described.

### <11.1 First Aspect of Insulating Rib>

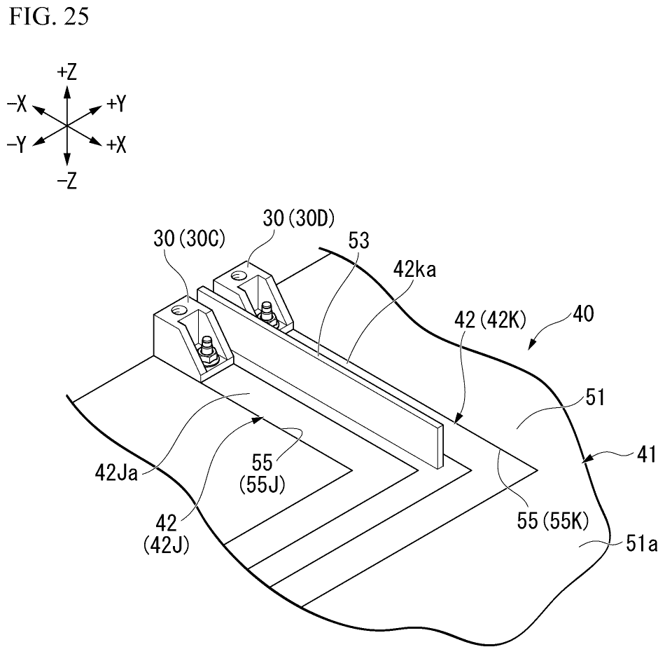

FIG. 25 is a perspective view for describing a first aspect of the insulating rib 53. In the present embodiment, the base plate 41 has the insulating rib 53. The insulating rib 53 is a rib standing in the +Z direction from the first surface 51a of the flat surface portion 51. The insulating rib 53 is made of a synthetic resin and has an insulating property. The insulating rib 53 is provided as part of the base plate 41, for example. The insulating rib 53 is disposed between two bus bars 42 disposed side by side in a state in which an upper surface side (first surface 51a side) of the two bus bars 42 is exposed, and secures an insulation distance between the two bus bars 42. In the present embodiment, the first surface 51a is an example of a “first surface”. The second surface 51b is an example of a “second surface”.

In the present embodiment, the routing board 40 includes a bus bar 42J and a bus bar 42K as the plurality of bus bars 42. In addition, the base plate 41 includes an accommodation portion 55J and an accommodation portion 55K as the plurality of accommodation portions 55.

At least part of the bus bar 42J is accommodated in the accommodation portion 55J and extends along the flat surface portion 51. The bus bar 42J is electrically connected to the terminal 13A of one electronic component 10 (hereinafter, referred to as a “first electronic component 10” in some cases) via the connection component 20. The bus bar 42J is an example of a “first bus bar”. The accommodation portion 55J is an example of a “first accommodation portion”.

At least part of the bus bar 42K is accommodated in the accommodation portion 55K and extends along the flat surface portion 51. The bus bar 42K is electrically connected to the terminal 13 of another electronic component 10 (second electronic component) via another connection component 20. Alternatively, the bus bar 42J may be electrically connected to the terminal 13B of the first electronic component 10 via another connection component 20. The bus bar 42K is an example of a “second bus bar”. The accommodation portion 55K is an example of a “second accommodation portion”.

In the present embodiment, the insulating rib 53 protrudes in the +Z direction from the first surface 51a at a position between the accommodation portion 55J and the accommodation portion 55K. The insulating rib 53 is an example of each of an “insulating wall” and a “first rib”.

In the present embodiment, the bus bar 42J is accommodated in the accommodation portion 55J in a state of being exposed to the upper surface side (first surface 51a side), and includes, for example, a first straight portion 42Ja linearly extending in the X direction. The bus bar 42K is accommodated in the accommodation portion 55K in a state of being exposed to the upper surface side (first surface 51a side), and includes, for example, a second straight portion 42Ka linearly extending in the X direction. The first straight portion 42Ja of the bus bar 42J and the second straight portion 42Ka of the bus bar 42K are adjacent to each other in the Y direction, for example. The second straight portion 42Ka of the bus bar 42K extends in parallel with the first straight portion 42Ja of the bus bar 42J.

The insulating rib 53 is located between the first straight portion 42Ja of the bus bar 42J and the second straight portion 42Ka of the bus bar 42K when viewed from the Z direction, and extends in parallel with the first straight portion 42Ja of the bus bar 42J and the second straight portion 42Ka of the bus bar 42K. The first straight portion 42Ja of the bus bar 42J, the second straight portion 42Ka of the bus bar 42K, and the insulating rib 53 may extend linearly in the Y direction instead of the X direction.

In the present embodiment, the subunit SU includes the connection component 30C and the connection component 30D as the plurality of connection components 30. The connection component 30C is adjacent to the bus bar 42J in the Z direction, and is connected to the bus bar 42J from the Z direction. The connection component 30C is electrically connected to a first external device via the external connection bus bar 76. The connection component 30D is adjacent to the bus bar 42K in the Z direction, and is connected to the bus bar 42K from the Z direction. The connection component 30D is electrically connected to the first external device or a second external device via another external connection bus bar 76. In the present embodiment, part of the insulating rib 53 is disposed between the connection component 30C (first connection component) and the connection component 30D (second connection component) to electrically insulate the connection component 30C (first connection component) from the connection component 30D (second connection component).

Note that the first connection component is not limited to the connection component 30, and may be the connection component 20 connected to another electronic component 10 (third electronic component) included in the same subunit SU. Similarly, the second connection component is not limited to the connection component 30, and may be the connection component 20 connected to another electronic component 10 (fourth electronic component) included in the same subunit SU.

### First Modification Example

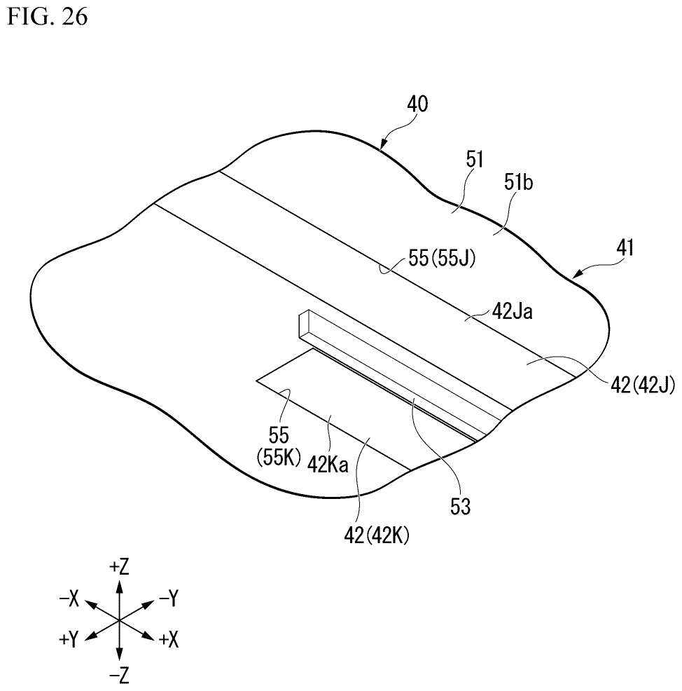

FIG. 26 is a perspective view for describing a first modification example of the first aspect of the insulating rib 53. In the present modification example, the insulating rib 53 is a rib standing in the −Z direction from the second surface 51b of the flat surface portion 51. The insulating rib 53 is provided as part of the base plate 41, for example. The insulating rib 53 is disposed between two bus bars 42 disposed side by side in a state in which a lower surface side (second surface 51b side) of the two bus bars 42 is exposed, and secures an insulation distance between the two bus bars 42. In the present modification example, the second surface 51b is an example of a “first surface”. The first surface 51a is an example of a “second surface”. The insulating rib 53 is an example of an “insulating wall”.

In the present modification example, the bus bar 42J is accommodated in the accommodation portion 55J in a state of being exposed to the lower surface side (second surface 51b side), and includes, for example, a first straight portion 42Ja linearly extending in the X direction. The bus bar 42K is accommodated in the accommodation portion 55K in a state of being exposed to the lower surface side (second surface 51b side), and includes, for example, a second straight portion 42Ka linearly extending in the X direction. The insulating rib 53 is located between the first straight portion 42Ja of the bus bar 42J and the second straight portion 42Ka of the bus bar 42K when viewed from the Z direction, and extends in parallel with the first straight portion 42Ja of the bus bar 42J and the second straight portion 42Ka of the bus bar 42K.

### Second Modification Example

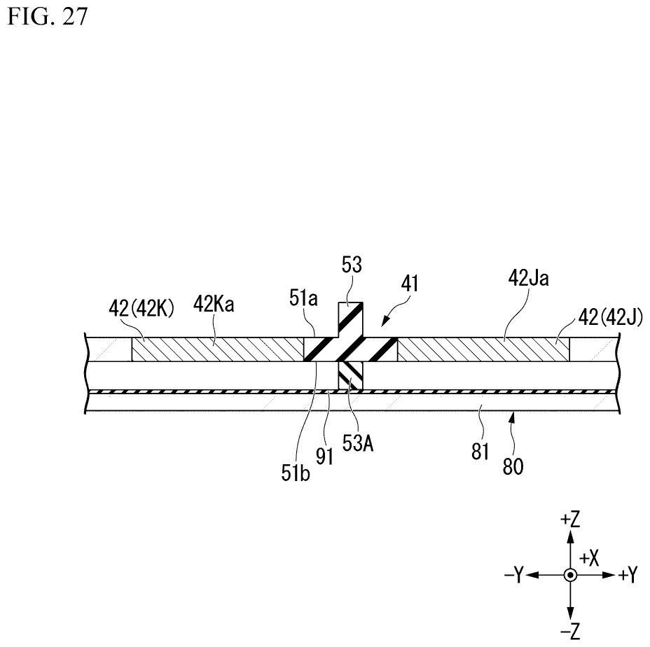

FIG. 27 is a cross-sectional view for describing a second modification example of the first aspect of the insulating wall. In the present modification example, an insulating wall 53A is provided between the second surface 51b of the flat surface portion 51 of the base plate 41 and the flat surface portion 81 of the metal plate 80. The insulating wall 53A is provided on the second surface 51b of the flat surface portion 51. In the present modification example, the second surface 51b is an example of a “first surface”. The first surface 51a is an example of a “second surface”. In the present disclosure, the phrase “provided on a surface” is not limited to a case where the surface is integrally formed with a member including the surface, and may include a case where the surface exists in association with the surface by being disposed to be in contact with the surface after being formed as a separate body.

In the present modification example, for example, the insulating wall 53A extends in the Z direction over the second surface 51b of the flat surface portion 51 of the base plate 41 and the flat surface portion 81 of the metal plate 80. The insulating wall 53A is made of a synthetic resin and has an insulating property. The insulating wall 53A is formed by, for example, compressing an elastic insulating member between the base plate 41 and the metal plate 80. Similarly to the insulating rib 53 of the first modification example, the insulating wall 53A is disposed between the two bus bars 42 disposed to be arranged in a state in which a lower surface of the two bus bars 42 is exposed, and secures an insulation distance between the two bus bars 42. Other constitutions of the insulating wall 53A are similar to those of the insulating rib 53 of the first modification example.

### <11.2 Second Aspect of Insulating Rib>

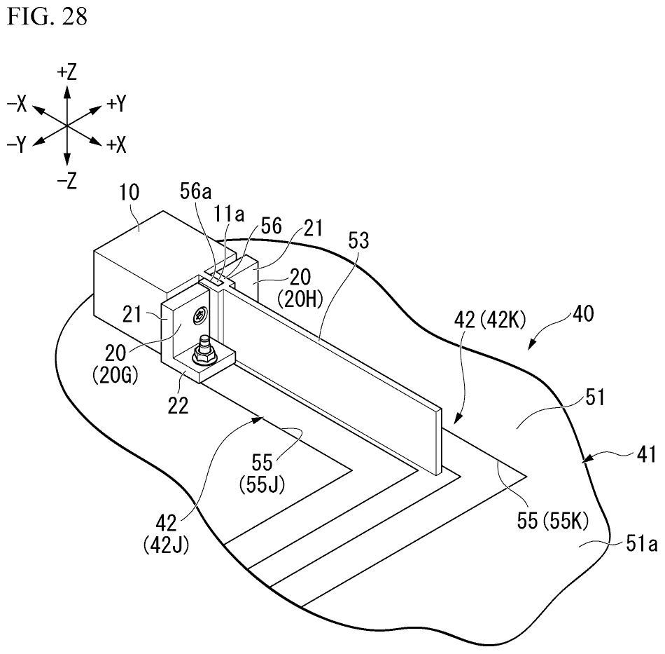

FIG. 28 is a perspective view for describing a second aspect of the insulating rib 53. In the present embodiment, the subunit SU includes a connection component 20G and a connection component 20H as the plurality of connection components 20. The connection component 20G is connected to the terminal 13A of the electronic component 10. The connection component 20G is adjacent to the bus bar 42J in the Z direction, and is connected to the bus bar 42J from the Z direction. The connection component 20H is connected to the terminal 13B of the electronic component 10. The connection component 20H is adjacent to the bus bar 42K in the Z direction, and is connected to the bus bar 42K from the Z direction. In the present embodiment, part of the insulating rib 53 is disposed between the connection component 20G (first connection component) and the connection component 20H (second connection component) to electrically insulate the connection component 20G (first connection component) from the connection component 20H (second connection component).

In the present embodiment, the electronic component 10 includes the insulating rib 11a described above. The insulating rib 11a is an example of each of a “rib” and a “second rib”. In the present embodiment, the insulating rib 53 provided on the base plate 41 is connected to the insulating rib 11a of the electronic component 10. As a result, a series of insulating ribs are formed by the insulating rib 11a of the electronic component 10 and the insulating rib 53.

In the present embodiment, the insulating rib 53 provided on the base plate 41 has an engagement portion 56 that is engaged with the insulating rib 11a of the electronic component 10. The engagement portion 56 has, for example, a recess 56a. The recess 56a is recessed in the protruding direction (X direction) of the insulating rib 11a and extends in the Z direction. The recess 56a is open in the +Z direction. The insulating rib 11a of the electronic component 10 can be inserted into the recess 56a in the Z direction. In addition, the electronic component 10 is movable in the Z direction in a state in which the insulating rib 11a is inserted into the recess 56a and guided by the recess 56a. The electronic component 10 is positioned in the X direction and the Y direction by the insulating rib 11a being inserted into the recess 56a.

### 12. Structure Related to Connection Component

Next, a structure related to the connection component 20 will be described.

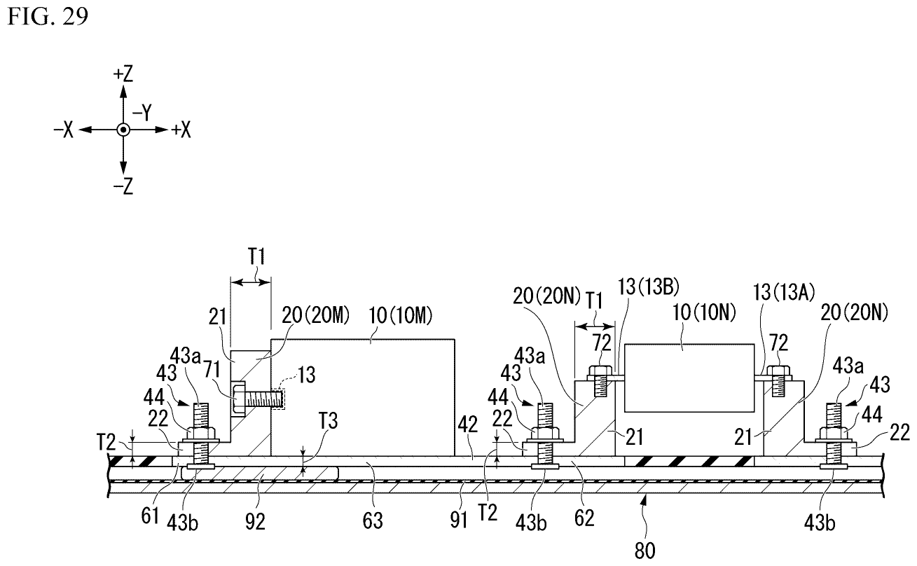

FIG. 29 is a cross-sectional view for describing a structure related to the connection component 20. In the present embodiment, the connection components 20 (for example, the connection component 20M and the connection component 20N) are heat storage members (heat absorbing members) that increase the heat capacity of the energization path of the electrical connection unit 1. The connection component 20 stores (absorbs) at least part of heat generated by the electronic component 10, for example. Alternatively/additionally, the connection component 20 may store (absorb) at least part of heat generated by the bus bar 42 itself due to energization. The connection component 20 may be referred to as a “heat storage component” or a “heat absorbing component”.

In the present embodiment, the bus bar 42 is disposed at a position away from the terminal 13 of the electronic component 10 (for example, a position away in the Z direction). The connection component 20 is disposed between the electronic component 10 and the bus bar 42. In the present disclosure, the phrase “the connection component is disposed between the electronic component and the bus bar” is not limited to a case where part of the connection component is located between the electronic component and the bus bar when viewed from the X direction or the Y direction. The phrase “the connection component is disposed between the electronic component and the bus bar” may correspond to a case where part of the connection component is located between the electronic component and the bus bar when viewed from a direction inclined with respect to the X direction or the Y direction. The connection component 20 electrically connects the terminal 13 of the electronic component 10 to the bus bar 42.

In the present embodiment, a thickness of at least part of the connection component 20 is larger than a plate thickness (a thickness in the Z direction) T3 of the bus bar 42. For example, a thickness T1 of at least part of the connection component 20 in the X direction is larger than the plate thickness T3 of the bus bar 42. In the present embodiment, the thickness T1 of the first portion 21 of the connection component 20 in the X direction is larger than the plate thickness T3 of the bus bar 42. In the present embodiment, the first portion 21 has the thickness T1 larger than the plate thickness T3 of the bus bar 42 as a thickness in the X direction over the entire length of the first portion 21 in the Z direction. The thickness T1 of the first portion 21 of the connection component 20 in the X direction is, for example, twice or more the plate thickness T3 of the bus bar 42. From another point of view, a thickness T2 of the second portion 22 of the connection component 20 in the Z direction may be larger than the plate thickness T3 of the bus bar 42.

In the present embodiment, the thickness T1 of the first portion 21 of the connection component 20 in the X direction is larger than the thickness T2 of the second portion 22 of the connection component 20 in the Z direction. In the present embodiment, the first portion 21 has the thickness T1 larger than the thickness T2 of the second portion 22 in the Z direction as a thickness in the X direction over the entire length of the first portion 21 in the Z direction.

The dimensional relationship described above is the same for the connection component 30 to which the external connection bus bar 76 is connected and/or the connection component 100 to which the coupling bus bar 75 is connected. For example, in the description of the connection component 30, the “connection component 20” may be replaced with the “connection component 30”, the “first portion 21” may be replaced with the “first portion 31”, and the “second portion 22” may be replaced with the “second portion 32” in the description of the connection component 20. Similarly, in the description of the connection component 100, the “connection component 20” may be replaced with the “connection component 100”, the “first portion 21” may be replaced with the “first portion 101”, and the “second portion 22” may be replaced with the “second portion 102” in the description of the connection component 20.

### 13. Method of Manufacturing Electrical Connection Unit

Next, a method of manufacturing the electrical connection unit 1 will be described.

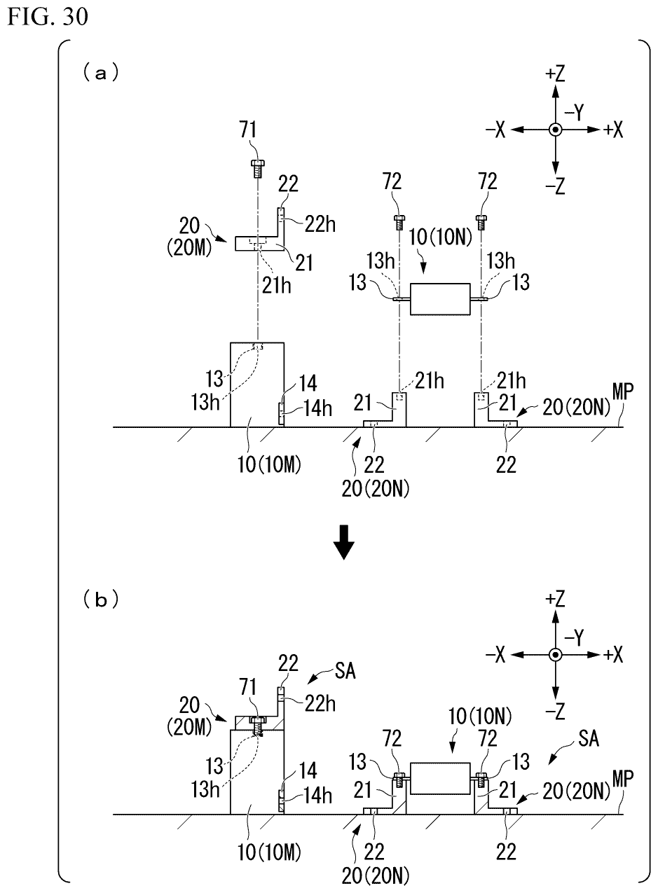

FIGS. 30 to 34 are cross-sectional views for describing the method of manufacturing the electrical connection unit 1. In the routing board 40 of each subunit SU, the base plate 41 and the plurality of bus bars 42 are integrated through insert molding or another method in a state in which the fastening member 43 is fixed to the bus bar 42. As a result, the routing board 40 of each subunit SU is prepared in advance.

### (First Step)

FIG. 30 illustrates a first step. In the first step, the connection component 20 is fixed to the terminal 13 of the electronic component 10 by using the fastening member 71 or the fastening member 72. As a result, an assembly SA in which the electronic component 10 and the connection component 20 are integrated is formed.

The first step related to the electronic component 10M is performed, for example, as follows. First, the electronic component 10 is placed on a placement table MP in a posture in which the attachment hole 13h of the terminal 13 of the electronic component 10M is directed in the vertical direction. Next, the connection component 20M is placed on the electronic component 10M in a posture in which the first attachment hole 21h of the connection component 20M is directed in the vertical direction. The first attachment hole 21h of the connection component 20M is aligned with the attachment hole 13h of the terminal 13 of the electronic component 10M. The first step is performed in a state in which the electronic component 10M and the connection component 20M are in a first posture. The first posture is a posture in which the attachment hole 13h and the first attachment hole 21h are directed in the vertical direction.

Next, the fastening member 71 is inserted into the first attachment hole 21h of the connection component 20M from the vertical direction. The fastening member 71 that has passed through the attachment hole 21h of the connection component 20M is engaged with the attachment hole 13h of the terminal 13 of the electronic component 10. As a result, the assembly SA in which the electronic component 10M and the connection component 20M are integrated is formed. The vertical direction is an example of a “first attachment direction”.

### (Second Step)

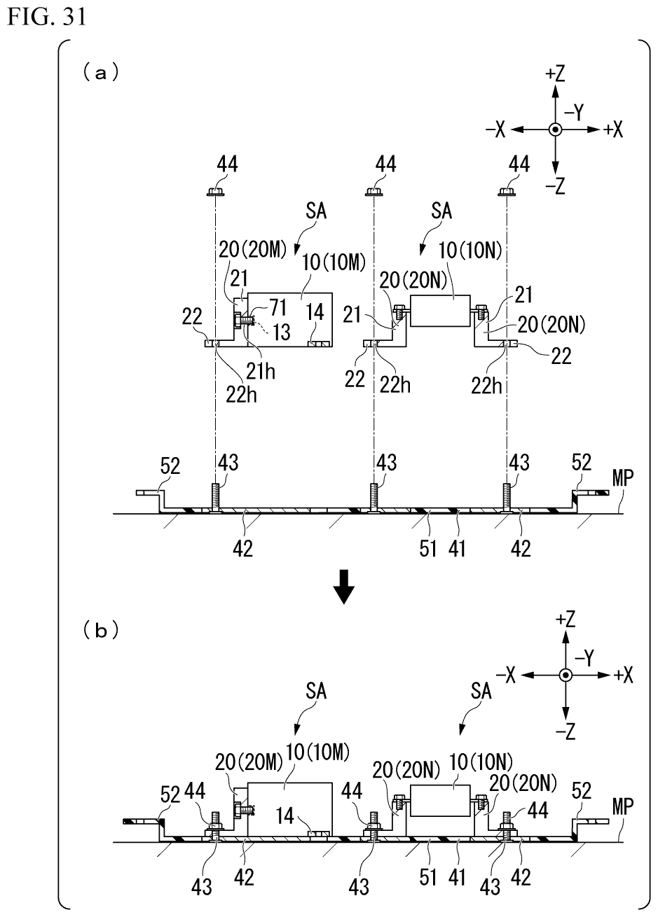

FIG. 31 illustrates a second step. In the second step, the assembly SA is fixed to the routing board 40 of each subunit SU. For example, the connection component 20 included in the assembly SA is fixed to the bus bar 42 included in the routing board 40. As a result, the electronic component 10 and the bus bar 42 are electrically connected.

The second step is performed, for example, as follows. As described above, in the routing board 40, the fastening member 43 is fixed to the bus bar 42. The fastening member 43 protrudes in the vertical direction from the bus bar 42. The assembly SA is placed on the routing board 40 such that the fastening member 43 is inserted into the second attachment hole 22h of the second portion 22 of the connection component 20 in the vertical direction. Next, the engagement member 44 (for example, a nut) is engaged with the upper end of the fastening member 43 from the vertical direction. As a result, the second portion 22 of the connection component 20 included in the assembly SA is fixed to the bus bar 42. As a result, each subunit SU is completed.

Here, the second step related to the electronic component 10M is performed, for example, as follows. First, the posture of the assembly SA is rotated by 90 degrees from the first step. That is, the first posture (see FIG. 30) in which the attachment hole 13h and the first attachment hole 21h are directed in the vertical direction is changed to the second posture (see FIG. 31) in which the attachment hole 13h and the first attachment hole 21h are directed in the horizontal direction and the second attachment hole 22h of the connection component 20 is directed in the vertical direction.

In the second posture, the assembly SA is placed on the routing board 40 such that the fastening member 43 is inserted into the second attachment hole 22h of the second portion 22 of the connection component 20 in the vertical direction. Next, the engagement member 44 (for example, a nut) is engaged with the upper end of the fastening member 43 from the vertical direction. As a result, the second portion 22 of the connection component 20M included in the assembly SA is fixed to the bus bar 42.

### (Third Step)

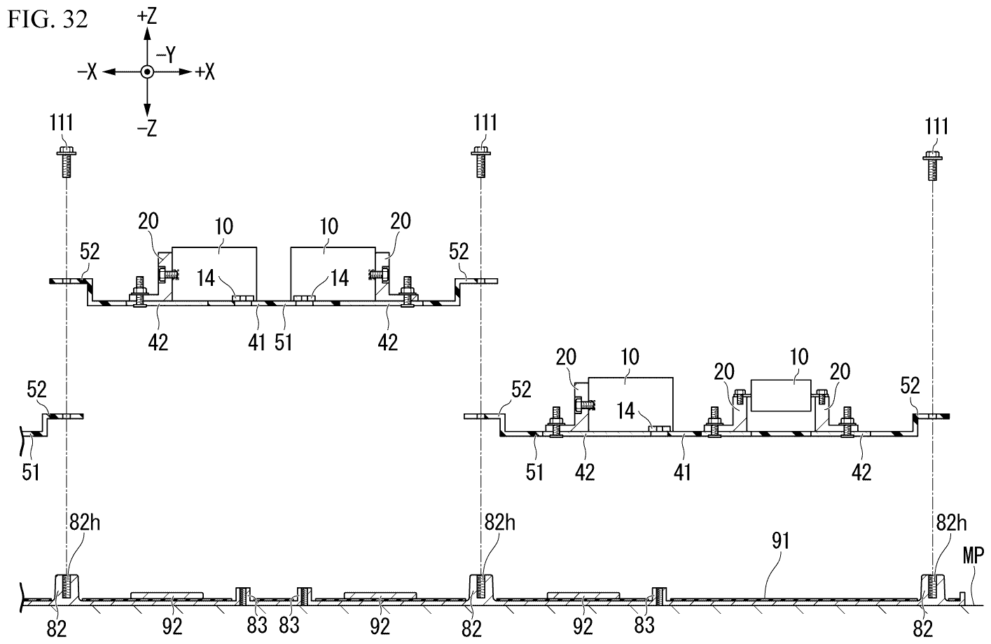

FIG. 32 illustrates a third step. In the third step, each subunit SU is attached to the metal plate 80. The third step is performed, for example, as follows. First, the insulating sheet 91 is attached to the surface of the flat surface portion 81 of the metal plate 80. Next, the heat transfer member 92 is fixed to the lower surface of each subunit SU with an adhesive or the like. Next, each subunit SU is placed on the metal plate 80 with the insulating sheet 91 and the heat transfer member 92 interposed therebetween. The fixing portion 52 of each subunit SU is fixed to the fixing portion 82 of the metal plate 80 via the fastening member 111.

### (Fourth Step)

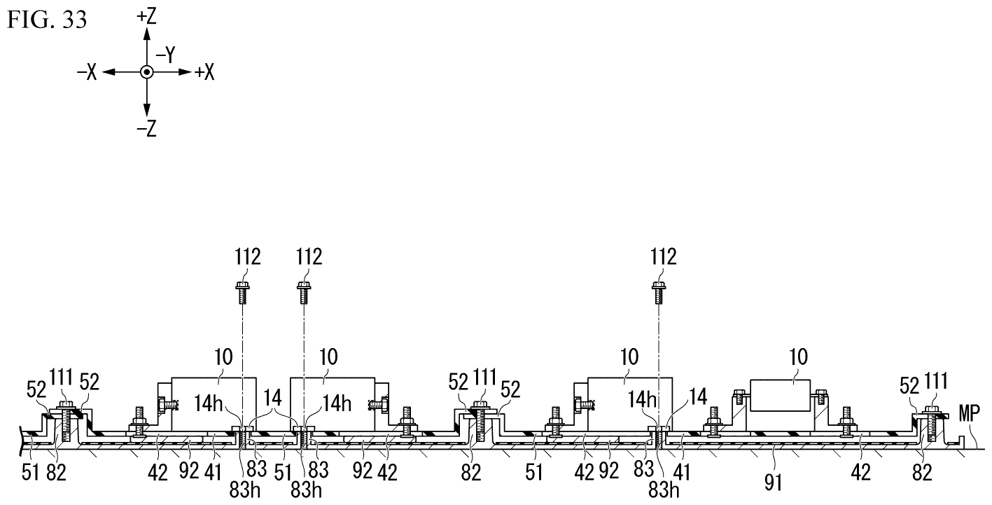

FIG. 33 illustrates a fourth step. In the fourth step, the attachment portion 14 of the electronic component 10 of each subunit SU is fixed to the fixing portion 83 of the metal plate 80 via the fastening member 112. The fourth step may be performed together with the third step.

### (Fifth Step)

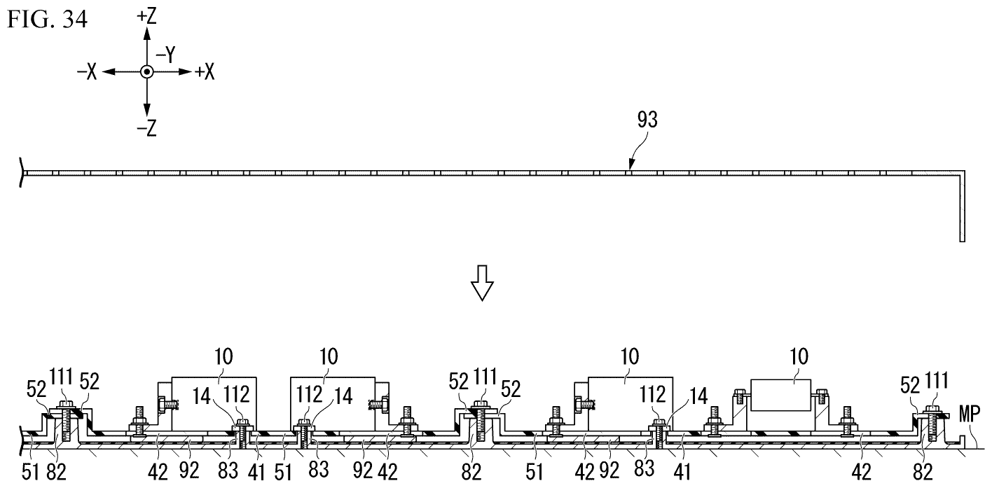

FIG. 34 illustrates a fifth step. In the fifth step, the insulating cover 93 is attached to the metal plate 80 in the vertical direction. As a result, the electrical connection unit 1 is completed.

Instead of/in addition to the assembly in which the electronic component 10 and the connection component 20 are integrated, the assembly SA may be an assembly in which the coupling bus bar 75 and the connection component 100 are integrated, or an assembly in which the external connection bus bar 76 and the connection component 30 are integrated. Each of the electronic component 10, the coupling bus bar 75, and the external connection bus bar 76 is an example of a “connection target component”. Therefore, the “electronic component 10” in the above description may be replaced with the “coupling bus bar 75” or the “external connection bus bar 76”. The “connection component 20” in the above description may be replaced with the “connection component 100” or the “connection component 30”.

### 14. Advantages

### <A. Advantages of Routing Board>

As a comparative example, an electrical connection unit in which a bus bar is disposed in a standing posture with respect to a lower wall of a housing will be considered. In such a constitution of the comparative example, for example, since a cross-sectional area of a bus bar is determined in order to function as a routing member, it may be difficult to reduce a width (height) of the standing bus bar. In this case, the width of the standing bus bar becomes a bottleneck, and it may be difficult to reduce a height of the electrical connection unit.

On the other hand, in the present embodiment, the electrical connection unit 1 includes the first electronic component 10 and the routing board 40. The routing board 40 includes the base plate 41 and the first bus bar 42. The base plate 41 has the plate-shaped flat surface portion 51 having a first surface 51a facing the first electronic component 10. The flat surface portion 51 has the first accommodation portion 55 recessed in the Z direction or penetrating the flat surface portion 51 in the Z direction. At least part of the first bus bar 42 is accommodated in the first accommodation portion 55 and extends along the flat surface portion 51. According to such a constitution, compared with the structure of the comparative example in which at least part of the routing path is formed on a plane, the width of the bus bar is less likely to be a bottleneck, and the height of the electrical connection unit 1 can be easily reduced.

In the present embodiment, the electrical connection unit 1 has the first connection component 20. The first connection component 20 electrically connects the first electronic component 10 to the first bus bar 42. The first bus bar 42 has the first connection portion 61 in contact with the first connection component 20. The first connection portion 61 is accommodated in the first accommodation portion 55 and extends along the flat surface portion 51. According to such a constitution, since more portions of the routing path are formed on a plane, it is further easy to reduce the height of the electrical connection unit 1.

In the present embodiment, the electrical connection unit 1 has the second connection component 20. The second connection component 20 electrically connects the second electronic component or an external device to the first bus bar 42. The first bus bar 42 has a second connection portion 62 in contact with the second connection component 20. The first bus bar 42 is accommodated in the first accommodation portion 55 at least over the first connection portion 61 and the second connection portion 62 and extends along the flat surface portion 51. According to such a constitution, since more portions of the routing path are formed on a plane, it is further easy to reduce the height of the electrical connection unit 1.

In the present embodiment, the first bus bar 42 has the extending portion 63 between the first connection portion 61 and the second connection portion 62. The extending portion 63 is accommodated in the first accommodation portion 55, passes through the region R overlapping the electronic component 10 when viewed from the Z direction, and extends over both sides of the region R. According to such a constitution, since the extending portion 63 is accommodated in the first accommodation portion 55, it is difficult to be restricted in the routing layout due to the presence of the electronic component 10. Thus, for example, it is possible to achieve a routing layout that makes electrical characteristics more advantageous, such as making it easier to cause the extending portion 63 to linearly extend. In addition, routing of the bus bar so as to detour the electronic component 10 can be avoided. This makes it possible to improve the electrical characteristics of the electrical connection unit 1 and/or to reduce the size of the electrical connection unit 1.

In the present embodiment, the first bus bar 42 extends to the region R overlapping the first electronic component 10 when viewed from the Z direction, and has the extension 64 having the end 42e1 at a position overlapping the first electronic component 10. The extension 64 is accommodated in the first accommodation portion 55 and extends along the flat surface portion 51. According to this constitution, since the extension 64 is accommodated in the first accommodation portion 55, the height of the electrical connection unit 1 can be reduced, and a metallic heat dissipation portion (extension 64) for promoting heat dissipation and/or heat storage of the first electronic component 10 can be disposed below the first electronic component 10. As a result, it is possible to improve the heat dissipation property and/or the heat storage property of the electrical connection unit 1 while reducing the height of the electrical connection unit 1.

In the present embodiment, the first bus bar 42 is accommodated in the first accommodation portion 55 over the entire length of the first bus bar 42 and extends along the flat surface portion 51. According to such a constitution, since more portions of the routing path are formed on a plane, it is further easy to reduce the height of the electrical connection unit 1.

In the present embodiment, the electrical connection unit 1 includes the second bus bar 42 electrically connected to the second terminal 13B of the first electronic component 10. The flat surface portion 51 has the second accommodation portion 55 recessed in the Z direction or penetrating the flat surface portion 51 in the Z direction at a position away from the first accommodation portion 55. At least part of the second bus bar 42 is accommodated in the second accommodation portion 55 and extends along the flat surface portion 51. According to such a constitution, since more portions of the routing path including the plurality of bus bars 42 are held on a plane by one base plate 41, it becomes easier to reduce the height of the electrical connection unit 1.

In the present embodiment, the electrical connection unit 1 includes the third bus bar 42. The first bus bar 42 is a bus bar included in the positive electrode line PL. The third bus bar 42 is a bus bar included in the negative electrode line NL. The flat surface portion 51 has the third accommodation portion 55 recessed in the Z direction or penetrating the flat surface portion 51 in the Z direction at a position away from the first accommodation portion 55. At least part of the third bus bar 42 is accommodated in the third accommodation portion 55 and extends along the flat surface portion 51. According to such a constitution, since more portions of the routing path forming the positive electrode line PL and the negative electrode line NL are held on a plane by one base plate 41, it becomes easier to reduce the height of the electrical connection unit 1.

In the present embodiment, the electrical connection unit 1 includes the fourth bus bar 42G, the fifth bus bar 75D, and the third connection component 100 that electrically connects the fourth bus bar 42G to the fifth bus bar 75D. The flat surface portion 51 has the fourth accommodation portion 55 recessed in the Z direction or penetrating the flat surface portion 51 in the Z direction at a position away from the first accommodation portion 55. At least part of the fourth bus bar 42G is accommodated in the fourth accommodation portion 55 and extends along the flat surface portion 51. The third connection component 100 includes a portion standing with respect to the fourth bus bar 42G. The fifth bus bar 75D is supported by the third connection component 100 at a position away from the first bus bar 42 in the Z direction, and extends in parallel with the first surface 51a. According to such a constitution, a routing path in a three-dimensional way can be easily formed by the fourth bus bar 42G, the third connection component 100, and the fifth bus bar 75D. Thus, the electrical connection unit 1 having excellent assemblability can be provided. In addition, since the fourth bus bar 42G is disposed in the accommodation portion 55 of the base plate 41, part of the three-dimensional routing path is formed within the thickness of the base plate 41. As a result, it becomes easier to reduce the height of the electrical connection unit 1.

In the present embodiment, the fifth bus bar 75D extends to straddle the first bus bar 42 at a position away from the first bus bar 42 in the Z direction. According to such a constitution, it is easy to form a routing path that three-dimensionally intersects the first bus bar 42 by using the third connection component 100 and the fifth bus bar 75D. Thus, the electrical connection unit 1 having excellent assemblability can be provided.

### <B. Advantages of Flat Bus Bars>

As a comparative example, an electrical connection unit in which a bus bar is disposed in a standing posture with respect to a lower wall of a housing will be considered. In such a constitution of the comparative example, it is necessary to fix the bus bar to the housing in a standing posture, and it is difficult to improve workability regarding attachment of the bus bar. In this case, it may be difficult to improve the assemblability of the electrical connection unit 1.

On the other hand, in the present embodiment, the electrical connection unit 1 includes the base plate 41 and the bus bar 42. The base plate 41 includes the flat surface portion 51 having a plate shape. The flat surface portion 51 has the first accommodation portion 55 recessed in the Z direction or penetrating the flat surface portion 51 in the Z direction. At least part of the bus bar 42 is accommodated in the first accommodation portion 55 and extends along the flat surface portion 51. According to such a constitution, the base plate 41 and the bus bar 42 can be easily handled integrally, and workability regarding attachment of the bus bar can be improved compared with the constitution of the comparative example. Thus, the assemblability of the electrical connection unit 1 can be improved.

In the present embodiment, the bus bar 42 is accommodated in the accommodation portion 55 over the entire length of the bus bar 42 and extends along the flat surface portion 51. According to such a constitution, it is easy to reduce the height of the electrical connection unit 1 while improving the assemblability of the electrical connection unit 1.

In the present embodiment, the bus bar 42 is integrated with the base plate 41 through insert molding. According to such a constitution, it is possible to eliminate or reduce the work of manually attaching the bus bar 42 to the housing. Thus, the assemblability of the electrical connection unit 1 can be further improved.

In the present embodiment, the fastening member 43 protruding from the bus bar 42 in the Z direction and the connection components 20 and 30 attached to the fastening member 43 from the Z direction are provided. The connection components 20 and 30 electrically connect the electronic component 10 or an external device to the bus bar 42. According to such a constitution, a direction of work of attaching a connection target component to the bus bar 42 can be easily aligned with the Z direction. In a case where the direction of work can be aligned, the assemblability of the electrical connection unit 1 can be further improved.

In the present embodiment, the connection component 20 is connected to the electronic component 10 from the X direction (or the Y direction). According to such a constitution, a connection direction of the electronic component 10 with respect to the bus bar 42 can be converted into the Z direction by using the connection component 20 for the electronic component 10 that needs to be connected from the X direction. Thus, the assemblability of the electrical connection unit 1 can be further improved.

### <C. Advantages of Exposure Structure on Upper Surface Side of Bus Bar>

As a comparative example, an electrical connection unit in which the upper surface side of the bus bar 42 is covered with a synthetic resin will be considered. In such a constitution of the comparative example, it may be difficult to improve a heat dissipation property of the electrical connection unit.

On the other hand, in the present embodiment, the electrical connection unit 1 includes the first electronic component 10, the base plate 41, and the bus bar 42. The base plate 41 has a plate-shaped flat surface portion 51 having the first surface 51a facing the first electronic component 10 and the second surface 51b located on the side opposite to the first surface 51a. The flat surface portion 51 has the accommodation portion 55 recessed in the Z direction or penetrating the flat surface portion 51 in the Z direction. At least part of the bus bar 42 has the plate portion 42p that is accommodated in the accommodation portion 55 and extends along the flat surface portion 51. The plate portion 42p includes the first connection portion 61 overlapping the first connection component 20 when viewed in the Z direction, and the extending portion 63 extending from the first connection portion 61 in a direction intersecting the Z direction. At least part of the extending portion 63 is exposed to the outside of the base plate 41 on the first surface 51a side. According to such a constitution, at least part of a portion of the bus bar 42 other than the connection portions 61 and 62 connected to other components is exposed to the outside of the base plate 41 and functions as an area for releasing heat. In this case, the heat dissipation property of the electrical connection unit 1 can be improved.

In the present embodiment, the extending portion 63 is exposed to the outside of the base plate 41 on the first surface 51a side at least in part of the region R overlapping the first electronic component 10 when viewed from the Z direction. According to such a constitution, it is easy for part of the extending portion 63 to function as a heat dissipation portion that transfers heat from the first electronic component 10. In this case, the heat dissipation property of the electrical connection unit 1 can be improved.

In the present embodiment, the first bus bar 42 has the second connection portion 62 overlapping the second connection components 20 and 30 when viewed in the Z direction. The first bus bar 42 is accommodated in the accommodation portion 55 at least over the entire length between the first connection portion 61 and the second connection portion 62, extends along the flat surface portion 51, and is exposed to the outside of the base plate 41 on the first surface 51a side. According to such a constitution, since the wider portion functions as a heat dissipation area, the heat dissipation property of the electrical connection unit 1 can be further improved.

In the present embodiment, the bus bar 42 is accommodated in the accommodation portion 55 over the entire length of the bus bar 42, extends along the flat surface portion 51, and is exposed to the outside of the base plate 41 on the first surface 51a side. According to such a constitution, since the wider portion functions as a heat dissipation area, the heat dissipation property of the electrical connection unit 1 can be further improved.

At least part of the extending portion 63 is exposed to the outside of the base plate 41 not only on the first surface 51a side but also on the second surface 51b side. According to such a constitution, since the wider portion functions as a heat dissipation area, the heat dissipation property of the electrical connection unit 1 can be further improved.

In the modification example of the present embodiment, the electrical connection unit 1 includes the metal plate 80 facing the flat surface portion 51 with the gap S1 between the metal plate 80 and the flat surface portion 51, and the heat transfer member 92 disposed between the bus bar 42 and the metal plate 80. The base plate 41 includes a cover portion 51v that covers at least part of the extending portion 63 on the second surface 51b side. According to such a constitution, even in a case where heat is likely to be confined in the gap S1 between the base plate 41 and the metal plate 80, it is possible to suppress the heat from being easily confined in the gap S1 by providing the cover portion 51v.

### <D. Advantages of Exposure Structure on Lower Surface Side of Bus Bar>

As a comparative example, an electrical connection unit in which the lower surface side of the bus bar 42 is covered with a synthetic resin will be considered. In such a constitution of the comparative example, it may be difficult to improve a heat dissipation property of the electrical connection unit.

On the other hand, in the present embodiment, the electrical connection unit 1 includes the first electronic component 10, the base plate 41, and the bus bar 42. The base plate 41 has a plate-shaped flat surface portion 51 having the first surface 51a facing the first electronic component 10 and the second surface 51b located on the side opposite to the first surface 51a. The flat surface portion 51 has the accommodation portion 55 recessed in the Z direction or penetrating the flat surface portion 51 in the Z direction. At least part of the bus bar 42 has the plate portion 42p that is accommodated in the accommodation portion 55 and extends along the flat surface portion 51. The plate portion 42p includes the exposed portion 42u exposed to the outside of the base plate 41 on the second surface 51b side. According to such a constitution, in the bus bar 42, at least part of the plate portion 42p is exposed to the outside of the base plate 41 and functions as an area for releasing heat. In this case, the heat dissipation property of the electrical connection unit 1 can be improved. From this point of view, the heat transfer member 92 need not be in contact with the exposed portion 42u.

In the present embodiment, at least part of the exposed portion 42u of the bus bar 42 is disposed in a region overlapping the connection component 20 when viewed from the Z direction. According to such a constitution, heat from the connection component 20 is easily dissipated by the exposed portion 42u of the bus bar 42. Thus, the heat dissipation property of the electrical connection unit 1 can be further improved.

In the present embodiment, the electrical connection unit 1 further includes the metal plate 80 and the heat transfer member 92. The metal plate 80 faces the second surface 51b of the flat surface portion 51 with the gap S1 between the metal plate 80 and the flat surface portion 51. The heat transfer member 92 is disposed between the exposed portion 42u of the bus bar 42 and the metal plate 80. According to such a constitution, the heat of the bus bar 42 is easily moved to the metal plate 80 via the heat transfer member 92 and dissipated. Thus, the heat dissipation property of the electrical connection unit 1 can be further improved.

In the present embodiment, at least part of the exposed portion 42u of the bus bar 42 is disposed in a region overlapping the connection component 20 when viewed from the Z direction. At least part of the heat transfer member 92 overlaps the exposed portion 42u of the bus bar 42 in a region overlapping the connection component 20 when viewed from the Z direction. According to such a constitution, heat of the electronic component 10 is easily moved to the metal plate 80 via the heat transfer member 92 and dissipated. Thus, the heat dissipation property of the electrical connection unit 1 can be further improved.

Instead of/in addition to the above example, at least part of the heat transfer member 92 overlaps the exposed portion 42u of the bus bar 42 in a region overlapping the connection component 30 when viewed from the Z direction. According to such a constitution, even in a case where heat is received from an external device via the external connection bus bar 76, the received heat is easily moved by the metal plate 80 and dissipated. Thus, the heat dissipation property of the electrical connection unit 1 can be further improved.

In the present embodiment, the exposed portion 42u of the bus bar 42 includes the first portion 42ua disposed in a region overlapping the connection component 20 when viewed from the Z direction and the second portion 42ub disposed in a region overlapping the first electronic component 10 when viewed from the Z direction. The heat transfer member 92 includes the first heat transfer portion 92a overlapping the first portion 42ua of the exposed portion 42u when viewed from the Z direction, and the second heat transfer portion 92b overlapping the second portion 42ub of the exposed portion 42u when viewed from the Z direction. According to such a constitution, heat of the first electronic component 10 is efficiently moved by the metal plate 80 via the heat transfer member 92 and easily dissipated. Thus, the heat dissipation property of the electrical connection unit 1 can be further improved.

In the present embodiment, the second portion 42ub of the exposed portion 42u of the bus bar 42 is exposed to the outside of the base plate 41 and faces the first electronic component 10 not only on the second surface 51b side but also on the first surface 51a side. According to such a constitution, heat of the first electronic component 10 is efficiently moved by the metal plate 80 via the heat transfer member 92 and easily dissipated. Thus, the heat dissipation property of the electrical connection unit 1 can be further improved.

In the present embodiment, the bus bar 42 is accommodated in the accommodation portion 55 over the entire length of the bus bar 42, extends along the flat surface portion 51, and is exposed to the outside of the base plate 41 on the second surface 51b side. According to such a constitution, since the wider portion functions as a heat dissipation area, the heat dissipation property of the electrical connection unit 1 can be further improved.

### <E. Advantages of Insulating Wall>

As a comparative example, an electrical connection unit in which an insulating wall is not provided between adjacent bus bars within a predetermined distance will be considered. In such a constitution of the comparative example, it is necessary to separate the bus bars by a predetermined distance or more in order to secure an insulation distance between the bus bars. If the bus bar needs to be separated by a predetermined distance or more, it may be difficult to miniaturize the electrical connection unit.

On the other hand, in the present embodiment, the base plate 41 includes the first accommodation portion 55J, the second accommodation portion 55K, and an insulating wall (for example, the insulating rib 53 or the insulating wall 53A). The first accommodation portion 55J is recessed in the Z direction or penetrates the flat surface portion 51 in the Z direction, and accommodates the first bus bar 42J in a state in which at least part of the first bus bar 42J is exposed to the first surface 51a side. The second accommodation portion 55K is recessed in the Z direction or penetrates the flat surface portion 51 in the Z direction, and accommodates the second bus bar 42K in a state in which at least part of the second bus bar 42K is exposed to the first surface 51a side. The insulating wall is provided on the first surface 51a at a position between the first accommodation portion 55J and the second accommodation portion 55K. According to such a constitution, even in a case where the first accommodation portion 55J and the second accommodation portion 55K are disposed within a predetermined distance, a necessary insulation distance can be secured by the insulating wall. Therefore, the plurality of bus bars 42 can be easily disposed close to each other. In a case where the plurality of bus bars 42 are easily disposed close to each other, the electrical connection unit 1 can be miniaturized.

In the present embodiment, a flow of an upward stream of air warmed by each bus bar 42 can be straightened by the insulating wall. As a result, it is possible to improve the heat dissipation property of the electrical connection unit 1.

In the present embodiment, the first bus bar 42J includes the first straight portion 42Ja that is accommodated in the first accommodation portion 55J in a state of being exposed to the first surface 51a side and linearly extends. The second bus bar 42K includes the second straight portion 42Ka that is accommodated in the second accommodation portion 55K in a state of being exposed to the first surface 51a side and linearly extends in parallel with the first straight portion 42Ja. The insulating wall is disposed between the first straight portion 42Ja and the second straight portion 42Ka and extends in parallel with the first straight portion 42Ja and the second straight portion 42Ka when viewed from the Z direction. According to such a constitution, the first straight portion 42Ja and the second straight portion 42Ka can be easily disposed close to each other, and it is easy to further miniaturize the electrical connection unit 1.

In the present embodiment, the electrical connection unit 1 has a first connection component (for example, the connection component 20 or the connection component 30) and a second connection component (for example, the connection component 20 or the connection component 30). The first connection component is connected to the first bus bar 42J, and electrically connects the first bus bar 42J to a third electronic component or a first external device. The second connection component is connected to the second bus bar 42K, and electrically connects the second bus bar 42K to a fourth electronic component, a first external device, or a second external device. Part of the insulating wall is disposed between the first connection component and the second connection component. According to such a constitution, even in a case where the first connection component and the second connection component are disposed within a predetermined distance, a necessary insulation distance can be secured between the first connection component and the second connection component by the insulating wall. Therefore, the first connection component and the second connection component can be easily disposed close to each other. When the first connection component and the second connection component are easily disposed close to each other, it is easy to further miniaturize the electrical connection unit 1.

In the present embodiment, the electrical connection unit 1 includes a first connection component (for example, the connection component 20) and a second connection component (for example, the connection component 20). The first connection component is attached to the first bus bar 42J, and electrically connects the first bus bar 42J to the first terminal 13A of the first electronic component 10. The second connection component is attached to the second bus bar 42K, and electrically connects the second bus bar 42K to the second terminal 13B of the first electronic component 10. Part of the insulating wall is disposed between the first connection component and the second connection component. According to such a constitution, even in a case where the first connection component and the second connection component connected to the same electronic component 10 are disposed within a predetermined distance, a necessary insulation distance can be secured between the first connection component and the second connection component by the insulating wall. Therefore, the first connection component and the second connection component can be easily disposed close to each other. When the first connection component and the second connection component are easily disposed close to each other, it is easy to further miniaturize the electrical connection unit 1.

In the present embodiment, the first electronic component 10 has the insulating rib 11a located between the first terminal 13A and the second terminal 13B. The insulating rib 53 has the engagement portion 56 that is engaged with the insulating rib 11a of the first electronic component 10. According to such a constitution, the electronic component 10 can be aligned by engaging the insulating rib 11a of the electronic component 10 with the insulating rib 53. Thus, the assemblability of the electrical connection unit 1 can be improved. According to this constitution, a series of insulating walls can be formed by the insulating rib 53 and the insulating rib 11a of first electronic component 10. As a result, a plurality of energization paths in the electrical connection unit 1 are easily disposed close to each other. When the plurality of energization paths are easily disposed close to each other, it is easy to further miniaturize the electrical connection unit 1.

In the present embodiment, the engagement portion 56 of the insulating rib 53 has the recess 56a into which the insulating rib 11a of the electronic component 10 is inserted. According to such a constitution, the electronic component 10 can be easily aligned by inserting the insulating rib 11a of the electronic component 10 into the recess 56a of the insulating rib 53. Thus, the assemblability of the electrical connection unit 1 can be further improved.

### <F. Advantages of Fixing Structure of Electronic Component>

As a comparative example, a case where the attachment portion 14 of the electronic component 10 is fixed to the base plate 41 will be considered. In such a constitution of the comparative example, since the base plate 41 is made of a synthetic resin, it is difficult to secure rigidity around the attachment portion 14. In addition, in the constitution of the comparative example, due to the linear expansion coefficient of the base plate 41 being larger than the linear expansion coefficient of the electronic component 10, there is a possibility that the position of the electronic component 10 greatly moves at the time of thermal expansion/contraction.

On the other hand, in the present embodiment, the base plate 41, the bus bar 42, the metal plate 80, and the electronic component 10 are provided. The base plate 41 has a plate-shaped flat surface portion 51 having the first surface 51a facing the first electronic component 10 and the second surface 51b located on the side opposite to the first surface 51a. The flat surface portion 51 has the accommodation portion 55 recessed in the Z direction or penetrating the flat surface portion 51 in the Z direction, and the through-hole 51h penetrating the flat surface portion 51 in the Z direction. At least part of the bus bar 42 is accommodated in the accommodation portion 55 and extends along the flat surface portion 51. The metal plate 80 includes the plate-shaped flat surface portion 81 facing the second surface 51b, the first fixing portion 82 to which the base plate 41 is fixed, and the second fixing portion 83 protruding in the Z direction from the flat surface portion 81 and inserted into the through-hole 51h. The electronic component 10 faces the first surface 51a, is electrically connected to the bus bar 42, and is fixed to the second fixing portion 83. According to such a constitution, the base plate 41 and the electronic component 10 are fixed to the metal plate 80. In this case, since the metal plate 80 is made of a metal, rigidity around the attachment portion 14 can be easily secured. Thus, the durability of the electrical connection unit 1 can be improved. In this constitution, since the linear expansion coefficient of the metal plate 80 is smaller than the linear expansion coefficient of the base plate 41, it is possible to suppress significant movement to the position of the electronic component 10 at the time of thermal expansion/contraction.

In the present embodiment, the second fixing portion 83 passes through the through-hole 51h and protrudes to the same position as the first surface 51a or protrudes beyond a position of the first surface 51a in the Z direction. The electronic component 10 is fixed to the second fixing portion 83 on the first surface 51a side. According to such a constitution, since the second fixing portion 83 protrudes close to the first surface 51a, the electronic component 10 is easily fixed to the second fixing portion 83. Thus, the assemblability of the electrical connection unit 1 can be further improved. In addition, the second fixing portion 83 protrudes to be inserted into the through-hole 51h, and thus the base plate 41 can be easily disposed closer to the metal plate 80. When the base plate 41 is easily disposed near the metal plate 80, it is easy to further reduce the height of the electrical connection unit 1.

In the present embodiment, the first fixing portion 82 has the first engagement hole 82h that is open in the Z direction and engaged with the first fastening member 111 that fixes the base plate 41 to the metal plate 80. The second fixing portion 83 has a second engagement hole 83h that is open in the Z direction and engaged with a second fastening member 112 for fixing the electronic component 10 to the metal plate 80. According to such a constitution, the working direction of the work of fixing the base plate 41 to the first fixing portion 82 and the working direction of the work of fixing the electronic component 10 to the second fixing portion 83 can be aligned in the same direction. In a case where these working directions are the same, the assemblability of the electrical connection unit 1 can be further improved.

In the present embodiment, the electrical connection unit 1 includes the connection component 20 that electrically connects the electronic component 10 to the bus bar 42. The connection component 20 is fixed to the electronic component 10 and is also fixed to the bus bar 42. According to such a constitution, the electronic component 10 is fixed to the bus bar 42 via the connection component 20 in addition to being fixed to the metal plate 80. As a result, the fixing structure of the electronic component 10 can be further strengthened.

In the present embodiment, the electrical connection unit 1 includes the fastening member 43 protruding in the Z direction from the bus bar 42. The connection component 20 is attached to the fastening member 43 from the Z direction and connected to the bus bar 42. According to such a constitution, the working direction of the work of fixing the base plate 41 to the first fixing portion 82, the working direction of the work of fixing the electronic component 10 to the second fixing portion 83, and the working direction of the work of fixing the connection component 20 fixed to the electronic component 10 to the bus bar 42 can be aligned in the same direction. In a case where these working directions are the same, the assemblability of the electrical connection unit 1 can be further improved.

### <G. Advantages of Convection Generation Structure>

As a comparative example, in a case where the metal plate 80 facing the second surface 51b of the flat surface portion 51 of the base plate 41 is provided, heat may be confined in the gap S1 between the flat surface portion 51 of the base plate 41 and the metal plate 80. In a case where heat is confined in the gap S1, the heat dissipation property of the electrical connection unit 1 may deteriorate.

On the other hand, in the present embodiment, the electrical connection unit 1 includes the base plate 41, the bus bar 42, and the metal plate 80. The base plate 41 has the plate-shaped flat surface portion 51. The flat surface portion 51 has the accommodation portion 55 recessed in the Z direction or penetrating the flat surface portion 51 in the Z direction, and the through-hole 51h penetrating the flat surface portion 51 in the Z direction. At least part of the bus bar 42 is accommodated in the accommodation portion 55 and extends along the flat surface portion 51. The metal plate 80 includes the flat surface portion 81 and a protruding portion (for example, the second fixing portion 83 or the protruding portion 84). The flat surface portion 81 has a plate shape facing the second surface 51b with the first gap S1 between the flat surface portion 81 and the second surface 51b. The protruding portion protrudes from the flat surface portion 81 in the Z direction and is inserted into the through-hole 51h, and forms the second gap S2 through which air can pass between the protruding portion and the inner circumferential surface 51ha of the through-hole 51h. According to such a constitution, the air flows indicated by the arrows A1 to A3 described above are generated, and the heat dissipation property of the electrical connection unit 1 can be improved.

In the present embodiment, the protruding portion passes through the through-hole 51h and protrudes to the same position as the first surface 51a or protrudes beyond a position of the first surface 51a in the Z direction. According to such a constitution, the air flows indicated by the arrows A1 to A3 described above are more likely to be generated. Therefore, the heat dissipation property of the electrical connection unit 1 can be further improved.

In the present embodiment, the protruding portion is the fixing portion 83 to which the electronic component 10 is fixed. According to such a constitution, the air flows indicated by the arrows A1 to A3 described above are further generated by using the fixing portion 83 to which the electronic component 10 is fixed. As a result, it is possible to improve the heat dissipation property of the electrical connection unit 1 while achieving miniaturization.

### <H. Advantages of Protective Structure Related to Thermal Expansion/Contraction>

As a comparative example, a constitution having the fixing portion 52 without the standing plate portion 52a will be considered. In such a constitution of the comparative example, due to expansion/contraction of the synthetic resin at a high temperature/a low temperature, a difference is generated in a length between fixing positions of the base plate 41 and the metal plate 80, and there is a possibility that the vicinity of the fixing portion 52 of the base plate 41 is damaged.

On the other hand, in the present embodiment, the electrical connection unit 1 includes the metal plate 80, the first electronic component 10, the first bus bar 42, and the first base plate 41. The first base plate 41 includes the first flat surface portion 51, the standing plate portion 52a, and the horizontal plate portion 52b. The first flat surface portion 51 has the first surface 51a facing the electronic component 10 and the second surface 51b located on the side opposite to the first surface 51a and facing the metal plate 80, and has a plate shape holding the first bus bar 42. The standing plate portion 52a has a plate shape extending from the first flat surface portion 51 in the Z direction intersecting the first surface 51a. The horizontal plate portion 52b is supported by the standing plate portion 52a, is disposed at a position different from the first surface 51a in the Z direction, and is fixed to the metal plate 80. According to such a constitution, the thermal expansion/contraction of the base plate 41 can be absorbed by the displacement of the first plate portion 52a. As a result, it is possible to reduce a possibility that damage occurs in the vicinity of the fixing portion 52 of the base plate 41. Thus, the durability of the electrical connection unit 1 can be improved.

In the present embodiment, the metal plate 80 includes the flat surface portion 81 facing the second surface 51b of the flat surface portion 51, and the first fixing portion 82 that protrudes in the Z direction from the flat surface portion 81 and to which the horizontal plate portion 52b of the first base plate 41 is fixed. According to such a constitution, the horizontal plate portion 52b is easily fixed to the metal plate 80. When the first plate portion 52a is provided, it is easy to secure an insulating property between the fixing portion 52 of the metal plate 80 and the bus bar 42.

In the present embodiment, the first base plate 41 has the through-hole 51h penetrating the flat surface portion 51 in the Z direction. The metal plate 80 has a fixing portion 83 that protrudes from the flat surface portion 81 in the Z direction, is inserted into the through-hole 51h of the first base plate 41, and to which the first electronic component 10 is fixed. The length L1 of the standing plate portion 52a in the Z direction is larger than a length L2 of the fixing portion 83 in the Z direction. According to such a constitution, the large standing plate portion 52a is present, and thermal expansion/contraction of the base plate 41 is more easily absorbed.

In the present embodiment, the electrical connection unit 1 further includes the second base plate 41. The second base plate 41 includes the second flat surface portion 51, the standing plate portion 52a, and the horizontal plate portion 52b. The second flat surface portion 51 has a plate shape, includes the third surface 51a facing the second electronic component and the fourth surface 51b located on the side opposite to the third surface 51a and facing the metal plate 80, and holds the second bus bar 42. The second flat surface portion 51 has a plate shape extending from the second flat surface portion 51 in the Z direction. The horizontal plate portion 52b is supported by the standing plate portion 52a, is disposed at a position different from the first surface 51a in the Z direction, overlaps the horizontal plate portion 52b of the first base plate, and is fixed to the metal plate 80. According to such a constitution, the horizontal plate portions 52b of the two base plates 41 are fixed to one fixing portion 82. Thus, the electrical connection unit 1 can be miniaturized.

### <I. Advantages of Manufacturing Method>

As a comparative example, a constitution in which an electronic component and a bus bar are directly attached will be considered. In such a constitution of the comparative example, the following state (1) or (2) may occur. (1) In a case where a bus bar is fastened to an electronic component first and then assembled to a housing, it is necessary to check contact with a peripheral component and assembly of the bus bar when the bus bar to be routed is housed in the housing, which may cause workability to deteriorate. (2) In a case where the electronic component and the bus bar are fastened after the electronic component and the bus bar are housed in the housing, a space for fastening in the horizontal direction is required and thus a useless space may be generated in the electrical connection unit.

On the other hand, in the present embodiment, a method of manufacturing the electrical connection unit 1 includes preparing the routing board 40, forming the assembly SA, and connecting a connection component (the connection component 20, the connection component 30, or the connection component 100) to the bus bar 42. The routing board 40 includes the base plate 41 having the plate-shaped flat surface portion 51 and the bus bar 42 held by the flat surface portion 51. The flat surface portion 51 has the accommodation portion 55 recessed in the Z direction or penetrating the flat surface portion 51 in the Z direction. At least part of the bus bar 42 is accommodated in the accommodation portion 55 and extends along the flat surface portion 51. Forming the assembly SA includes fixing the connection component to a connection target component (the electronic component 10, the coupling bus bar 75, or the external connection bus bar 76) by using a first fastening member (the fastening member 71, the fastening member 72, or the fastening member 73) to form the assembly SA in which the connection target component and the connection component are integrated. Connecting the connection component to the bus bar 42 includes, after forming the assembly SA, connecting the connection component included in the assembly SA to the bus bar 42 by using a second fastening member (for example, the fastening member 43). According to such a constitution, assemblability of the connection target component and the connection component with respect to the bus bar 42 can be enhanced. Thus, the assemblability of the electrical connection unit 1 can be improved.

The second fastening member is not limited to the fastening member 43 protruding from the bus bar 42. In a case where an attachment hole (for example, a screw hole) is formed in the bus bar 42, the second fastening member may be a fastening member (for example, a bolt or a screw) that passes through an insertion hole formed in the connection target component and is engaged with the attachment hole of the bus bar 42.

In the present embodiment, an example of the connection target component is the electronic component 10. The connection component is fixed to the terminal 13 of the electronic component 10 by using the first fastening member. According to such a constitution, forming the assembly SA by using the electronic component 10 and the connection component 20 can enhance the assemblability of the electronic component 10 and the connection component 20 with respect to the bus bar 42. Thus, the assemblability of the electrical connection unit 1 can be improved.

In the present embodiment, the work of fixing the connection component to the connection target component by using the first fastening member is performed in a state in which the connection target component and the connection component are in a first posture. The work of fixing the connection component included in the assembly SA to the bus bar 42 by using the second fastening member is performed in a state in which the connection target component and the connection component are in a second posture different from the first posture. According to such a constitution, even in a case where a connection direction between the connection target component and the connection component is the horizontal direction in the assembled state of the electrical connection unit 1, a load on a worker can be reduced and the assemblability of the electrical connection unit 1 can be improved by attaching the connection target component and the connection component in a direction different from the horizontal direction at the time of assembly.

In the present embodiment, the connection component includes a first attachment hole into which the first fastening member is inserted, and a second attachment hole that is open in a direction different from the first attachment hole and into which the second fastening member is inserted. The first posture is a posture in which the first attachment hole is directed in a first attachment direction. The second posture is a posture in which the first attachment hole is directed in a direction different from the first attachment direction and the second attachment hole is directed in the first attachment direction. According to such a constitution, even in a case where a connection direction between the connection target component and the connection component is the horizontal direction, an attachment direction of the connection target component and the connection component and an assembly direction of the assembly SA with respect to the bus bar 42 can be aligned in the same direction. As a result, a load on a worker can be further reduced, and the assemblability of the electrical connection unit 1 can be further improved.

In the present embodiment, the connection component 20 includes the first portion 21 to which the first fastening member is attached and that is connected to the electronic component 10, and the second portion 22 to which the second fastening member is attached and that is connected to the bus bar 42. The thickness T1 of the first portion 21 in the X direction is larger than a thickness of the second portion 22 in the Z direction. According to such a constitution, the connection component 20 has a larger heat capacity per unit length than that of the bus bar 42. Therefore, even in a case where a short-term large current flows through the electronic component 10 and the temperature of the electronic component 10 becomes higher in a short period of time, part of heat generated by the electronic component 10 is stored by the connection component 20. As a result, it is possible to suppress a temperature change inside the electrical connection unit 1. Thus, it is possible to improve the thermal characteristics (for example, thermal resistance) of the electrical connection unit 1.

From another point of view, in the present embodiment, the connection component 20 is disposed between the first terminal 13 of the electronic component 10 and the bus bar 42. The connection component 20 electrically connects the electronic component 10 to the bus bar 42. A thickness of at least part of the connection component 20 is larger than a plate thickness of the bus bar 42 in the Z direction. According to such a constitution, the connection component 20 has a larger heat capacity per unit length than that of the bus bar 42. Therefore, even in a case where a short-term large current flows through the electronic component 10 and the temperature of the electronic component 10 becomes higher in a short period of time, part of heat generated by the electronic component 10 is stored by the connection component 20. As a result, it is possible to suppress a temperature change inside the electrical connection unit 1. Thus, it is possible to improve the thermal characteristics (for example, thermal resistance) of the electrical connection unit 1.

### <J. Advantages of Division Structure>

As a comparative example, a constitution in which the metal plate 80 is not present in a constitution in which the main body MU is divided into a plurality of subunits SU will be considered. In such a constitution of the comparative example, it may be necessary to increase a plate thickness of the base plate 41 or to add a reinforcing component in order to secure the rigidity of a coupling portion of the plurality of subunits SU. In this case, it may be difficult to reduce the height of the electrical connection unit 1.

On the other hand, in the present embodiment, the electrical connection unit 1 includes the first subunit SU, the second subunit SU electrically connected to the first subunit SU, and the metal plate 80. The first subunit SU includes a plurality of first electronic components (for example, the plurality of electronic components 10), a plurality of first bus bars (for example, the plurality of bus bars 42), and a first base member (for example, the base plate 41). The plurality of first bus bars include portions disposed on the same plane, and are electrically connected to the plurality of first electronic components. The first base member includes a plate-shaped first flat surface portion that holds the plurality of first bus bars. The second subunit SU includes a plurality of second electronic components (for example, the plurality of electronic components 10), a plurality of second bus bars (for example, the plurality of bus bars 42), and a second base member (for example, the base plate 41). The plurality of second bus bars include portions disposed on the same plane, and are electrically connected to the plurality of second electronic components. The second base member includes a plate-shaped second flat surface portion that holds the plurality of second bus bars. The metal plate 80 is fixed to each of the first subunit SU and the second subunit SU, and integrally holds the first subunit SU and the second subunit SU. According to such a constitution, the rigidity of the coupling portion between the first subunit SU and the second subunit SU can be secured by the metal plate 80. Therefore, it is unnecessary or less necessary to increase the plate thickness of the base plate 41 or add a reinforcing component, and it is possible to reduce the height of the electrical connection unit 1 compared with the case where the metal plate 80 is not present.

In the present embodiment, the first flat surface portion includes a plurality of first accommodation portions that are recessed in the Z direction or penetrate the first flat surface portion in the Z direction to accommodate a plurality of first bus bars. The second flat surface portion includes a plurality of second accommodation portions that are recessed in the Z direction or penetrate the second flat surface portion in the Z direction to accommodate a plurality of second bus bars. According to such a constitution, it is possible to further reduce the height of the electrical connection unit 1.

In the present embodiment, the longitudinal direction of the first subunit SU is the X direction. The longitudinal direction of the second subunit SU is the X direction. The second subunit SU is adjacent to the first subunit SU in the X direction. The longitudinal direction of the metal plate 80 is the X direction. The length of the metal plate 80 in the X direction is larger than the sum of the length of the first subunit SU in the X direction and the length of the second subunit SU in the second direction. According to such a constitution, it is easy to more firmly hold the first subunit SU and the second subunit SU with the metal plate 80.

In the present embodiment, the electrical connection unit 1 further includes the coupling bus bar 75 that electrically connects the first subunit SU to the second subunit SU. The coupling bus bar 75 is disposed on the side opposite to the metal plate 80 with respect to the first subunit SU and the second subunit SU. According to such a constitution, the coupling portion between the first subunit SU and the second subunit SU is reinforced from both sides in the Z direction (the +Z direction side and the −Z direction side) by the metal plate 80 and the coupling bus bar 75. As a result, the metal plate 80 can be thinned, and the height of the electrical connection unit 1 can be further reduced.

In the present embodiment, the first subunit SU includes the first fixing portion 52. The second subunit SU includes the second fixing portion 52 overlapping the first fixing portion 52 when viewed from the Z direction. The first fixing portion 52 and the second fixing portion 52 are fixed to the metal plate 80 via one fastening member 111. According to such a constitution, it is possible to miniaturize the electrical connection unit 1 in the X direction, and it is possible to reduce the cost with the reduction in the number of components.

### 15. Modification Examples

Next, several modification examples will be described. Note that a constitution other than that described below in each modification example is the same as the constitution of the first embodiment.

### First Modification Example

The routing board 40 is not limited to a structure in which the base plate 41 and the bus bar 42 are integrated through insert molding. For example, the bus bar 42 may be disposed in the accommodation portion 55 after the base plate 41 provided with the accommodation portion 55 for accommodating the bus bar 42 is molded. In this case, the bus bar 42 may be fixed to the accommodation portion 55 through fitting, or may be fixed to the accommodation portion 55 via an adhesive or other fixing means. In these cases, potting may be performed to fill a gap between the bus bar 42 and the accommodation portion 55.

### Second Modification Example

A base member of the routing board 40 is not limited to the base plate 41 having the plate-shaped flat surface portion 51. The routing board 40 may be a base member (for example, an insulating sheet) having a sheet-shaped flat surface portion 51. In this case, the accommodation portion 55 may be formed by part of the flat surface portion 51 following the outer shape of the bus bar 42. In the present disclosure, the “sheet-shaped” or “sheet” is not limited to a member having a thickness of 1 mm or more, and a member (so-called a film) having a thickness of less than 1 mm can also be used.

### Third Modification Example

The base plate 41 of the routing board 40 may include a plurality of members (plate members or sheet members). The plurality of members are provided to sandwich the plurality of bus bars 42 arranged in the horizontal direction. For example, the plurality of members are integrated by sandwiching the plurality of bus bars 42 through laminate molding, for example. The plurality of members form the flat surface portion 51. In this case, the accommodation portion 55 may be formed in a hollow shape inside the base plate 41 (between the plurality of members). The plurality of members may be a plurality of plate members, a plurality of sheet members, or a combination of a plate member and a sheet member. The sheet member may be, for example, a flexible sheet member. The flat surface portion 51 formed of the plurality of members has an opening through which at least first connection portion 61 and second connection portion 62 of bus bar 42 are exposed.

### Fourth Modification Example

A connection between the electronic component 10 and the bus bar 42 is not limited to the connection using the connection component 20. The electronic component 10 may be directly connected to the bus bar 42 by using a fastening member (for example, a bolt or a screw), welding, or the like.

### Second Embodiment

Next, a second embodiment will be described. The second embodiment is different from the first embodiment in that an opening 121 for heat dissipation is provided in a base plate 41. The constitution other than that described below is the same as that of the first embodiment.

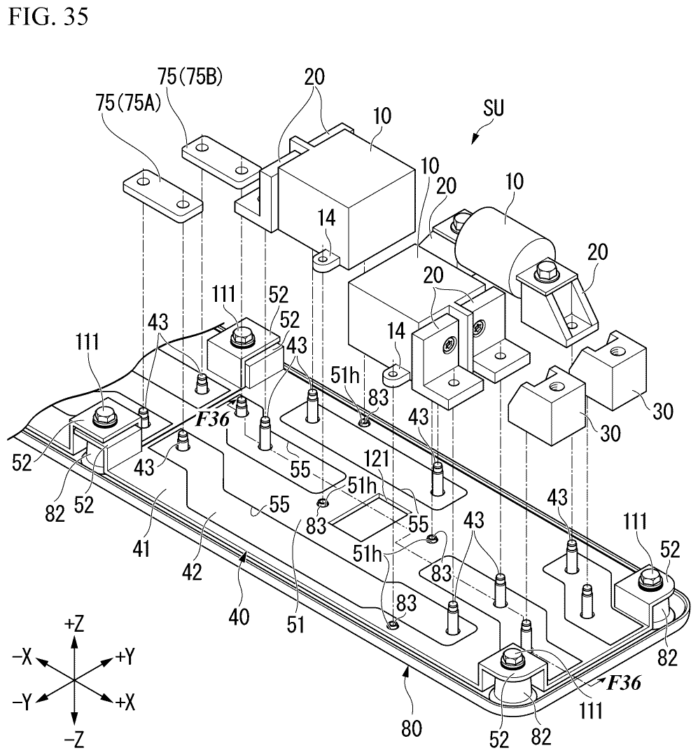

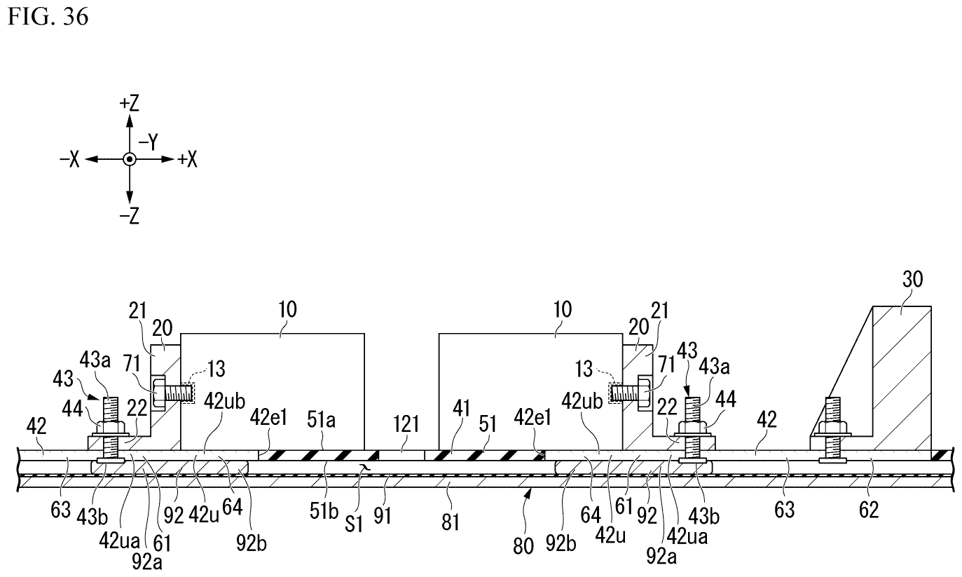

FIG. 35 is a perspective view for describing a subunit SU of the second embodiment. FIG. 36 is a cross-sectional view taken along line F36-F36 of the structure illustrated in FIG. 35. Similarly to the first embodiment, the electrical connection unit 1 of the second embodiment has the metal plate 80 disposed with the gap S1 between the metal plate 80 and the base plate 41 and facing the second surface 51b of the flat surface portion 51. The heat transfer member 92 is present between the bus bar 42 and the metal plate 80. In this constitution, heat may be confined in the gap S1 between the base plate 41 and the metal plate 80.

In the present embodiment, the flat surface portion 51 of the base plate 41 has an opening 121 for heat dissipation. The opening 121 penetrates the flat surface portion 51 in the Z direction, communicates with the gap S1 between the flat surface portion 51 and the metal plate 80, and allows air to pass therethrough. The air in the gap S1 between the flat surface portion 51 and the metal plate 80 is moved above the flat surface portion 51 through the opening 121, for example, in response to being warmed.

According to such a constitution, heat is less likely to be confined in the gap S1 between the base plate 41 and the metal plate 80. In a case where heat is hardly confined in gap S1, the heat dissipation property of the bus bar 42 is improved. When the heat dissipation property of the bus bar 42 is improved, the heat dissipation property of the electrical connection unit 1 can be improved.

### Third Embodiment

Next, a third embodiment will be described. The third embodiment is different from the first embodiment in that an insulating portion for enhancing an insulating property between adjacent bus bars 42 is provided. The constitution other than that described below is the same as that of the first embodiment.

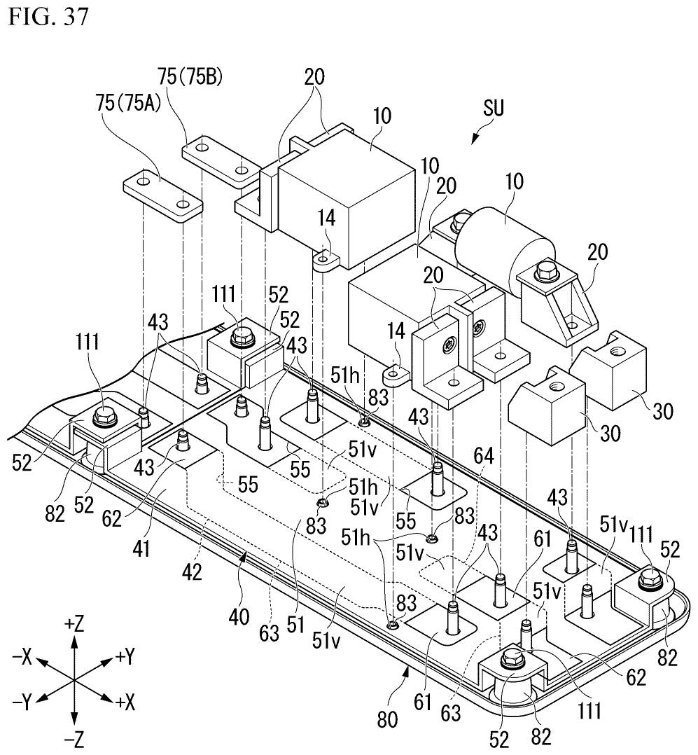

FIG. 37 is a perspective view for describing a subunit SU of the third embodiment. In the third embodiment, the base plate 41 includes a cover portion 51v. The cover portion 51v is an insulating portion that covers part of the bus bar 42 on at least one of the first surface 51a side and the second surface 51b side. The cover portion 51v covers, for example, at least part of the extending portion 63 of the bus bar 42. Instead of/in addition to the above example, the cover portion 51v covers at least part of the extension 64 of the bus bar 42. For example, the cover portion 51v is provided in a portion where two bus bars 42 are adjacent to each other within a predetermined distance.

According to such a constitution, it is easy to enhance an insulating property between the adjacent bus bars 42 and to secure an insulation distance between the adjacent bus bars 42. Note that the cover portion 51v may be formed through insert molding, for example, similarly to other portions of the flat surface portion 51. Alternatively, the cover portion 51v may be formed by applying an insulating material to the surface of the bus bar 42, bonding an insulating sheet, or the like. The cover portion 51v may be provided as part of the base plate 41, or may be formed of a component attached to the base plate 41 after being provided separately from the base plate 41.

### Fourth Embodiment

Next, a fourth embodiment will be described. The fourth embodiment is different from the first embodiment in that a holding portion 131 that supports a bus bar 42 is provided. The constitution other than that described below is the same as that of the first embodiment.

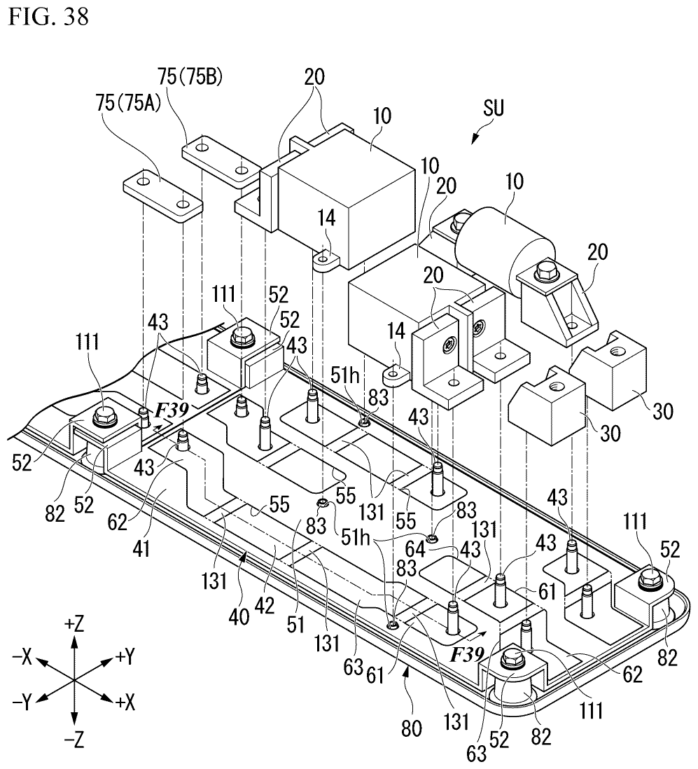

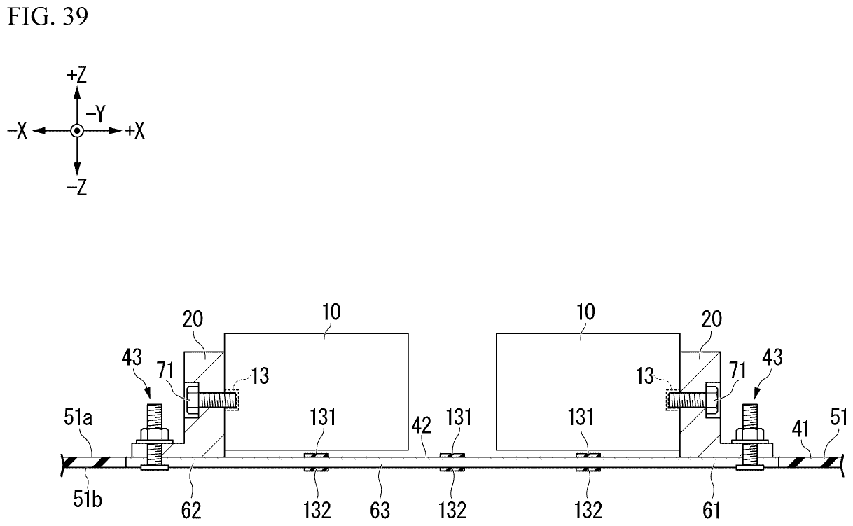

FIG. 38 is a perspective view for describing a subunit SU of the fourth embodiment. FIG. 39 is a cross-sectional view taken along line F39-F39 of the structure illustrated in FIG. 38. In the fourth embodiment, the base plate 41 has holding portions 131 and 132 that overlap part of the bus bar 42 when viewed from the Z direction and support the bus bar 42 in the Z direction. Note that only one of the holding portion 131 and the holding portion 132 may be provided.

For example, the holding portion 131 is disposed adjacent to the first surface 51a of the flat surface portion 51, is disposed above the bus bar 42, and supports the bus bar 42 from above. The holding portion 131 holds the bus bar 42 so that the bus bar 42 does not fall off upward. On the other hand, the holding portion 132 is disposed adjacent to the second surface 51b of the flat surface portion 51, and supports the bus bar 42 from below. The holding portion 132 holds the bus bar 42 so that the bus bar 42 does not fall off downward. The holding portions 131 and 132 are provided, for example, in the extending portion 63 or the extension 64 of the bus bar 42. However, the holding portions 131 and 132 may be provided in the first connection portion 61 or the second connection portion 62 of the bus bar 42.

According to such a constitution, even in a case where a gap may be generated between the accommodation portion 55 and the bus bar 42 at the time of thermal expansion due to a difference between the linear expansion coefficient of the base plate 41 and the linear expansion coefficient of the bus bar 42, the bus bar 42 is less likely to fall off from the base plate 41. Thus, the heat resistance of the electrical connection unit 1 can be improved.

Note that the holding portions 131 and 132 may be formed through, for example, insert molding similarly to other portions of the flat surface portion 51. Alternatively, the holding portions 131 and 132 may be formed of separate components attached to the base plate 41 after being provided separately from the base plate 41.

### Modification Example

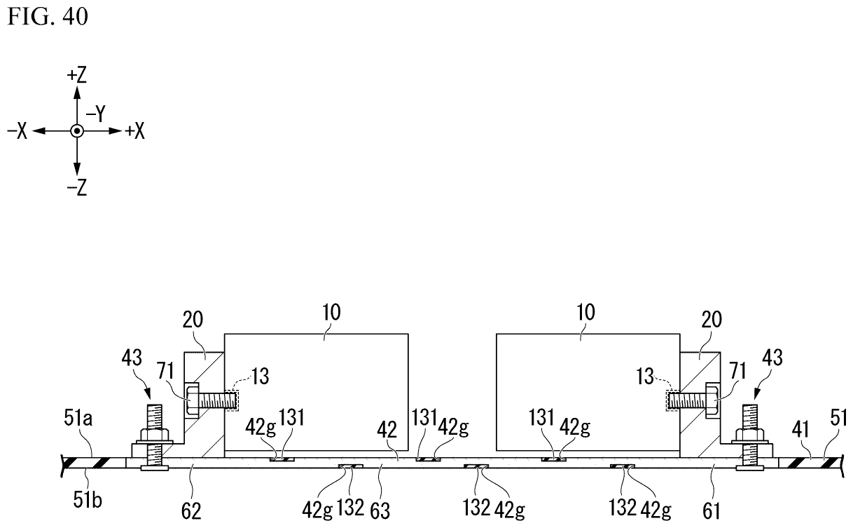

FIG. 40 is a cross-sectional view illustrating a modification example of the fourth embodiment. In the present modification example, the upper surface of the bus bar 42 has a recess 42g recessed in the −Z direction. The recess 42g extends, for example, in the Y direction. Similarly, the lower surface of the bus bar 42 has a recess 42g recessed in the +Z direction. The recess 42g extends, for example, in the Y direction.

In the present modification example, the holding portion 131 is provided in the recess 42g on the upper surface of the bus bar 42. Similarly, the holding portion 132 is provided in the recess 42g on the lower surface of the bus bar 42. For example, the holding portions 131 and 132 are formed within the range of the thickness of the bus bar 42 in the Z direction. According to such a constitution, it is easy to further reduce the height of the electrical connection unit 1.

### Fifth Embodiment

Next, a fifth embodiment will be described. The fifth embodiment is different from the first embodiment in that a support portion 141 that presses the bus bar 42 toward the heat transfer member 92 is provided. The constitution other than that described below is the same as that of the first embodiment.

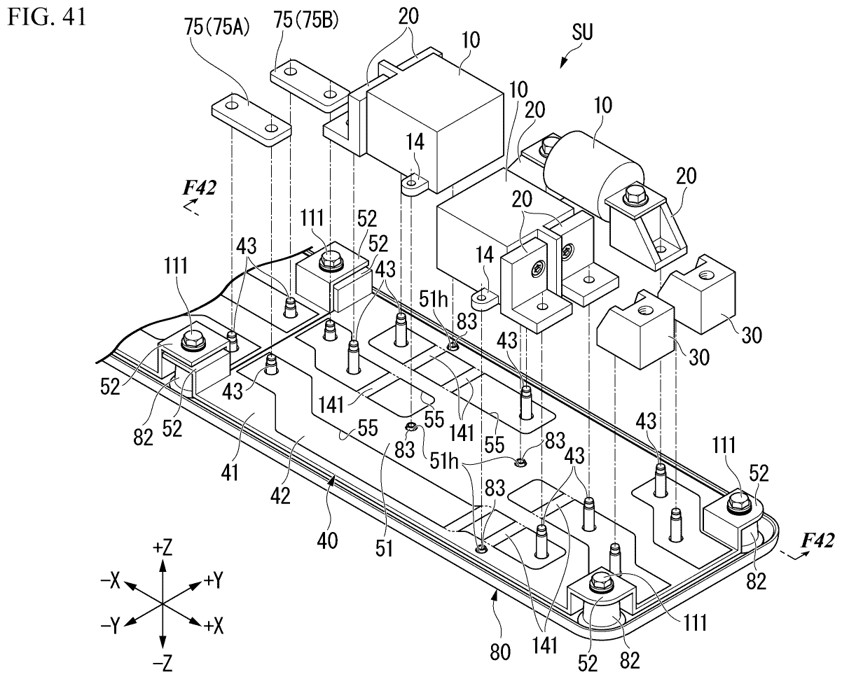

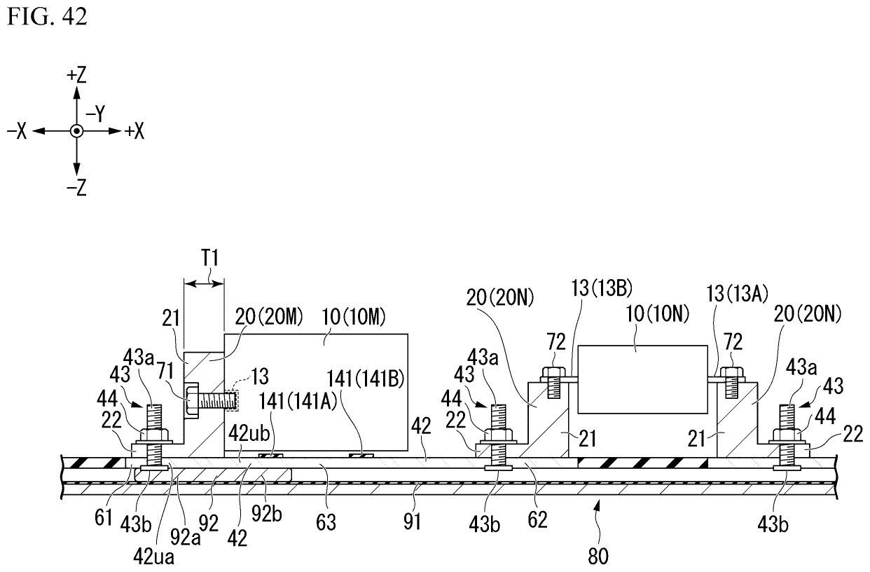

FIG. 41 is a perspective view for describing a subunit SU of the fifth embodiment. FIG. 42 is a cross-sectional view taken along line F42-F42 of the structure illustrated in FIG. 41. In the fifth embodiment, the base plate 41 is disposed on the side opposite to the heat transfer member 92 with respect to the bus bar 42, and includes the support portion 141 that presses the bus bar 42 toward the heat transfer member 92.

In the present embodiment, the heat transfer member 92 has elasticity. Therefore, in a case where the bus bar 42 can be pressed toward the heat transfer member 92 to enhance the contact between the bus bar 42 and the heat transfer member 92, the heat dissipation property can be enhanced. A plurality of support portions 141 include, for example, a support portion 141A and a support portion 141B. Note that only one of the support portion 141A and the support portion 141B may be provided.

For example, the support portion 141A is disposed adjacent to the first surface 51a of the flat surface portion 51, is disposed above the bus bar 42, and supports the bus bar 42 from above. The support portion 141A overlaps at least part of the heat transfer member 92 when viewed from the Z direction. The support portion 141A presses the bus bar 42 toward the heat transfer member 92 in a region overlapping the heat transfer member 92 when viewed from the Z direction.

For example, the support portion 141B is disposed adjacent to the first surface 51a of the flat surface portion 51, is disposed above the bus bar 42, and supports the bus bar 42 from above. The support portion 141B overlaps at least part of the electronic component 10 when viewed from the Z direction. The support portion 141B presses the bus bar 42 toward the heat transfer member 92 in a region overlapping the electronic component 10 when viewed from the Z direction.

Note that the support portion 141 is not limited to the support portion 141A or the support portion 141B described above, and may be a support portion that presses the bus bar 42 toward the heat transfer member 92 at another location.

According to such a constitution, the bus bar 42 is pressed toward the heat transfer member 92 by the support portion 141, and the contact between the bus bar 42 and the heat transfer member 92 is enhanced. Thus, the heat dissipation property of the electrical connection unit 1 can be further improved.

Note that the support portion 141 may be formed through, for example, insert molding similarly to other portions of the flat surface portion 51. Alternatively, the support portion 141 may be formed of separate components attached to the base plate 41 after being provided separately from the base plate 41.

Several embodiments and modification examples have been described above. However, the embodiment and the modification examples are not limited to the examples described above. For example, a plurality of embodiments may be implemented in combination with each other. The above-described embodiments can be implemented in various other forms, and various additions, omissions, substitutions, and changes can be made without departing from the concept of the present disclosure.

### INDUSTRIAL APPLICABILITY

According to the present disclosure, the height of the electrical connection unit can be reduced.

### REFERENCE SIGNS LIST

1 Electrical connection unit
SU Subunit
10 Electronic component
13, 13A, 13B Terminal
20 Connection component
21 First portion
21h First attachment hole
22 Second portion
22h Second attachment hole
30 Connection component
31 First portion
32 Second portion
40 Routing board
41 Base plate
42 Bus bar
42e1 End of bus bar
42p Plate portion
42u Exposed portion
42ua First portion
42ub Second portion
43 Fastening member (fastening portion)
51 Flat surface portion (insulating base portion)
51a First surface, third surface
51b Second surface, fourth surface
52 Fixing portion
52a First portion, third portion
52b Second portion, fourth portion
55 Accommodation portion
56 Engagement portion
56 Recess
61 First connection portion
62 Second connection portion
63 Extending portion
64 Extension
71 Fastening member
72 Fastening member
73 Fastening member
80 Metal plate
81 Flat surface portion (metal base portion)
82 Fixing portion
83 Fixing portion
92 Heat transfer member
92a First heat transfer portion
92b Second heat transfer portion
100 Connection component
101 First portion
102 Second portion
111 Fastening member
112 Fastening member
121 Opening
131, 132 Holding portion
141 Support portion

What is claimed is:

1. An electrical connection unit comprising:
an insulating base member including a flat surface portion having a plate shape or a sheet shape, the flat surface portion including an accommodation portion that is recessed in a first direction or penetrates the flat surface portion in the first direction in a case where a thickness direction of the flat surface portion is the first direction; and
a bus bar at least a part of which is accommodated in the accommodation portion and extends along the flat surface portion.

2. The electrical connection unit according to claim 1, wherein
the bus bar is accommodated in the accommodation portion over an entire length of the bus bar and extends along the flat surface portion.

3. The electrical connection unit according to claim 1, wherein
the bus bar is integrated with the base member through insert molding.

4. The electrical connection unit according to claim 1, further comprising:
a fastening portion protruding from the bus bar in the first direction; and
a connection component electrically connecting an electronic component or an external device to the bus bar, the connection component being attached to the fastening portion from the first direction and connected to the bus bar.

5. The electrical connection unit according to claim 4, wherein
in a case where a direction intersecting the first direction is a second direction, the connection component is connected to the electronic component from the second direction.

6. The electrical connection unit according to claim 1, further comprising:
a metal plate facing the flat surface portion with a gap between the metal plate and the flat surface portion; and
a heat transfer member disposed between the bus bar and the metal plate, wherein
the flat surface portion has an opening that penetrates the flat surface portion in the first direction, communicates with the gap, and allows air to pass therethrough.

7. The electrical connection unit according to claim 1, wherein
the flat surface portion has a first surface and a second surface located on a side opposite to the first surface, and
the base member includes an insulating portion that covers a part of the bus bar on at least one of the first surface side and the second surface side.

8. The electrical connection unit according to claim 1, wherein
the base member includes a holding portion that overlaps a part of the bus bar when viewed from the first direction and supports the bus bar in the first direction.

9. The electrical connection unit according to claim 1, further comprising:
a metal plate facing the flat surface portion with a gap between the metal plate and the flat surface portion; and
a heat transfer member disposed between the bus bar and the metal plate,
wherein the base member includes a support portion that is disposed on a side opposite to the heat transfer member with respect to the bus bar and presses the bus bar toward the heat transfer member.
